(19) United States
(12) Patent Application Publication
(10) Pub. No.: US 2025/0160212 A1
(43) Pub. Date: May 15, 2025

(54) LONG LIFE ORGANIC LIGHT EMITTING MATERIALS AND ORGANIC LIGHT EMITTING DIODE

(71) Applicant: LORDIN CO., LTD, Hwaseong-si, Gyeonggi-do (KR)

(72) Inventors: Bubae PARK, Hwaseong-si, Gyeonggi-do (KR); Garam HAN, Osan-si, Gyeonggi-do (KR); Youngjoon KIM, Hwaseong-si, Gyeonggi-do (KR); Minsik MUN, Hwaseong-si, Gyeonggi-do (KR)

(21) Appl. No.: 18/247,061

(22) PCT Filed: Aug. 5, 2022
(86) PCT No.: PCT/KR2022/011631

§ 371 Date: Dec. 3, 2024

(30) Foreign Application Priority Data
Feb. 15, 2022 (KR) KR10-2022-0019489
Jul. 29, 2022 (KR) KR10-2022-0094694

(51) Int. Cl. H10K 85/60; C09K 11/06; H10K 85/40; H10K 101/00; H10K 101/10; H10K 101/20; H10K 101/30

(52) U.S. Cl. CPC H10K 85/658; C09K 11/06; H10K 85/40; H10K 85/622; H10K 85/633; H10K 85/636; H10K 85/653; H10K 85/654; H10K 85/655; H10K 85/656; H10K 85/6572; H10K 85/6574; H10K 85/6576; H10K 2101/10; H10K 2101/20; H10K 2101/27; H10K 2101/30

(57) ABSTRACT

An organic light emitting diode including the first electrode, the second electrode, and the emission layer positioned between the first electrode and the second electrode, wherein the emission layer includes a novel multifunctional emitting compound represented by Formula 1 described in the detailed description.

### CROSS REFERENCE TO RELATED APPLICATIONS

The present application is a U.S. National Phase of International Application No. PCT/KR2022/011631 entitled “LONG LIFE ORGANIC LIGHT EMITTING MATERIALS AND ORGANIC LIGHT EMITTING DIODE,” and filed on Aug. 5, 2022. International Application No. PCT/KR2022/011631 claims priority to Korean Patent Application No. KR10-2022-0019489 filed on Feb. 15, 2022 and Korean Patent Application No. KR10-2022-0094694 filed on Jul. 29, 2022. The entire contents of each of the above-listed applications are hereby incorporated by reference for all purposes.

### TECHNICAL FIELD

The present disclosure relates to long life organic light emitting materials and an organic light emitting diode.

### BACKGROUND ART

OLED (Organic Light Emitting Diode) is a device in which a hole injected from the anode and an electron injected from the cathode combine in the emission layer through the charge transport layer to form an exciton and it emits light, which is first reported in Appl. Phys. Lett 51, 913. by C. W. Tang in 1987. At that time, the emission layer was composed of Alq3 as a single material. In J. Appl. Phys., Vol. 65, 3610 in 1989, Alq3 was doped with DCM as a red emitting compound and Coumarine 540 as a green emitting compound in small amounts to adjust the emission wavelength and increase efficiency.

### DISCLOSURE

### Technical Problem

An object of the present disclosure is to provide an organic light emitting diode capable of minimizing decrease in light brightness even when driven for a long time by improving light emission stability of a luminant.

The objectives of the present disclosure are not limited to the above-mentioned objectives, and other unmentioned objectives and advantages of the present disclosure may be understood by the following description, and will be more clearly understood by the embodiments of the present disclosure. In addition, it will be readily apparent that the objectives and advantages of the present disclosure can be realized by means and combinations thereof set forth in the claims.

### Technical Solution

One of more embodiments include an organic light emitting diode comprising a first electrode, a second electrode and an emission layer interposed between the first electrode and the second electrode,
wherein the emission layer includes a multifunctional emitting compound represented by Formula 1 below,
the multifunctional emitting compound includes an emitting moiety and a charge stabilizing moiety, the emitting moiety and the charge stabilizing moiety are connected through an atom X and the atom X is X indicated in Formula 1 below,
the emitting moiety includes a ring A, a conjugated ring formed with Y1 to Y5 being included, and Q in Formula 1 below,
the charge stabilizing moiety includes a conjugated ring formed with Y6 to Y10 being included, a conjugated ring formed with Y11 to Y15 being included, and Z in Formula 1 below,
the charge stabilizing moiety comprises at least one atom having an unshared pair of electrons:

### <Formula 1>

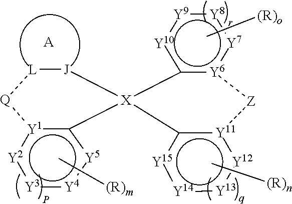

In Formula 1,
a ring A is a fused ring represented by Formula 2, Formula 3 or Formula 4 below,
L represents a linking site in the ring A,
J represents the other linking site in the ring A, and J is linked to X,
X is C, Si, Ge, Sn or Pb,
Q is absent or represents a single bond, or is an atom selected from the group consisting of group IIIA, group IVA, group VA and group VIA elements,
when Q does not exist, L in the ring A is not linked to Y1,
when Q is a single bond, a single bond which directly connects L in the ring A and Y1 is formed so as to form a 5-membered ring including X,
when Q is any of atom selected from the elements defined above, a 6-membered ring including X and Q is formed, and the atom as Q can have a substituent(s) selected from the group consisting of alkyl having 1 to 20 carbon atoms, a first additional substituent-substituted or unsubstituted aryl having 6 to 20 carbon atoms, a first additional substituent-substituted or unsubstituted heteroaryl having 5 to 20 carbon atoms and combinations thereof, in accordance with a stoichiometric ratio, and the first additional substituent can connect to Y2 or Y2-linked R to form a fused ring, or connect to the ring A to form a fused ring,
Y1 to Y15 are, each independently, boron, carbon, nitrogen, oxygen, sulfur, Se or Te,
Z is absent, or is a single bond, oxygen, sulfur, Se, C—(Ar1)2, POAr1 or N—Ar1, where Ar1 is alkyl having 1 to 20 carbon atoms, a second additional substituent-substituted or unsubstituted aryl having 6 to 20 carbon atoms or a second additional substituent-substituted or unsubstituted heteroaryl having 5 to 20 carbon atoms, and Ar1 can connect to any of Y7, Y12, Y7-linked R or Y12-linked R to form a fused ring,
when Z is absent, Y6 and Y11 are not connected,
when Z is a single bond, Y6 and Y11 are connected by a single bond,
m, n and o are, each independently, an integer from 0 to 5,
R is, each independently, hydrogen, deuterium, alkyl having 1 to 20 carbon atoms, a second additional substituent-substituted or unsubstituted aryl having 6 to 20 carbon atoms, a second additional substituent-substituted or unsubstituted heteroaryl having 5 to 20 carbon atoms, alkylamine having 1 to 20 carbon atoms, a second additional substituent-substituted or unsubstituted arylamine having 6 to 30 carbon atoms, a second additional substituent-substituted or unsubstituted alkylarylamine having 7 to 30 carbon atoms, halogen, CN, a second additional substituent-substituted or unsubstituted alkoxy having 1 to 20 carbon atoms, aryloxy having 6 to 30 carbon atoms, alkylsilyl having 3 to 20 carbon atoms, a second additional substituent-substituted or unsubstituted arylsilyl having 6 to 30 carbon atoms, a second additional substituent-substituted or unsubstituted alkylarylsilyl having 7 to 30 carbon atoms, alkylthiol having 3 to 20 carbon atoms, a second additional substituent-substituted or unsubstituted arylthiol having 6 to 30 carbon atoms, or a second additional substituent-substituted or unsubstituted arylphosphine oxide having 6 to 30 carbon atoms, and when m, n or o is 2 or more, at least two R present can be connected to each other to form a ring,
p, q and r, each independently, represent 0 or 1; when p, q or r is 0, it means that a 5-membered ring is formed; and when p, q or r is 1, it means that a 6-membered ring is formed;

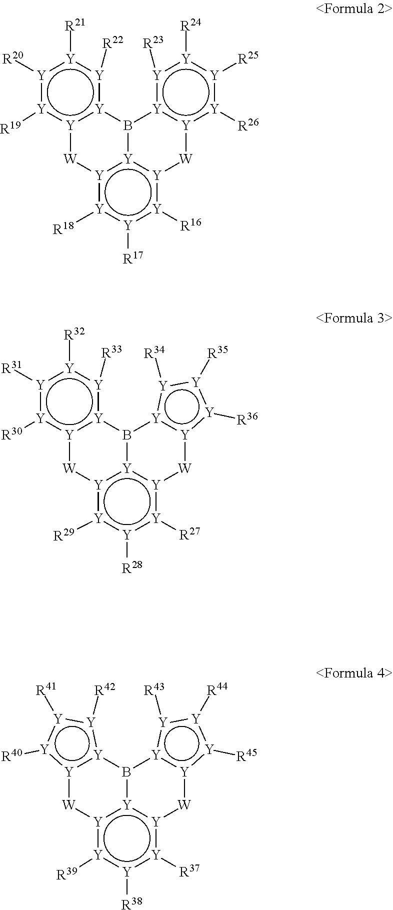

In Formula 2, Formula 3, and Formula 4,
Y is, each independently, carbon, nitrogen, oxygen, sulfur, Se or Te, provided that Y at a position corresponding to J in Formula 1 is carbon,
W is, each independently, oxygen, sulfur, Se, POAr2, or N—Ar2, and Ar2 is alkyl having 1 to 20 carbon atoms, a second additional substituent-substituted or unsubstituted aryl having 6 to 20 carbon atoms, or, a second additional substituent-substituted or unsubstituted heteroaryl having 5 to 20 carbon atoms,
R16 to R45, each independently, represent a bond with X such that the Y connected thereto corresponds to J in Formula 1; or, a bond with Q such that the Y connected thereto corresponds to L in Formula 1; or, is hydrogen, deuterium, alkyl having 1 to 20 carbon atoms, a second additional substituent-substituted or unsubstituted aryl of 6 to 20 carbon atoms, a second additional substituent-substituted or unsubstituted heteroaryl having 5 to 20 carbon atoms, alkylamine having 1 to 20 carbon atoms, a second additional substituent-substituted or unsubstituted arylamine having 6 to 30 carbon atoms, a second additional substituent-substituted or unsubstituted alkylarylamine having 7 to 30 carbon atoms, halogen, CN, alkoxy having 1 to 20 carbon atoms, a second additional substituent-substituted or unsubstituted aryloxy having 6 to 30 carbon atoms, alkylsilyl having 3 to 20 carbon atoms, a second additional substituent-substituted or unsubstituted arylsilyl having 6 to 30 carbon atoms, a second additional substituent-substituted or unsubstituted alkylarylsilyl having 7 to 30 carbon atoms, alkylthiol having 3 to 20 carbon atoms, arylthiol having 6 to 30 carbon atoms, or, arylphosphine oxide having 6 to 30 carbon atoms, and at least two of R16 to R45 can be connected to each other to form a ring,
the first additional substituent is selected from the group consisting of deuterium, alkyl having 1 to 20 carbon atoms, halogen, cyano, aryl having 6 to 30 carbon atoms, alkylsilyl having 1 to 20 carbon atoms, arylsilyl having 6 to 20 carbon atoms, alkylamine having 1 to 20 carbon atoms, arylamine having 6 to 20 carbon atoms, heteroaryl having 5 to 30 carbon atoms, alkoxy having 1 to 20 carbon atoms, aryloxy having 6 to 30 carbon atoms, alkylthiol having 3 to 20 carbon atoms, arylthiol having 6 to 30 carbon atoms, arylphosphine oxides having 6 to 30 carbon atoms and combinations thereof, and
the second additional substituent is deuterium, alkyl having 1 to 20 carbon atoms, alkoxy having 1 to 20 carbon atoms, halogen, cyano group, carboxyl, carbonyl, amine, alkylamine having 1 to 20 carbon atoms, nitro, alkylsilyl having 1 to 20 carbon atoms, alkoxysilyl having 1 to 20 carbon atoms, arylsilyl having 6 to 30 carbon atoms, aryl having 6 to 30 carbon atoms, arylamine having 6 to 30 carbon atoms, heteroaryl having 5 to 30 carbon atoms, aryl phosphine oxide having 6 to 30 carbon atoms, arylphosphinyl having 6 to 30 carbon atoms, alkylphosphine oxide having 6 to 30 carbon atoms, alkylsulfonyl having 6 to 30 carbon atoms and combinations thereof,
provided that (i) the Y connected to one of R16 to R45 corresponds to J in Formula 1, and another Y adjacent to the Y corresponding to J corresponds to L in Formula 1; or,
(ii) one of W is N—Ar2, where Ar2 is a second additional substituent-substituted or unsubstituted aryl having 6 to 20 carbon atoms, or, a second additional substituent-substituted or unsubstituted heteroaryl having 5 to 20 carbon atoms, and one of ring members of aryl or heteroaryl of Ar2 is carbon and corresponds to J in Formula 1, and another ring member adjacent thereto corresponds to L in Formula 1.

### Advantageous Effects

The organic light emitting diode including the multifunctional emitting compound of the present disclosure increases the light emission stability of the device and minimizes the decrease in brightness even when driven for a long time.

In addition to the effects described above, specific effects of the present disclosure will be described together while explaining specific details for carrying out the present disclosure.

### DESCRIPTION OF DRAWINGS

FIG. 1 shows the HOMO-LUMO energy levels of a host and a dopant.

### BEST MODE

Hereinafter, embodiments of the present disclosure will be described in detail in such a manner that the disclosure may be easily carried out by those skilled in the art to which the present disclosure pertains. The present disclosure may exist as different embodiments and should not be construed as being limited to the ones set forth herein.

As used herein, the term “substituted” means that a hydrogen atom bonded to a carbon atom in a compound is substituted with another substituent. The position where substitution occurs means the position where a hydrogen atom is substituted. The position is not limited as long as hydrogen at the position can be substituted with a substituent. When two or more substitutions occur, the two or more substituents may be the same or different.

As used herein, a substituent in the case of being “substituted”, unless otherwise stated, may be one selected from the group consisting of, for example, deuterium, an alkyl group having 1 to 20 carbon atoms, an alkoxy group having 1 to 20 carbon atoms, a halogen, a cyano group, a carboxy group, a carbonyl group, an amine group, and an alkylamine group having 1 to 20 carbon atoms, a nitro group, an alkylsilyl group having 1 to 20 carbon atoms, an alkoxysilyl group having 1 to 20 carbon atoms, a cycloalkyl silyl group having 3 to 30 carbon atoms, an arylsilyl group having 6 to 30 carbon atoms, an aryl group having 6 to 30 carbon atoms, an arylamine group having 6 to 30 carbon atoms, a heteroaryl group having 5 to 30 carbon atoms, an aryl phosphine oxide group having 6 to 30 carbon atoms, an aryl phosphinyl group having 6 to 30 carbon atoms, an alkyl phosphine oxide group having 6 to 30 carbon atoms, an alkylsulfonyl group having 6 to 30 carbon atoms and their combinations, but is not limited thereto.

Throughout the entire specification, the case where two substituents are connected to form a ring includes the case where one of the two substituents is hydrogen and this hydrogen is removed upon being connected.

Throughout the entire specification, alkyl includes cycloalkyl and heterocycloalkyl. For example, alkyl amine includes cycloalkyl amine and heterocycloalkyl amine.

One embodiment of the present disclosure provides an organic light emitting diode comprising the first electrode, the second electrode and an emission layer interposed between the first electrode and the second electrode,
wherein the emission layer includes a multifunctional emitting compound represented by Formula 1 below,
the multifunctional emitting compound includes an emitting moiety and a charge stabilizing moiety, the emitting moiety and the charge stabilizing moiety are connected through an atom X and the atom X is X indicated in Formula 1 below,
the emitting moiety includes a ring A, a conjugated ring formed with Y¹ to Y⁵ being included, and Q in Formula 1 below,
the charge stabilizing moiety includes a conjugated ring formed with Y⁶ to Y¹⁰ being included, a conjugated ring formed with Y¹¹ to Y¹⁵ being included, and Z in Formula 1 below,
the charge stabilizing moiety comprises at least one atom having an unshared pair of electrons.

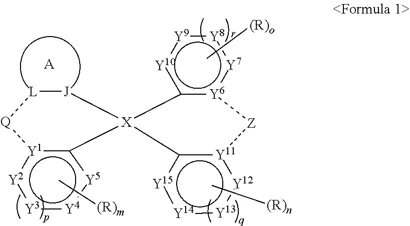

In Formula 1,
a ring A is a fused ring represented by Formula 2, Formula 3 or Formula 4 below,
L represents a linking site in the ring A,
J represents the other linking site in the ring A, and J is linked to X,
X is C, Si, Ge, Sn or Pb,
Q is absent or represents a single bond, or is an atom selected from the group consisting of group IIIA, group IVA, group VA and group VIA elements,
when Q does not exist, L in the ring A is not linked to Y¹,
when Q is a single bond, a single bond which directly connects L in the ring A and Y¹ is formed so as to form a 5-membered ring including X,
when Q is any of atom selected from the elements defined above, a 6-membered ring including X and Q is formed, and the atom as Q can have a substituent(s) selected from the group consisting of alkyl having 1 to 20 carbon atoms, the first additional substituent-substituted or unsubstituted aryl having 6 to 20 carbon atoms, the first additional substituent-substituted or unsubstituted heteroaryl having 5 to 20 carbon atoms and combinations thereof, in accordance with the stoichiometric ratio, and the first additional substituent can connect to Y² or Y²-linked R to form a fused ring, or connect to the ring A to form a fused ring,
Y¹ to Y¹⁵ are, each independently, boron, carbon, nitrogen, oxygen, sulfur, Se or Te,
Z is absent, or is a single bond, oxygen, sulfur, Se, C—(Ar¹)₂, POAr¹ or N—Ar¹, where Ar¹ is alkyl having 1 to 20 carbon atoms, the second additional substituent-substituted or unsubstituted aryl having 6 to 20 carbon atoms or the second additional substituent-substituted or unsubstituted heteroaryl having 5 to 20 carbon atoms, and Ar¹ can connect to any of Y⁷, Y¹², Y⁷-linked R or Y¹²-linked R to form a fused ring,
when Z is absent, Y⁶ and Y¹¹ are not connected,
when Z is a single bond, Y⁶ and Y¹¹ are connected by a single bond,
m, n and o are, each independently, an integer from 0 to 5,
R is, each independently, hydrogen, deuterium, alkyl having 1 to 20 carbon atoms, the second additional substituent-substituted or unsubstituted aryl having 6 to 20 carbon atoms, the second additional substituent-substituted or unsubstituted heteroaryl having 5 to 20 carbon atoms, alkylamine having 1 to 20 carbon atoms, the second additional substituent-substituted or unsubstituted arylamine having 6 to 30 carbon atoms, the second additional substituent-substituted or unsubstituted alkylarylamine having 7 to 30 carbon atoms, halogen, CN, the second additional substituent-substituted or unsubstituted alkoxy having 1 to 20 carbon atoms, aryloxy having 6 to 30 carbon atoms, alkylsilyl having 3 to 20 carbon atoms, the second additional substituent-substituted or unsubstituted arylsilyl having 6 to 30 carbon atoms, the second additional substituent-substituted or unsubstituted alkylarylsilyl having 7 to 30 carbon atoms, alkylthiol having 3 to 20 carbon atoms, the second additional substituent-substituted or unsubstituted arylthiol having 6 to 30 carbon atoms, or the second additional substituent-substituted or unsubstituted arylphosphine oxide having 6 to 30 carbon atoms, and when m, n or o is 2 or more, at least two R present can be connected to each other to form a ring,
p, q and r, each independently, represent 0 or 1; when p, q or r is 0, it means that a 5-membered ring is formed; and when p, q or r is 1, it means that a 6-membered ring is formed;

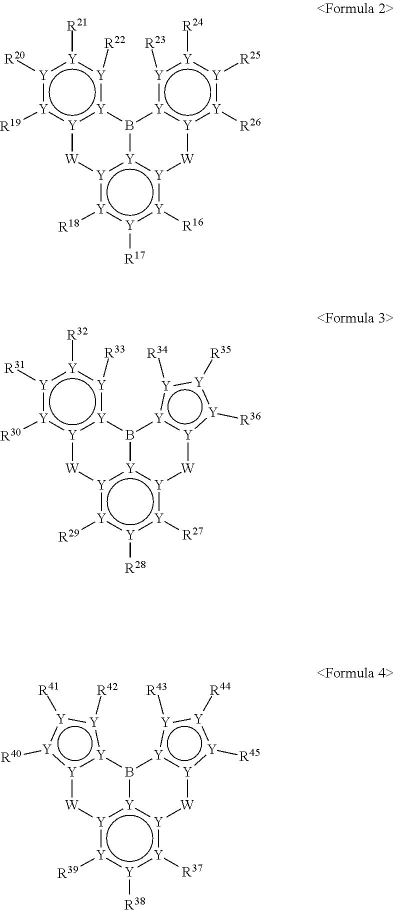

In Formula 2, Formula 3, and Formula 4,
Y is, each independently, carbon, nitrogen, oxygen, sulfur, Se or Te, provided that Y at the position corresponding to J in Formula 1 is carbon,
W is, each independently, oxygen, sulfur, Se, POAr², or N—Ar², and Ar² is alkyl having 1 to 20 carbon atoms, the second additional substituent-substituted or unsubstituted aryl having 6 to 20 carbon atoms, or, the second additional substituent-substituted or unsubstituted heteroaryl having 5 to 20 carbon atoms,
R¹⁶ to R⁴⁵, each independently, represent a bond with X such that the Y connected thereto corresponds to J in Formula 1; or, a bond with Q such that the Y connected thereto corresponds to L in Formula 1; or, is hydrogen, deuterium, alkyl having 1 to 20 carbon atoms, the second additional substituent-substituted or unsubstituted aryl of 6 to 20 carbon atoms, the second additional substituent-substituted or unsubstituted heteroaryl having 5 to 20 carbon atoms, alkylamine having 1 to 20 carbon atoms, the second additional substituent-substituted or unsubstituted arylamine having 6 to 30 carbon atoms, the second additional substituent-substituted or unsubstituted alkylarylamine having 7 to 30 carbon atoms, halogen, CN, alkoxy having 1 to 20 carbon atoms, the second additional substituent-substituted or unsubstituted aryloxy having 6 to 30 carbon atoms, alkylsilyl having 3 to 20 carbon atoms, the second additional substituent-substituted or unsubstituted arylsilyl having 6 to 30 carbon atoms, the second additional substituent-substituted or unsubstituted alkylarylsilyl having 7 to 30 carbon atoms, alkylthiol having 3 to 20 carbon atoms, arylthiol having 6 to 30 carbon atoms, or, arylphosphine oxide having 6 to 30 carbon atoms, and at least two of R¹⁶ to R⁴⁵ can be connected to each other to form a ring,
the first additional substituent is selected from the group consisting of deuterium, alkyl having 1 to 20 carbon atoms, halogen, cyano, aryl having 6 to 30 carbon atoms, alkylsilyl having 1 to 20 carbon atoms, arylsilyl having 6 to 20 carbon atoms, alkylamine having 1 to 20 carbon atoms, arylamine having 6 to 20 carbon atoms, heteroaryl having 5 to 30 carbon atoms, alkoxy having 1 to 20 carbon atoms, aryloxy having 6 to 30 carbon atoms, alkylthiol having 3 to 20 carbon atoms, arylthiol having 6 to 30 carbon atoms, arylphosphine oxides having 6 to 30 carbon atoms and combinations thereof, and
the second additional substituent is deuterium, alkyl having 1 to 20 carbon atoms, alkoxy having 1 to 20 carbon atoms, halogen, cyano group, carboxyl, carbonyl, amine, alkylamine having 1 to 20 carbon atoms, nitro, alkylsilyl having 1 to 20 carbon atoms, alkoxysilyl having 1 to 20 carbon atoms, arylsilyl having 6 to 30 carbon atoms, aryl having 6 to 30 carbon atoms, arylamine having 6 to 30 carbon atoms, heteroaryl having 5 to 30 carbon atoms, aryl phosphine oxide having 6 to 30 carbon atoms, arylphosphinyl having 6 to 30 carbon atoms, alkylphosphine oxide having 6 to 30 carbon atoms, alkylsulfonyl having 6 to 30 carbon atoms and combinations thereof,
provided that (i) the Y connected to one of R¹⁶ to R⁴⁵ corresponds to J in Formula 1, and another Y adjacent to the Y corresponding to J corresponds to L in Formula 1; or,
(ii) one of W is N—Ar², where Ar² is the second additional substituent-substituted or unsubstituted aryl having 6 to 20 carbon atoms, or, the second additional substituent-substituted or unsubstituted heteroaryl having 5 to 20 carbon atoms, and one of ring members of aryl or heteroaryl of Ar² is carbon and corresponds to J in Formula 1, and another ring member adjacent thereto corresponds to L in Formula 1.

When at least two R in Formula 1 are connected to form a ring, such a ring includes a fused ring. In addition, the case where two R are connected includes the case where any one of the two R connected is hydrogen, and the hydrogen R is removed while the other of the two directly connects to any one of Y¹ to Y¹⁵ to which the hydrogen has been linked.

In Formulae 2 to 4, when at least two of R¹⁶ to R⁴⁵ are connected to each other to form a ring, such a ring includes a fused ring. In addition, the case where two of R¹⁶ to R⁴⁵ are connected includes the case where one of the two connected is hydrogen, and the hydrogen is removed while the other of the two connected directly connects to Y to which the hydrogen has been linked.

The organic light emitting diode realizes an organic light emitting diode that minimizes brightness reduction even when driven for a long time by increasing the light emitting stability of the device by using the novel multifunctional emitting compound represented by Formula 1.

Generally, a dopant plays a decisive role in reducing brightness according to operating time of an organic light emitting diode, in addition to the emission wavelength and efficiency of the organic light emitting diode. The multifunctional emitting compound is developed to exhibit stable brightness even when the device is driven for a long time by improving a dopant deterioration mechanism and an energy transfer process.

The electrons and the holes injected into the emission layer are combined at the host of the emission layer to form excitons, and the process in which the energy is transferred to the dopant is described by the method by light of Equation 1 below (FRET, Förster Resonance Energy transfer) and the method by electrons of Equation 2 below (Dexter Electron Transfer).

FRET (Förster Resonance Energy transfer)

$${k}_{ET} = ( \frac{1}{{r}^{6} {τ}_{D}} ) ( \frac{2.07 {κ}^{2} {Q}_{D} J}{128 {π}^{5} {N}_{A} {n}^{4}} ) \qquad [ Equation 1 ]$$

### Dexter Electron Transfer

$${k}_{ET} ∝ J {exp}^{( - \frac{2 r}{L} )} \qquad [ Equation 2 ]$$

K_{ET}: rate constant
r: distance between an energy donor and an energy acceptor
τ_{D}: PL decay time of an energy donor
κ: orientation factor
Q_{D}: PL quantum efficiency of an energy donor
N_{A}: Avogadro's number
n: refractive index
J: defined as Equation 3 as below.

$$J = \int {f}_{D} ( λ ) {ε}_{A} ( λ ) {λ}^{4} d λ \qquad [ Equation 3 ]$$

f_{D}: emission spectrum of an energy donor
ε_{A}: extinction coefficient according to the wavelength of an energy donor
L: the sum of Van der Waals radii
λ: wavelength

Once the dopant receives energy from the host, it becomes excited. That is, it is in the same state as when one of the two electrons present in the HOMO (Highest Occupied Molecular Orbital) level of the dopant has moved to the LUMO (Lowest Unoccupied Molecular Orbital) level. It takes a few nanoseconds to several milliseconds depending on the spin state of the electrons until the electron in the LUMO level descends to the HOMO level and is stabilized again. Considering that the vibrational motion time of a molecule takes place on the order of several picoseconds, the dopant in the excited state constantly interacts with the surrounding molecules before being relaxed by light. A new energy level may be created, a chemical reaction may occur, or a decomposition may occur. These series of processes accelerate the decrease in light emission intensity according to the operating time of the organic light emitting diode.

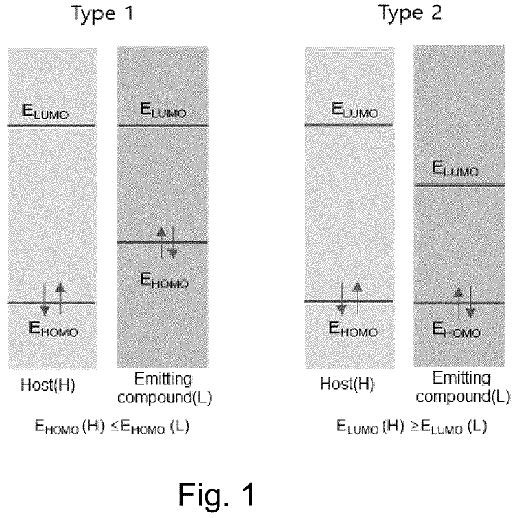

The HOMO-LUMO gap energy of the dopant is always smaller than the HOMO-LUMO gap energy of the host material, but the positions of energy levels between the two materials are not always constant and may appear in two types in FIG. 1. In FIG. 1, EHOMO represents the HOMO energy level of each material, and E_{LUMO} represents the LUMO energy level of each material.

Type 1 is a case where the HOMO energy level of the dopant is higher than the HOMO energy level of the host, and Type 2 is a case where the LUMO energy level of the dopant is lower than the LUMO energy level of the host. Holes are directly injected into the emission layer through the hole transport layer, and electrons are injected into the emission layer through the electron transport layer from the opposite side. Before holes and electrons are injected from the opposite sides of the emission layer with a thickness of 200 to 500 Å and thus the two charges meet to form excitons, holes are trapped (Type 1) or electrons are trapped (Type 2) in the dopant.

Once the charge is trapped in the dopant, the ionized dopant is very unstable and finds a way to stabilize until the opposite charge arrives. It interacts with other excitons already formed around it, or it causes chemical reactions with the surrounding compounds. Sometimes, it decomposes. These series of processes accelerate the decrease in light emission intensity according to the operating time of the organic light emitting device.

When the multifunctional emitting compound is in an excited state or in an ionized state, the emitting moiety is stabilized by the charge stabilizing moiety at a very close distance, so that the organic light emitting device can maintain stable brightness even when the organic light emitting device has been driven for a long time.

The emitting moiety and the charge stabilizing moiety of the multifunctional emitting compound are as defined in Formula 1 above.

Specifically, the charge stabilizing moiety includes a conjugated ring formed with Y⁶ to Y¹⁰ being included, a conjugated ring formed with Y¹¹ to Y¹⁵ being included, and Z in Formula 1 above.

The first role of the charge stabilizing moiety is to stabilize the emitting moiety that is ionized when charges are trapped in the emitting moiety, or excited.

The second role of the charge stabilizing moiety is to spatially protect a certain region of the emitting moiety to reduce the probability that the excited or the ionized emitting moiety interacts with other molecules in the vicinity.

The third role of the charge stabilizing moiety is to spatially protect a certain region of the emitting moiety to reduce the probability that charges are directly trapped in the emitting moiety.

In order for the charge stabilizing moiety to play these roles, it needs to have a polarity (Dipole Moment). Specifically, the charge stabilizing moiety includes an atom having at least one unshared pair of electrons and has a polarity greater than 0 Debye.

Examples of the elements having unshared pair of electrons may include nitrogen, phosphorus, arsenic, antimony, oxygen, sulfur, Se, fluorine, chlorine, or bromine, etc. The element having an unshared pair of electrons included in the charge stabilizing moiety may act as an electron donor or an electron acceptor depending on the bonding type, or make the charge stabilizing moiety polar so as to stabilize the emitting moiety. In addition, the element having an unshared pair of electrons necessarily constitutes the HOMO or the LUMO wave function. That is, it should be included in the wave function representing the electron distribution of the HOMO and the LUMO. For example, for the case where a high electron density is formed in the atom having the unshared electron pair in the HOMO wave function of the charge stabilization moiety, the stabilization effect is increased when the emitting moiety has a positive charge. On the other hand, for the case where a high electron density is formed in the atom having the unshared electron pair in the LUMO wave function of the charge stabilization moiety, a stabilization effect can be expected when the emitting moiety is negatively charged. Quantum calculations can be performed using DFT B3LYP 6-31G* as a basis set.

The HOMO-LUMO gap energy of the charge stabilizing moiety should be equal to or greater than the HOMO-LUMO gap energy of the emitting moiety. In this case, the charge stabilizing moiety can stabilize the emitting moiety as described above without receiving energy from the emitting moiety. On the other hand, when the gap energy of the charge stabilizing moiety is smaller than that of the emitting moiety, energy of the emitting moiety may move to the charge stabilizing moiety and light emission may occur from the charge stabilizing moiety.

In one embodiment, for the charge stabilizing moiety,
at least one of Y6 to Y15 and Z in Formula 1 is an atom having an unshared electron pair included in the wave function of the HOMO or the LUMO of the charge stabilizing moiety; or
at least one of Y6 to Y15 in Formula 1 has R represented by Formula 5 or Formula 6 below.

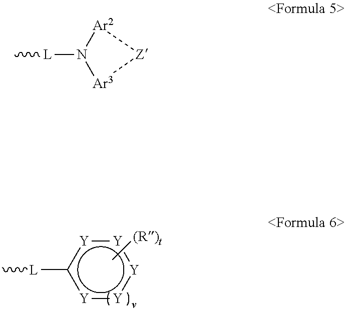

In Formula 5 or Formula 6,
L is a single bond, or a divalent group selected from the group consisting of alkylene having 1 to 20 carbon atoms, alkyl silylene having 1 to 20 carbon atoms, aryl silylene having 1 to 20 carbon atoms, alkylaryl silylene having 1 to 20 carbon atoms, oxygen, sulfur, a divalent group of aryl phosphine having 6 to 20 carbon atoms, a divalent group of aryl phosphine oxide having 6 to 20 carbon atoms, arylene having 6 to 20 carbon atoms, heteroarylene having 5 to 20 carbon atoms and combinations thereof,
Z′ is absent or represents a single bond, or is an atom selected from the group consisting of group IIIA, group IVA, group VA and group VIA elements, and when Z′ is an atom, Z′ can have a substituent(s) selected from hydrogen, alkyl having 1 to 20 carbon atoms, the third additional substituent substituted or unsubstituted aryl having 6 to 20 carbon atoms, the third additional substituent substituted or unsubstituted heteroaryl having 5 to 20 carbon atoms and combinations thereof, in accordance with the stoichiometric ratio,
Ar² and Ar³ are, each independently, alkyl having 1 to 20 carbon atoms, the third additional substituent substituted or unsubstituted aryl having 6 to 20 carbon atoms, or, the third additional substituent substituted or unsubstituted heteroaryl having 5 to 20 carbon atoms, t is an integer from 0 to 5;
v is 0 or 1
R″ is, each independently, selected from the group consisting of hydrogen, deuterium, alkyl having 1 to 20 carbon atoms, the third additional substituent substituted or unsubstituted aryl having 6 to 20 carbon atoms, the third additional substituent substituted or unsubstituted heteroaryl having 5 to 20 carbon atoms, alkylamine having 1 to 20 carbon atoms, the third additional substituent substituted or unsubstituted arylamine having 6 to 30 carbon atoms, the third additional substituent substituted or unsubstituted alkylarylamines having 7 to 30 carbon atoms, halogen, CN, alkoxy having 1 to 20 carbon atoms, the third additional substituent substituted or unsubstituted aryloxy having 6 to 30 carbon atoms, the third additional substituent substituted or unsubstituted alkylsilyl having 1 to 20 carbon atoms, the third additional substituent substituted or unsubstituted arylsilyl having 6 to 30 carbon atoms, the third additional substituent substituted or unsubstituted alkylarylsilyl having 7 to 30 carbon atoms, alkylthiol having 1 to 20 carbon atoms, arylthiol having 6 to 20 carbon atoms, aryl phosphine having 1 to 20 carbon atoms, aryl phosphine oxide having 1 to 20 carbon atoms and combinations thereof, and at least two R″ can be linked to each other to form a ring,
the third additional substituent is selected from the group consisting of alkyl having 1 to 20 carbon atoms, aryl having 6 to 20 carbon atoms, heteroaryl having 5 to 20 carbon atoms, alkylamine having 2 to 20 carbon atoms, alkylarylamine having 7 to 20 carbon atoms, alkylsilyl having 1 to 20 carbon atoms, arylsilyl having 6 to 20 carbon atoms, alkylarylsilyl having 7 to 30 carbon atoms, alkylthiol having 1 to 20 carbon atoms, arylthiol having 6 to 20 carbon atoms and combinations thereof,
Y is, each independently, nitrogen, oxygen, sulfur or carbon, indicates a connection site,
provided that L or R″ in Formula 6 includes at least one atom having an unshared electron pair included in the HOMO or the LUMO wave function of the charge stabilizing moiety, or at least one of Y is nitrogen, oxygen or sulfur.

When at least two R″ of Formula 6 are connected to form a ring, such a ring includes a fused ring. In addition, the case where two R″ are connected includes the case where any one R″ of the two connected is hydrogen, and the hydrogen R″ is removed while the other R″ of the two connected directly connects to Y to which the hydrogen R″ has been linked.

In one embodiment, R represented by Formula 5 or Formula 6 may be represented by any one of the structures of Formulae D-1 to D-38 below. That is, the charge stabilizing moiety may include R represented by any one of Formulae D-1 to D-38.

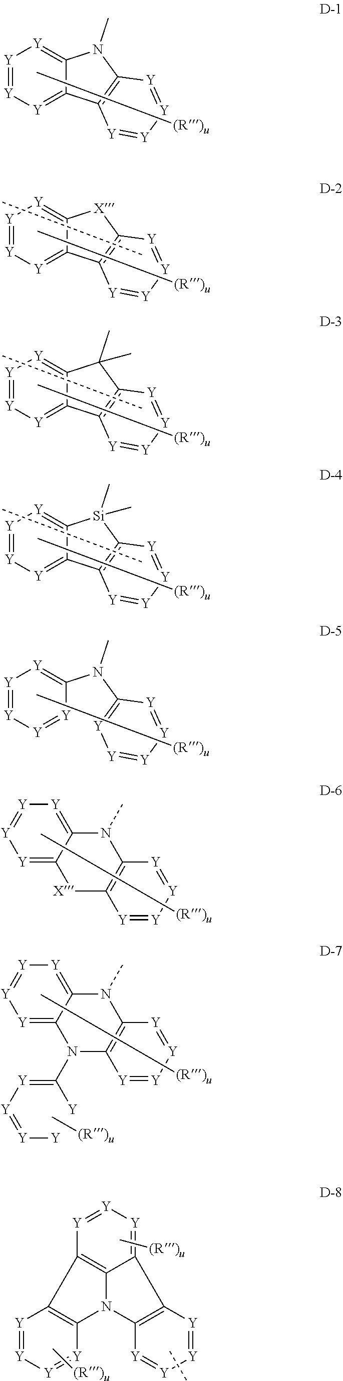

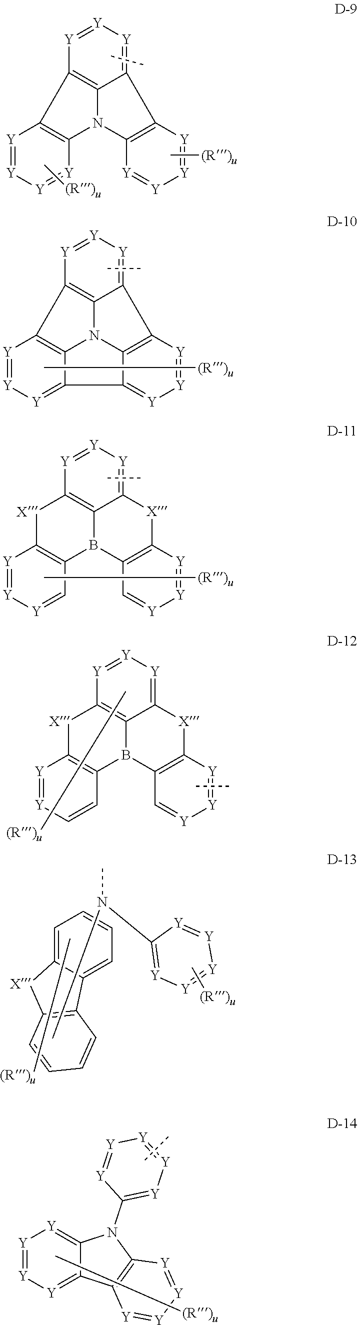

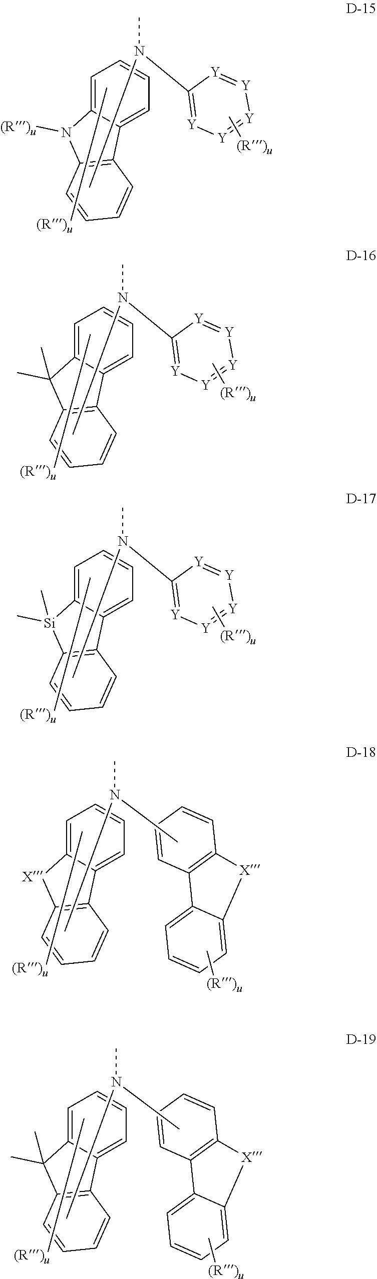

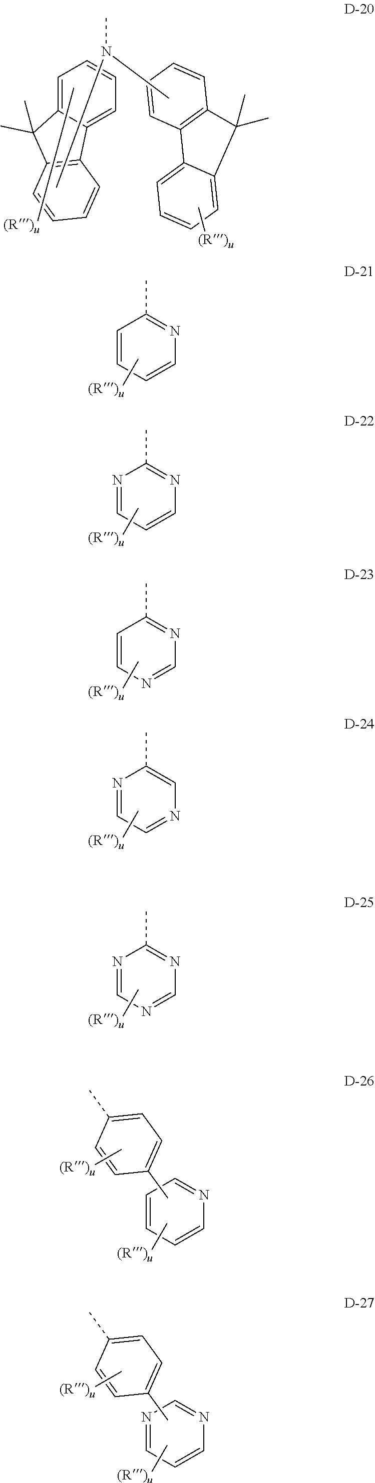

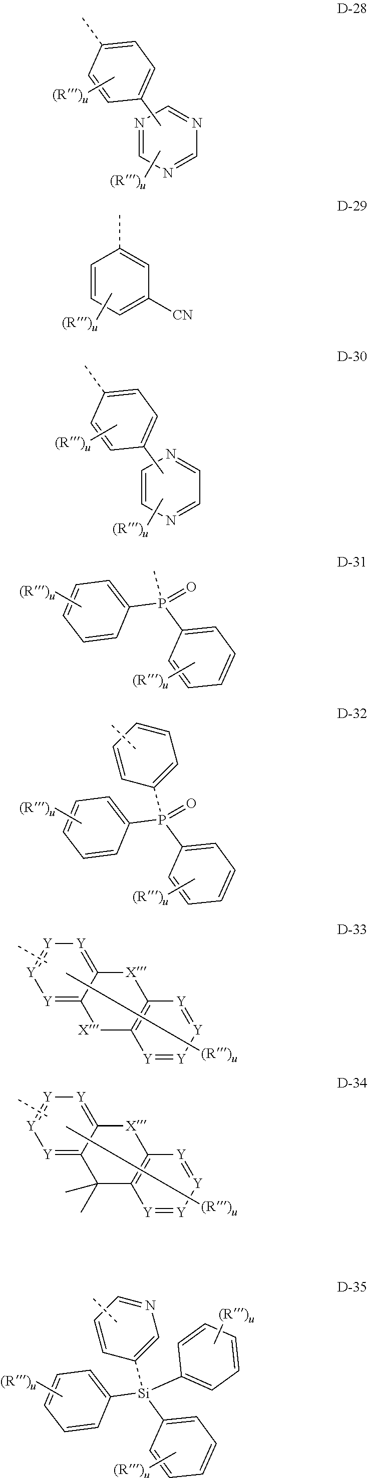

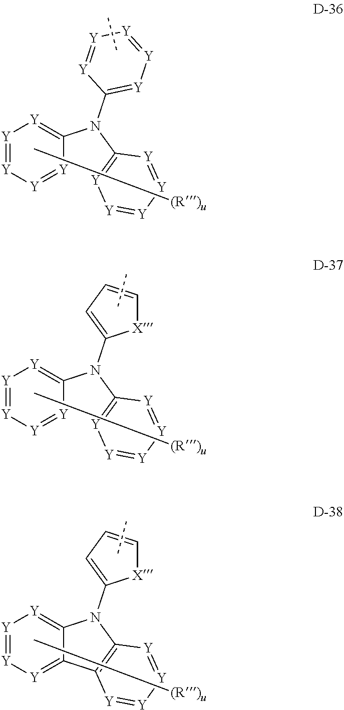

In Formulae D-1 to D-38,
Y is, each independently, carbon or nitrogen,
X″ is, each independently, oxygen, nitrogen, sulfur or selenium,
R″ is, each independently, selected from hydrogen, deuterium, alkyl having 1 to 20 carbon atoms, aryl having 6 to 20 carbon atoms, heteroaryl having 5 to 20 carbon atoms, alkylamine having 2 to 20 carbon atoms, halogen, CN group, alkylsilyl having 4 to 20 carbon atoms, arylsilyl of 6 to 20 carbon atoms and combinations thereof, u is, each independently, an integer from 0 to 20,
the dotted line represents a connection site,
provided that Formulae D-1 to D-38 include at least one atom having an unshared electron pair included in the HOMO or the LUMO wave function of the charge stabilizing moiety.

In the multifunctional emitting compound represented by Formula 1, the charge stabilizing moiety and the emitting moiety are bonded by an atom X, and when Q and Z are present, a spiro connection is formed through a spiro atom X.

The first role of the connection portion by the atom X is to ensure that the charge stabilizing moiety and the emitting moiety exist at a certain distance and space. In this way, when the charge stabilizing moiety maintains a spatial position and an angle that do not cause chemical interaction with the emitting moiety, a certain region of the emitting moiety is protected, thereby obtaining an advantage in that the probability of chemical interaction and Coulomb interaction with other dopant materials, host materials and excitons is significantly lowered.

The second role of the connection portion by the atom X is to spatially minimize the HOMO or the LUMO wave function overlap between the charge stabilizing moiety and the emitting moiety. This is because when significant overlapping of the wave functions occurs due to the overlap of the conjugated structure of the charge stabilizing moiety and the emitting moiety, it may cause the problems such as shifting the emission wavelength of the emitting moiety to a longer wavelength or reducing emitting efficiency.

The connection portion by the atom X may be formed by connecting the charge stabilizing moiety and the emitting moiety through a spiro connection or may be a linking group. The case where the connection portion by the atom X is formed as a linking group is the case where Q or Z in Formula 1 does not exist and thus a spiro connection is not formed.

Specifically, the emitting moiety includes the ring A, the conjugated ring formed with Y¹ to Y⁵ being included, and Q in Formula 1 above.

The emitting moiety emits light by receiving the exciton energy formed in the host.

The emitting moiety may be derived from an emitting material (referred to herein as an emitting compound) capable of emitting light by movement of electrons in an organic light emitting diode.

The emitting compound (the emitting material) may be a compound that can be commonly used as a dopant in an organic light emitting diode. A dopant capable of implementing a desired color may be selected as a light emitting compound according to the purpose, and the emitting moiety may be derived therefrom.

In one embodiment, the emitting moiety may have a conjugated structure having a quantum efficiency of 50% or more in a visible light wavelength range of 400 nm to 700 nm.

In one embodiment, the emitting moiety may have a conjugated structure having a quantum efficiency of 0.5% or more in the 700 nm to 2500 nm near infrared wavelength region.

The light emitting mechanism of the emitting moiety may include fluorescence emitting light from a singlet, phosphorescence emitting light from a triplet, and thermally activated delayed fluorescence emitting light when energy is transferred from a triplet to a singlet.

For example, the ring A may be represented by any one of the following C-1 to C-24.

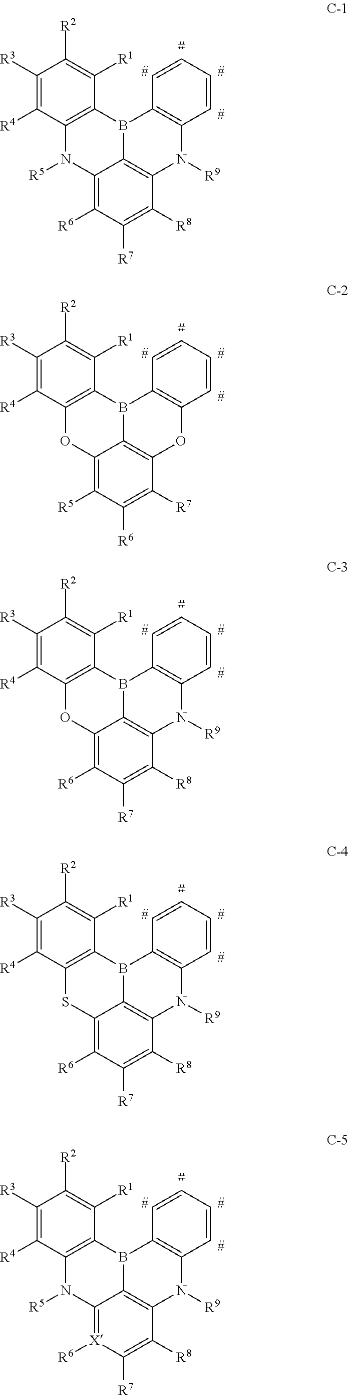

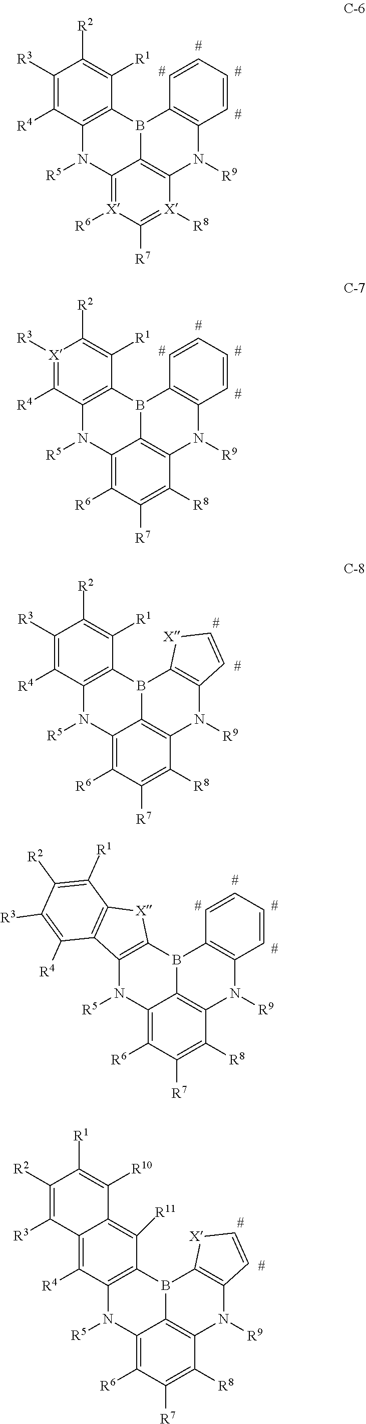

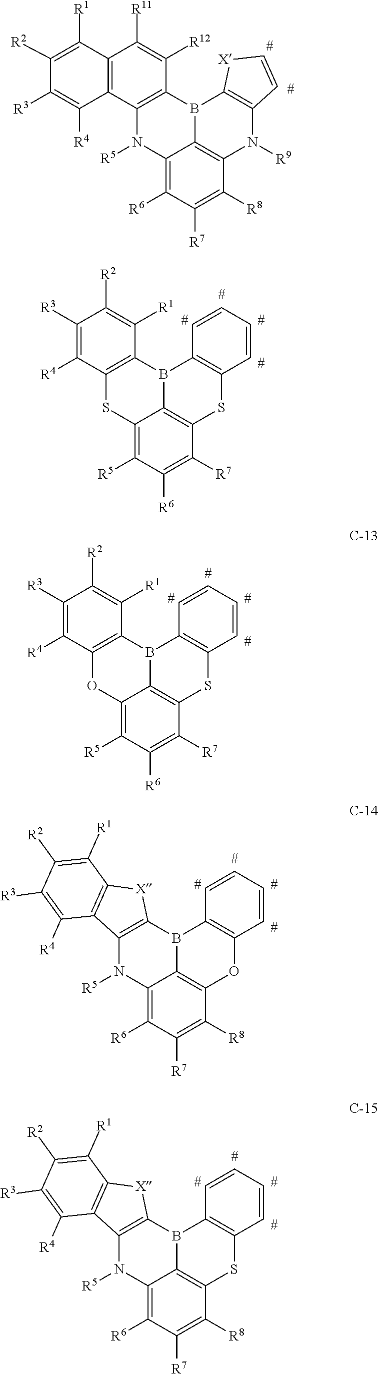

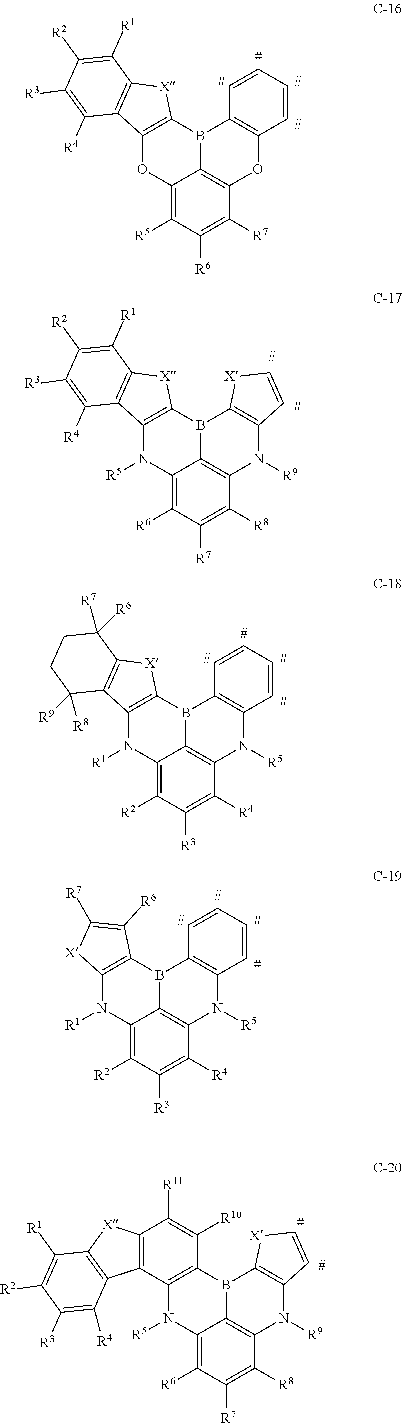

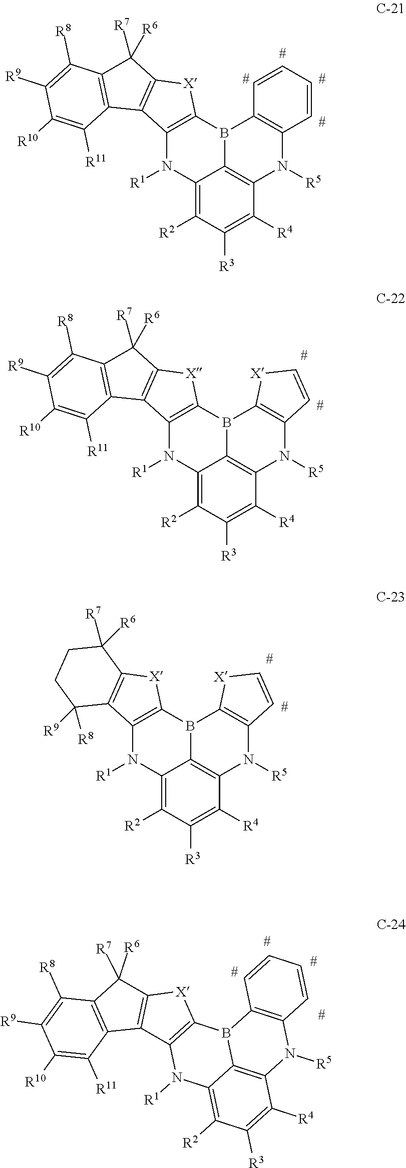

In the above C-1 to C-24,
two adjacent #among #-indicated positions correspond to J or L in the ring A of Formula 1,

R¹ to R¹¹ are, each independently, hydrogen, deuterium, alkyl having 1 to 20 carbon atoms, the second additional substituent-substituted or unsubstituted aryl of 6 to 20 carbon atoms, the second additional substituent-substituted or unsubstituted heteroaryl having 5 to 20 carbon atoms, alkylamine having 1 to 20 carbon atoms, the second additional substituent-substituted or unsubstituted arylamine having 6 to 30 carbon atoms, the second additional substituent-substituted or unsubstituted alkylarylamine having 7 to 30 carbon atoms, halogen, CN, alkoxy having 1 to 20 carbon atoms, the second additional substituent-substituted or unsubstituted aryloxy having 6 to 30 carbon atoms, alkylsilyl having 3 to 20 carbon atoms, the second additional substituent-substituted or unsubstituted arylsilyl having 6 to 30 carbon atoms, the second additional substituent-substituted or unsubstituted alkylarylsilyl having 7 to 30 carbon atoms, alkylthiol having 3 to 20 carbon atoms, arylthiol having 6 to 30 carbon atoms, or, arylphosphine oxide having 6 to 30 carbon atoms, and at least two of R¹ to R¹¹ can be connected to each other to form a ring,
X′ is, each independently, O, S, Se, C, Si, C—(Ar³)₂, Si—(Ar³)₂ or N—Ar³, and Ar³ is alkyl having 1 to 20 carbon atoms, the second additional substituent-substituted or unsubstituted aryl having 6 to 20 carbon atoms, or, the second additional substituent-substituted or unsubstituted heteroaryl having 5 to 20 carbon atoms, and when a plurality of Ar³ exist, a plurality of Ar³ are connected to each other to form a ring,
X″ is, each independently, N, O, S or Se.

The second additional substituent is defined the same as the second additional substituent defined in Formula 1 above.

In C-1 to C-24, when at least two of R¹ to R¹¹ are connected to each other to form a ring, such a ring includes a fused ring. In addition, the case where two of R¹ to R¹¹ are connected includes the case where one of the two connected is hydrogen, and the hydrogen is removed while the other of the two connected directly connects to the ring member of the ring to which the hydrogen has been linked.

In one embodiment, the band gap energy of the charge stabilizing moiety may be 1 eV to 4.7 eV, and the band gap energy of the emitting moiety may be 0.4 eV to 3.5 eV.

The HOMO energy can be measured by methods such as Cyclic Voltammetry (CV), Ultraviolet Photoelectron Spectroscopy (UPS), AC2, etc., and the LUMO energy can be measured by UV absorption spectrum or Cyclic Voltammetry (CV).

In one embodiment, Formula 1 is any one of the formulae represented by the following B-1 to B-32.

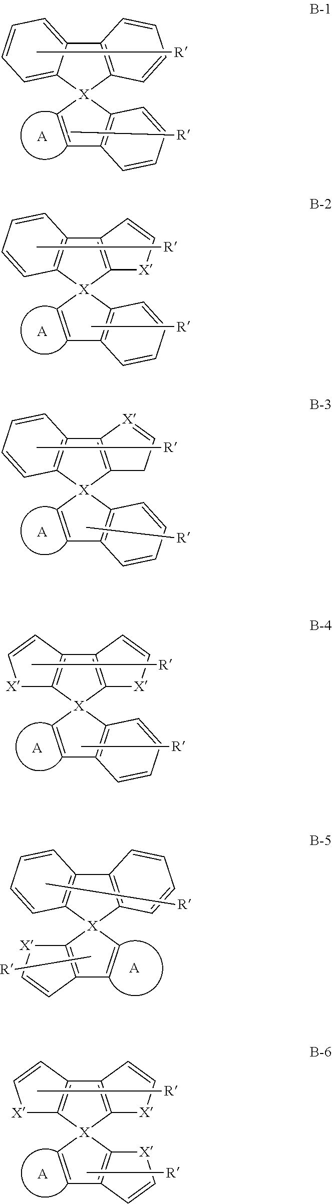

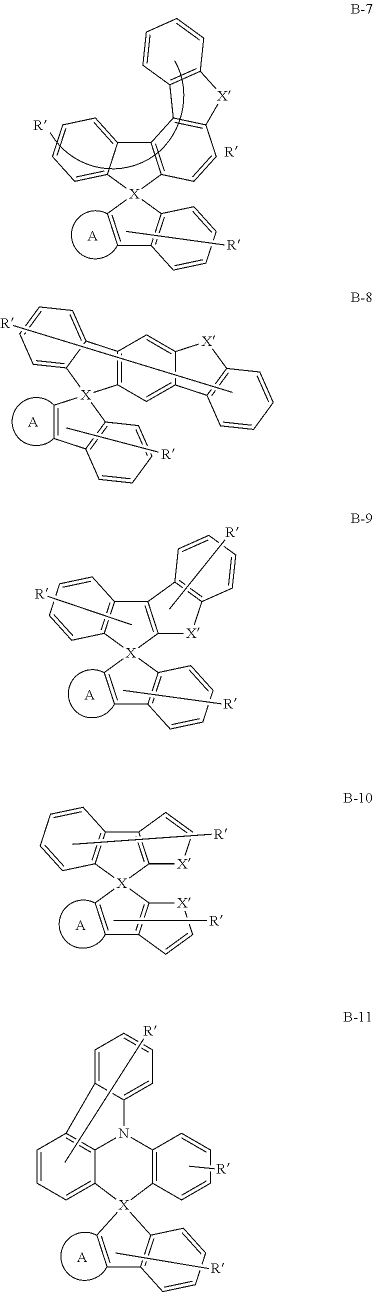

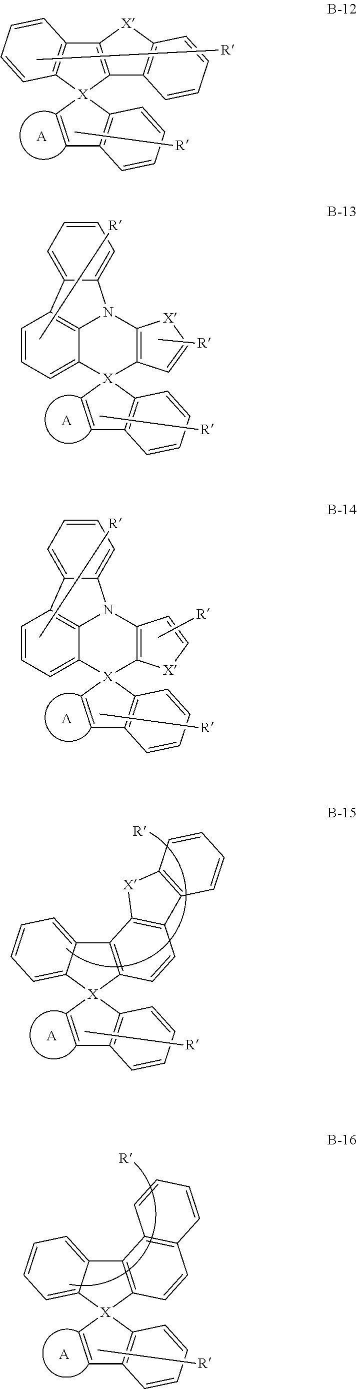

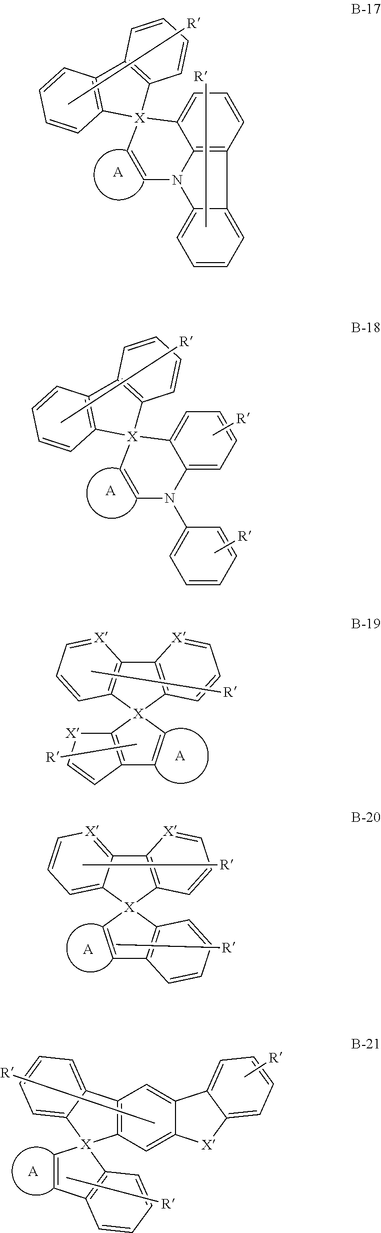

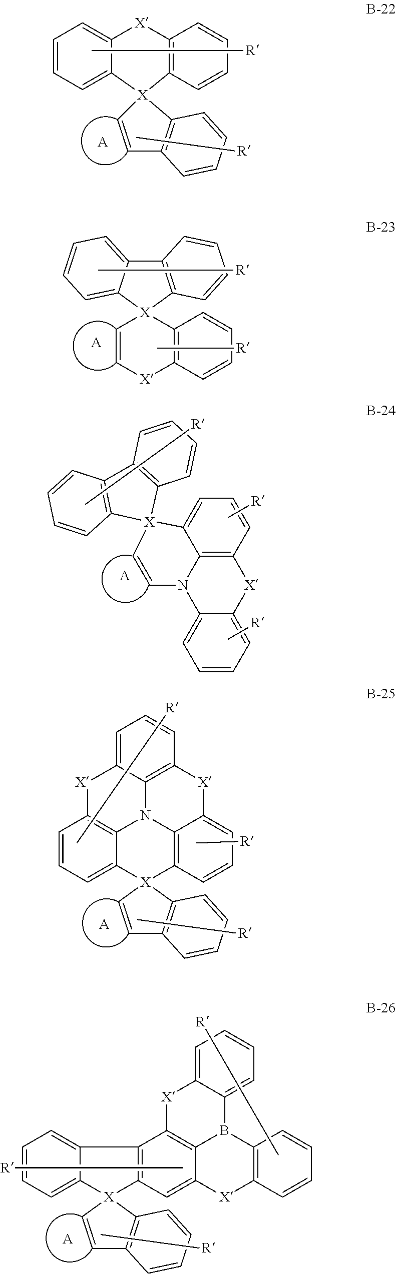

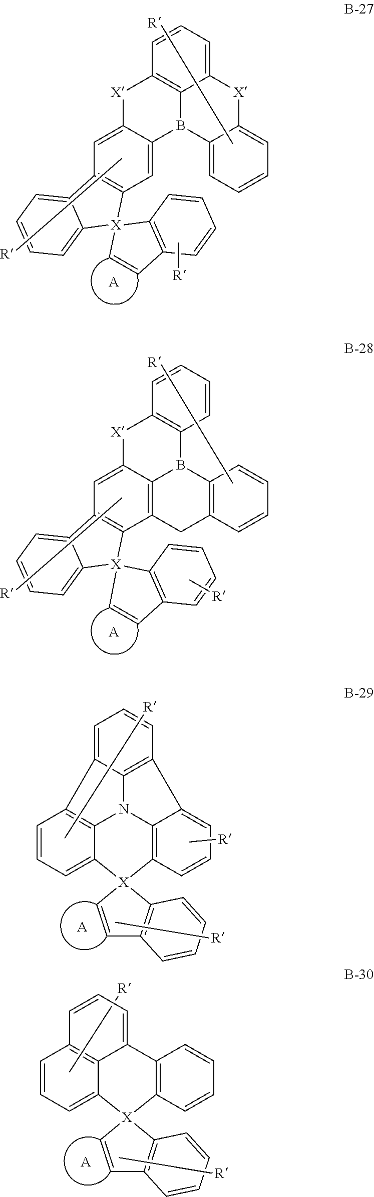

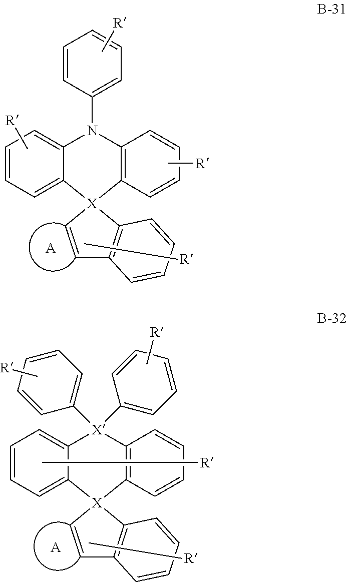

In the above B-1 to B-32,
a ring A is as defined in Formula 1 above,
X is C, Si, Ge, Sn or Pb,
X′ is, each independently, O, S, Se, C, Si, C—(Ar³)₂, Si—(Ar³)₂ or N—Ar³, and Ar³ is alkyl having 1 to 20 carbon atoms, the second additional substituent-substituted or unsubstituted aryl having 6 to 20 carbon atoms, or, the second additional substituent-substituted or unsubstituted heteroaryl having 5 to 20 carbon atoms, and when a plurality of Ar³ exist, a plurality of Ar³ can be connected to each other to form a ring,
R′ is present in a number according to the stoichiometric ratio, and is, each independently, hydrogen, deuterium, alkyl having 1 to 20 carbon atoms, the second additional substituent-substituted or unsubstituted aryl of 6 to 20 carbon atoms, the second additional substituent-substituted or unsubstituted heteroaryl having 5 to 20 carbon atoms, alkylamine having 1 to 20 carbon atoms, the second additional substituent-substituted or unsubstituted arylamine having 6 to 30 carbon atoms, the second additional substituent-substituted or unsubstituted alkylarylamine having 7 to 30 carbon atoms, halogen, CN, alkoxy having 1 to 20 carbon atoms, the second additional substituent-substituted or unsubstituted aryloxy having 6 to 30 carbon atoms, alkylsilyl having 1 to 20 carbon atoms, the second additional substituent-substituted or unsubstituted arylsilyl having 6 to 30 carbon atoms, the second additional substituent-substituted or unsubstituted alkylarylsilyl having 7 to 30 carbon atoms, alkylthiol having 3 to 20 carbon atoms, arylthiol having 6 to 30 carbon atoms, or arylphosphine oxide having 6 to 30 carbon atoms, and at least two of R′ can be connected to each other to form a ring, and
the second additional substituent is defined the same as the second additional substituent defined in Formula 1 above.

In the above B-1 to B-32, when at least two of the R′ are connected to each other to form a ring, such a ring includes a fused ring. In addition, the case where two of R′ are connected includes the case where one of the two connected is hydrogen, and the hydrogen is removed while the other R′ of the two connected directly connects to the ring member of the ring to which the hydrogen has been linked.

In one embodiment, the multifunctional emitting compound may be any of the compounds represented by the following structural formulae.

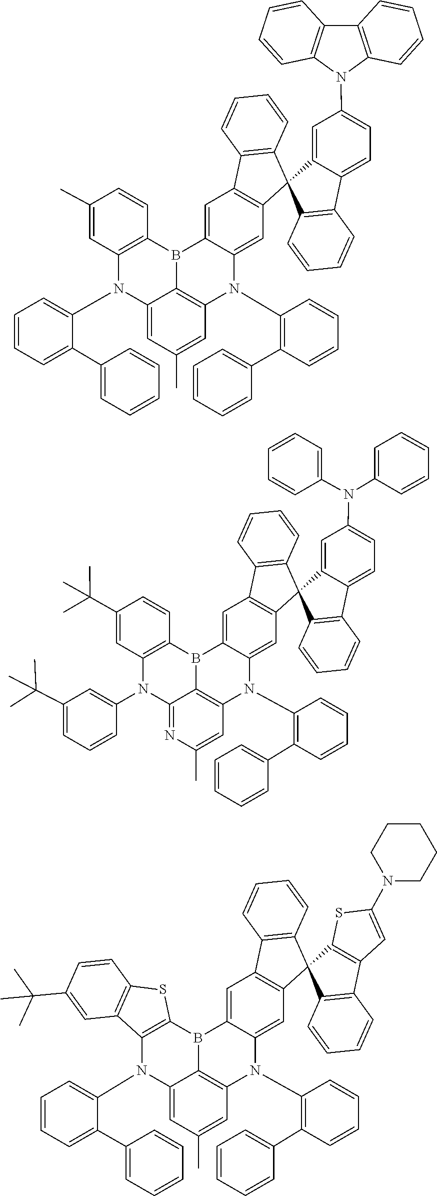 [SMILES: Cc1ccc2c(c1)N(c1ccccc1-c1ccccc1)c1cc(C)cc3c1B2c1cc2c(cc1N3c1ccccc1-c1ccccc1)[C@]1(c3ccccc3-c3ccc(-n4c5ccccc5c5ccccc54)cc31)c1ccccc1-2 ; Cc1cc2c3c(n1)N(c1cccc(C(C)(C)C)c1)c1cc(C(C)(C)C)ccc1B3c1cc3c(cc1N2c1ccccc1-c1ccccc1)[C@]1(c2ccccc2-c2ccc(N(c4ccccc4)c4ccccc4)cc21)c1ccccc1-3 ; Cc1cc2c3c(c1)N(c1ccccc1-c1ccccc1)c1c(sc4ccc(C(C)(C)C)cc14)B3c1cc3c(cc1N2c1ccccc1-c1ccccc1)[C@@]1(c2ccccc2-3)c2ccccc2-c2cc(N3CCCCC3)sc21]

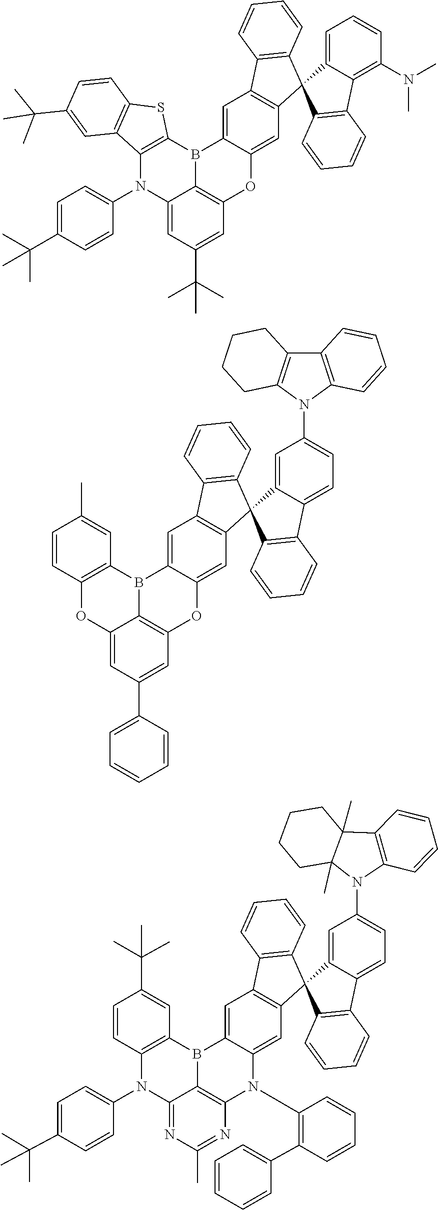

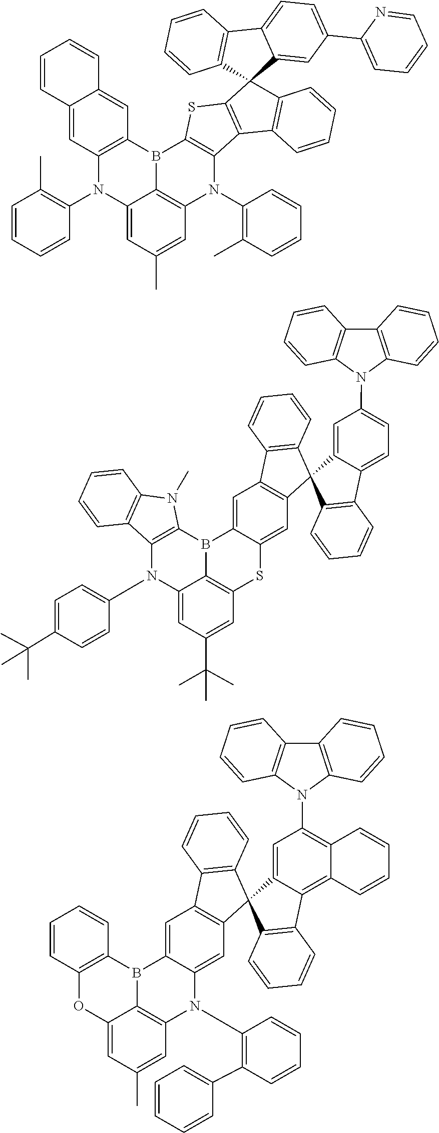

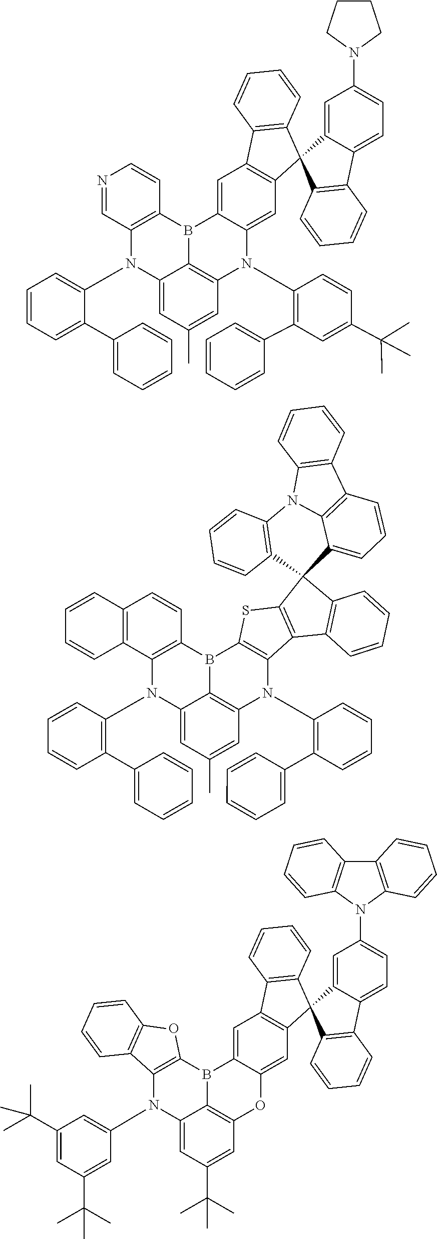

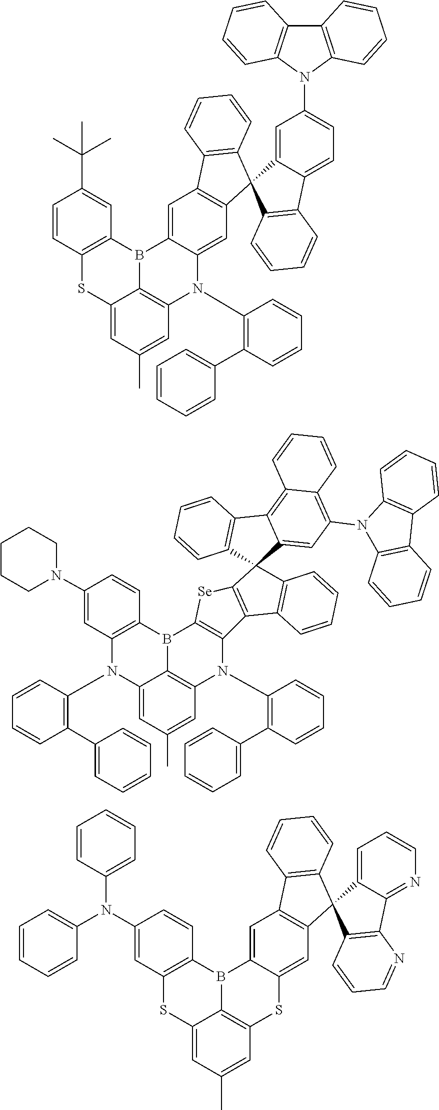

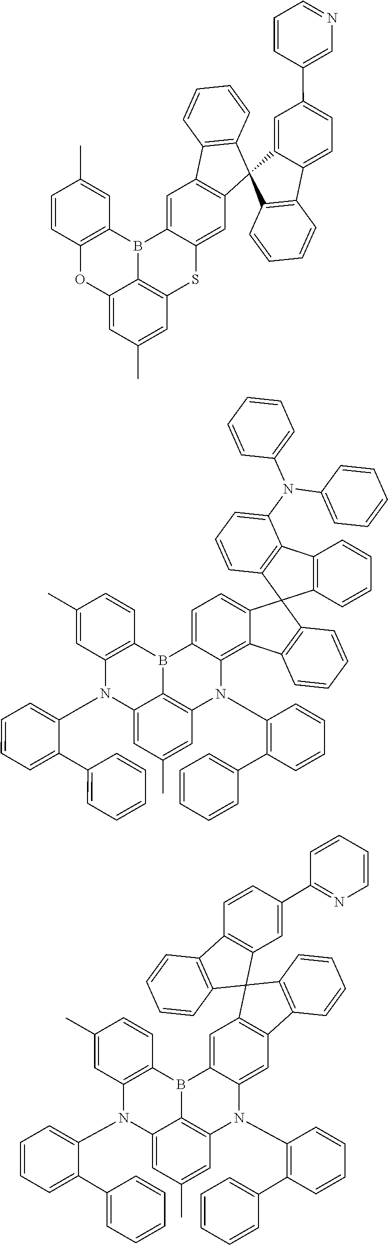 [SMILES: Cc1cc2c3c(c1)Sc1cc4c(cc1B3c1cc(C)ccc1O2)-c1ccccc1[C@@]41c2ccccc2-c2ccc(-c3cccnc3)cc21 ; Cc1ccc2c(c1)N(c1ccccc1-c1ccccc1)c1cc(C)cc3c1B2c1ccc2c(c1N3c1ccccc1-c1ccccc1)-c1ccccc1C21c2ccccc2-c2c(N(c3ccccc3)c3ccccc3)cccc21 ; Cc1ccc2c(c1)N(c1ccccc1-c1ccccc1)c1cc(C)cc3c1B2c1cc2c(cc1N3c1ccccc1-c1ccccc1)-c1ccccc1C21c2ccccc2-c2ccc(-c3ccccn3)cc21]

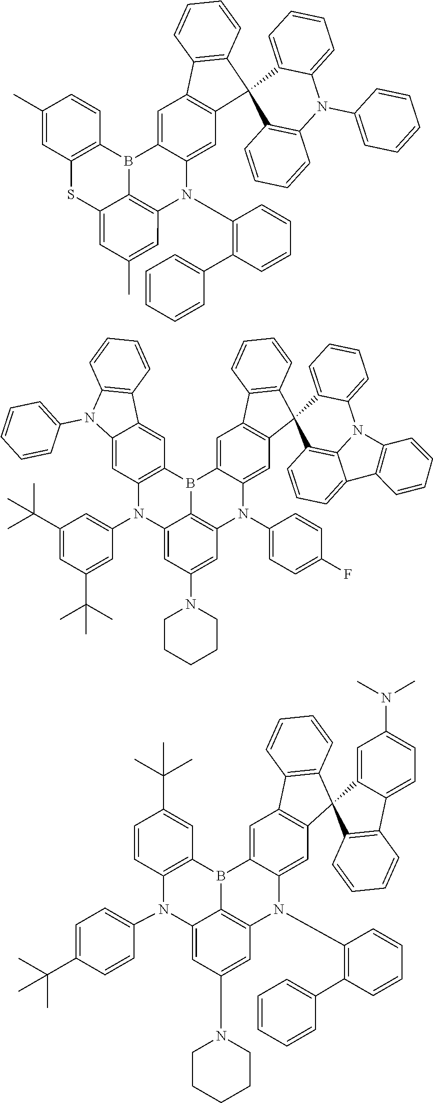

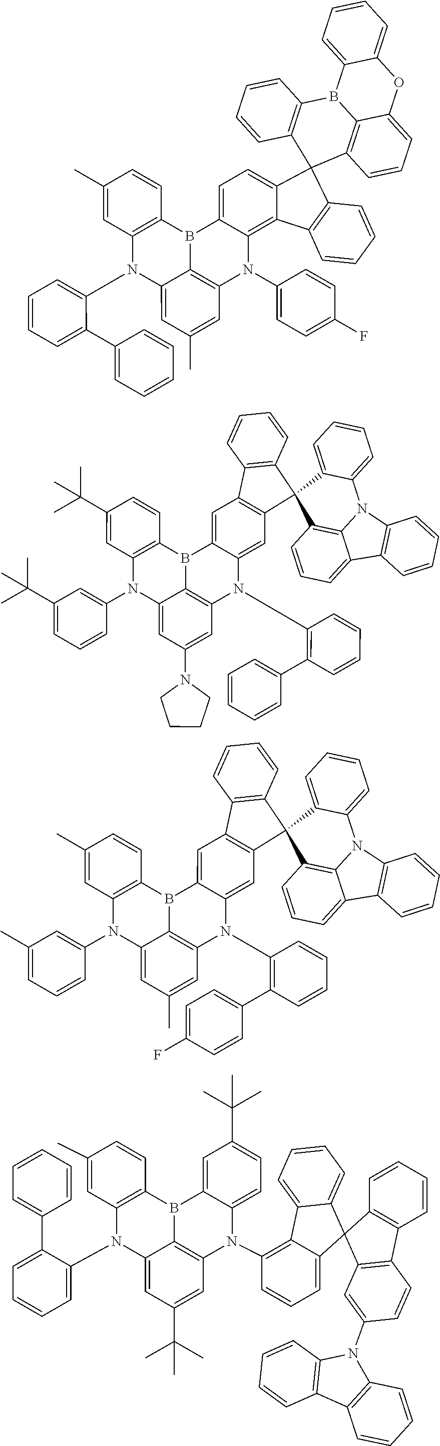

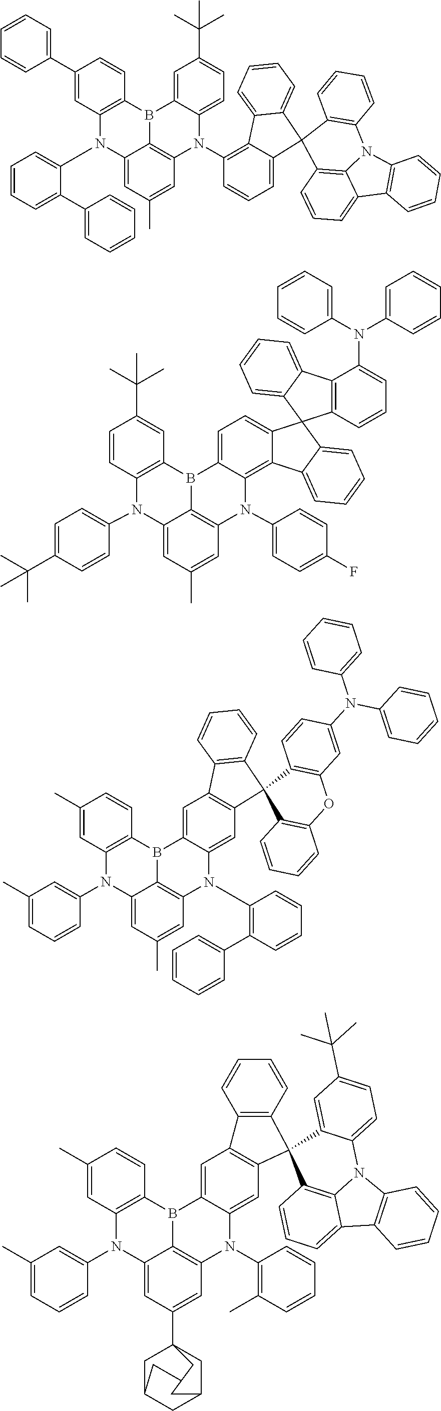

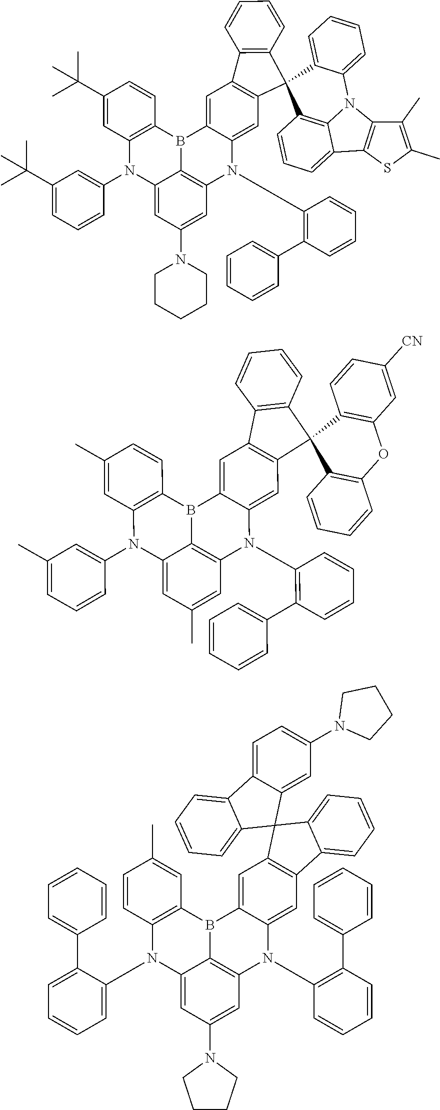

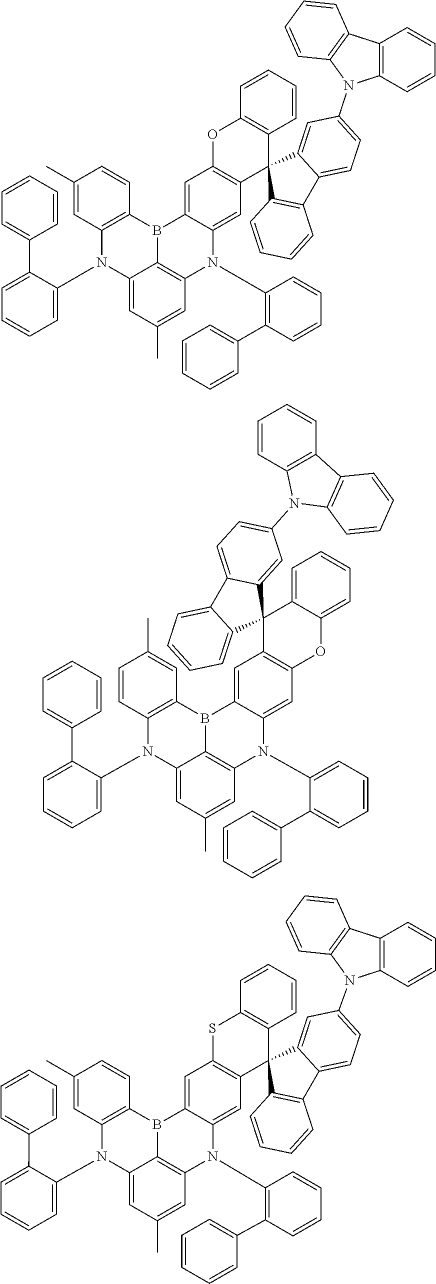

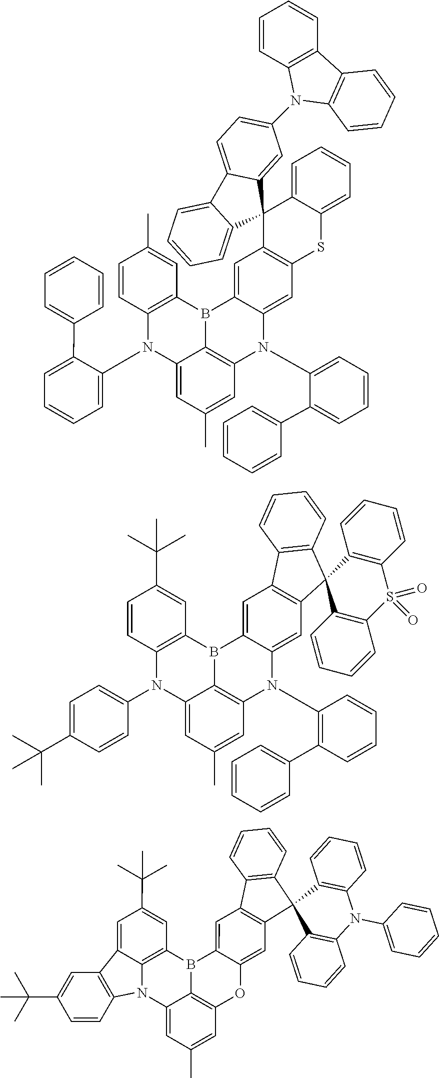

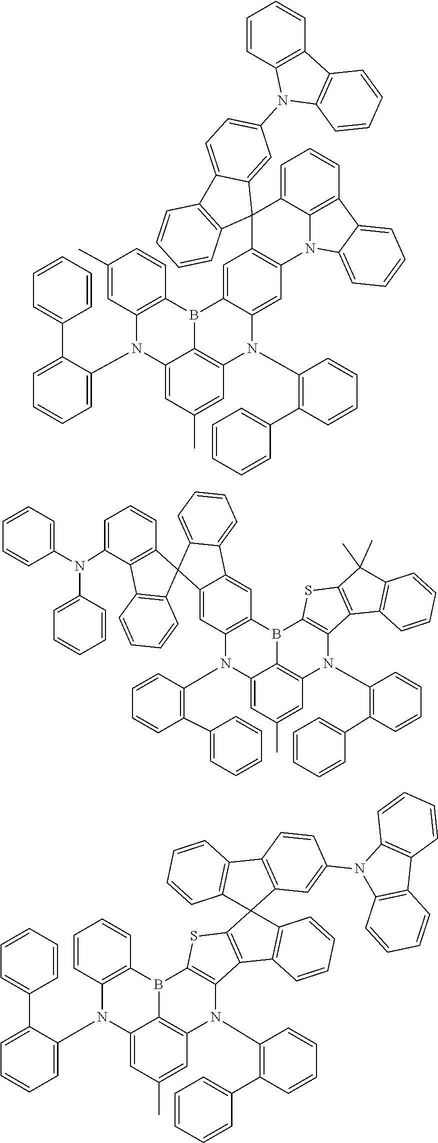

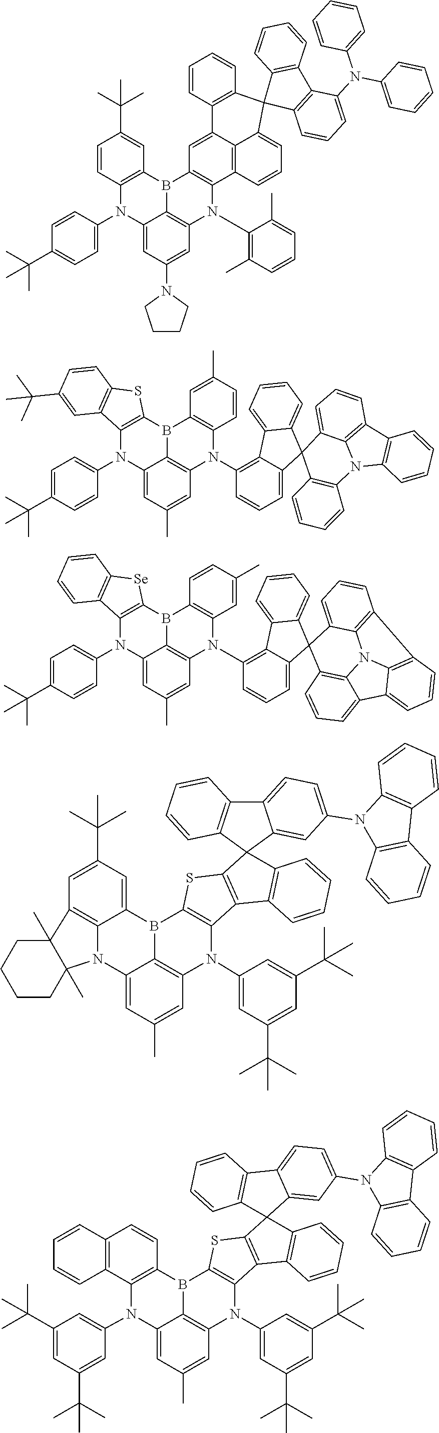

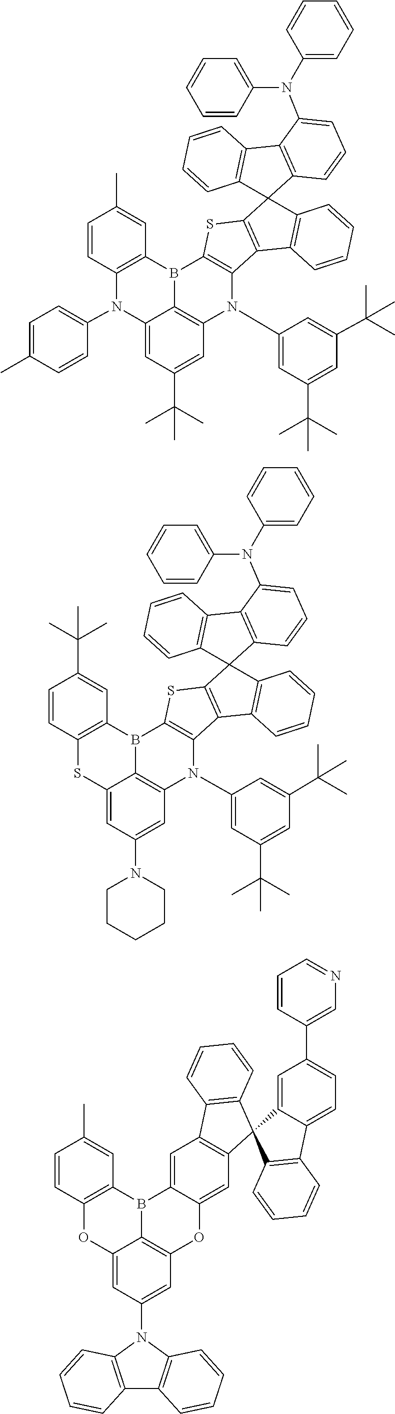

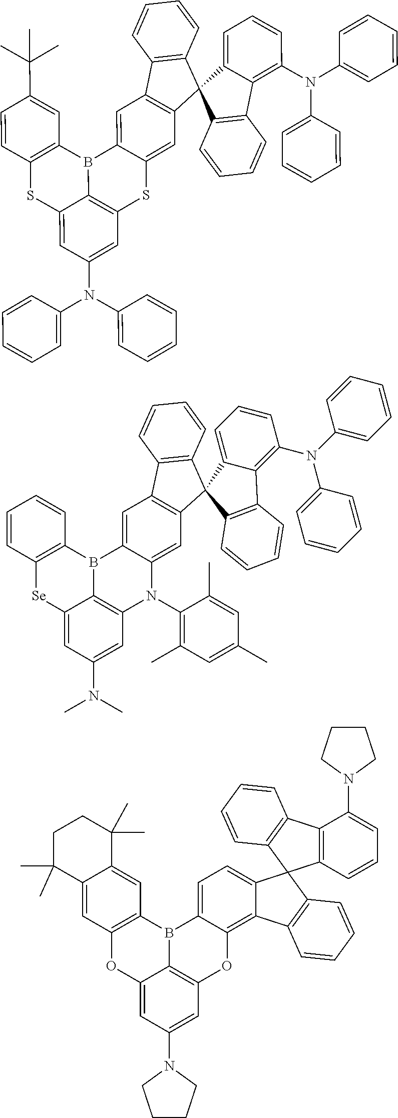

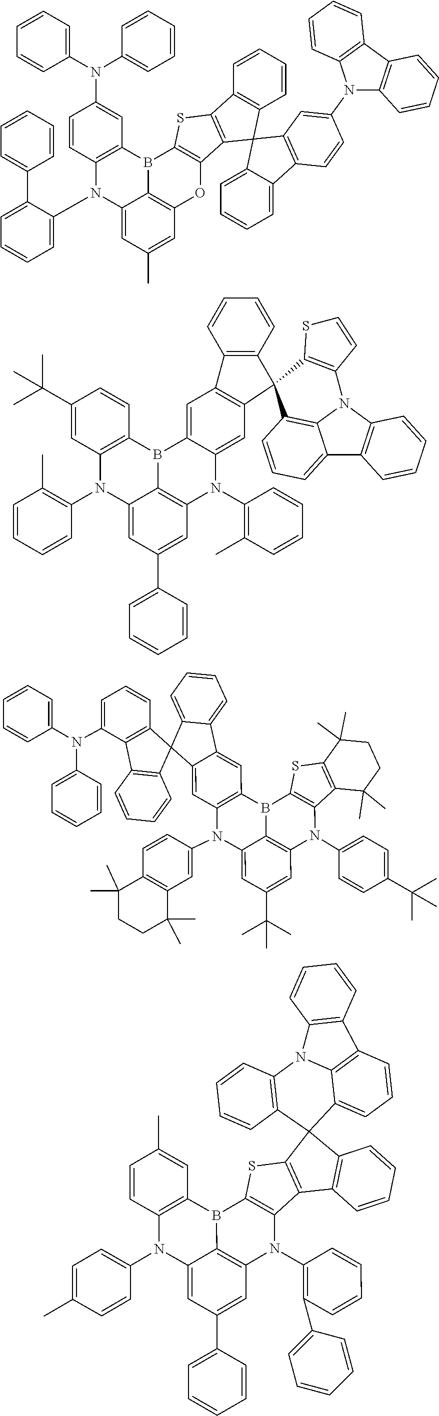

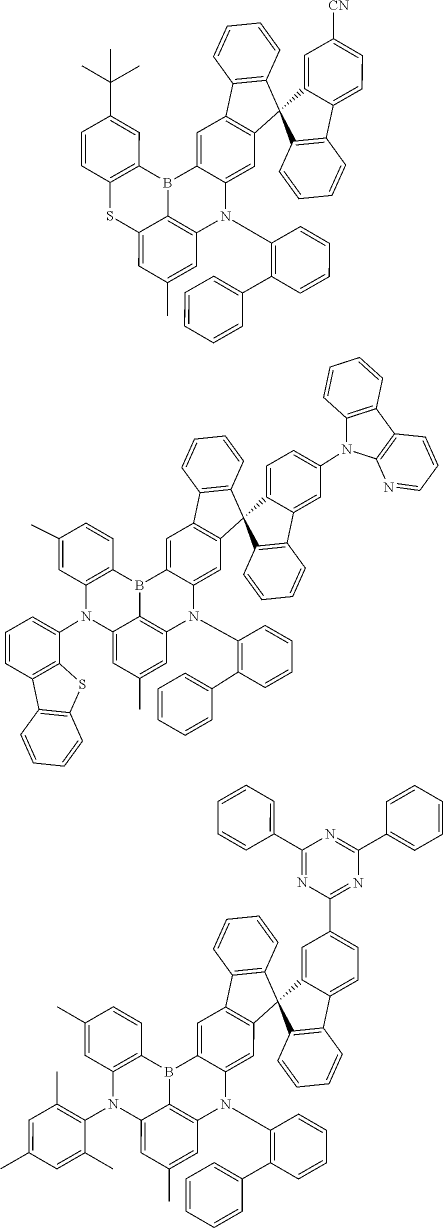 [SMILES: Cc1cc2c3c(c1)N(c1ccccc1-c1ccccc1)c1cc4c(cc1B3c1cc(C(C)(C)C)ccc1S2)-c1ccccc1[C@@]41c2ccccc2-c2ccc(C#N)cc21 ; Cc1ccc2c(c1)N(c1cccc3c1sc1ccccc13)c1cc(C)cc3c1B2c1cc2c(cc1N3c1ccccc1-c1ccccc1)[C@]1(c3ccccc3-c3cc(-n4c5ccccc5c5cccnc54)ccc31)c1ccccc1-2 ; Cc1cc(C)c(N2c3cc(C)ccc3B3c4cc5c(cc4N(c4ccccc4-c4ccccc4)c4cc(C)cc2c43)[C@]2(c3ccccc3-c3ccc(-c4nc(-c6ccccc6)nc(-c6ccccc6)n4)cc32)c2ccccc2-5)c(C)c1]

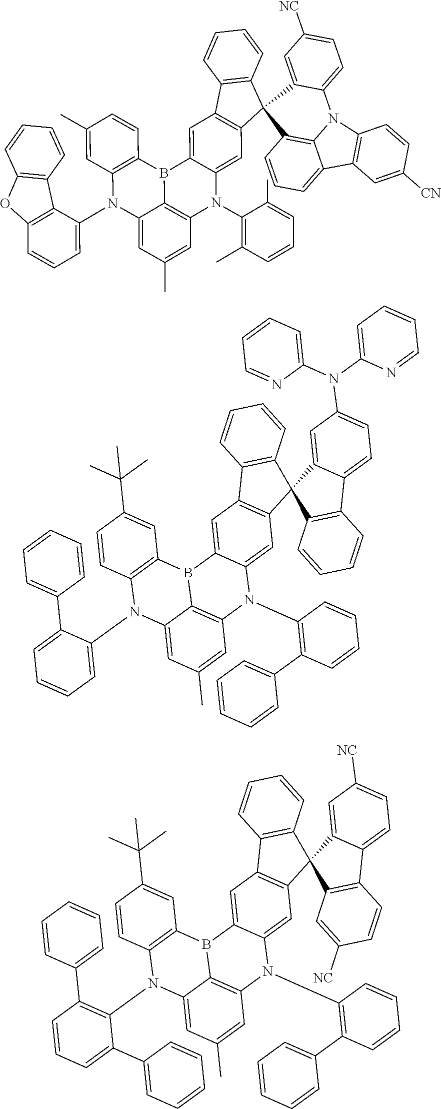

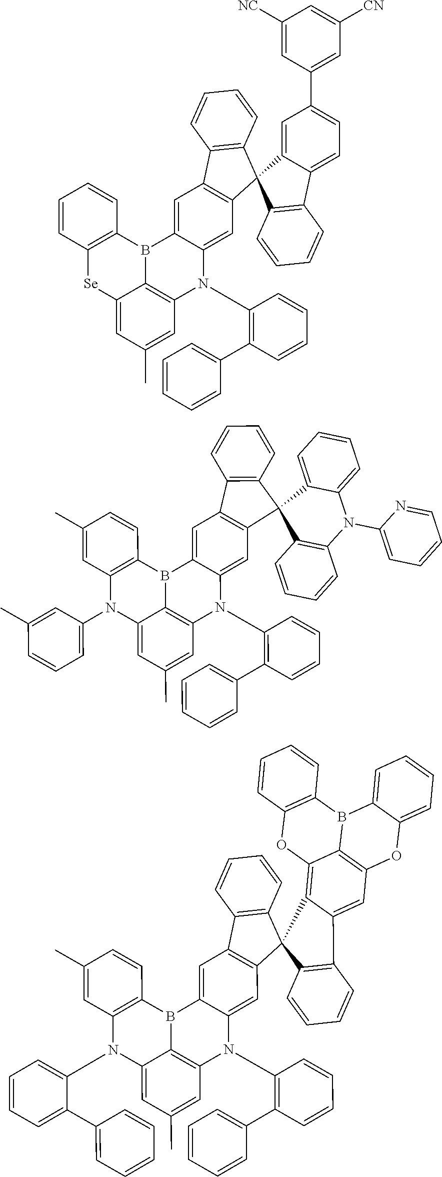

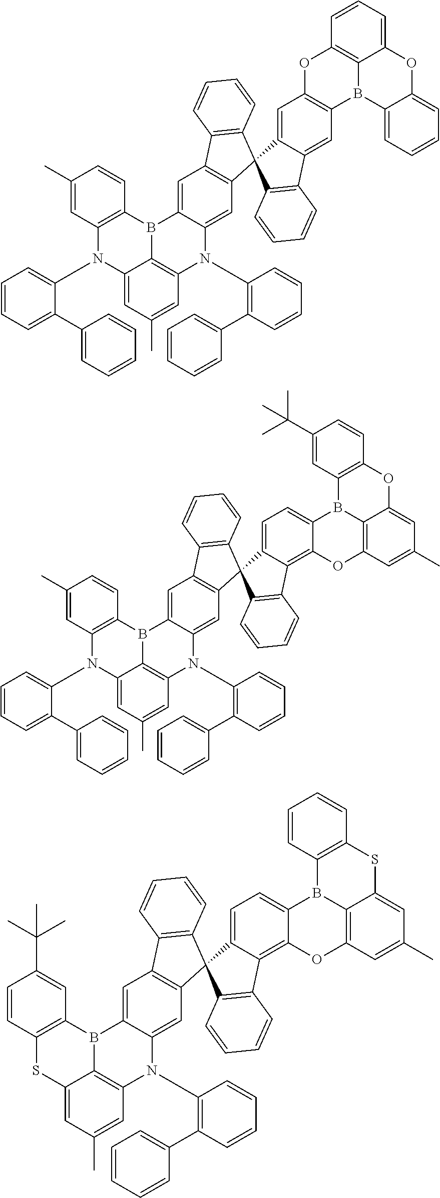 [SMILES: Cc1ccc2c(c1)N(c1ccccc1-c1ccccc1)c1cc(C)cc3c1B2c1cc2c(cc1N3c1ccccc1-c1ccccc1)[C@]1(c3ccccc3-c3cc4c(cc31)Oc1cccc3c1B4c1ccccc1O3)c1ccccc1-2 ; Cc1cc2c3c(c1)Oc1c(ccc4c1-c1ccccc1[C@@]41c4ccccc4-c4cc5c(cc41)N(c1ccccc1-c1ccccc1)c1cc(C)cc4c1B5c1ccc(C)cc1N4c1ccccc1-c1ccccc1)B3c1cc(C(C)(C)C)ccc1O2 ; Cc1cc2c3c(c1)Sc1ccccc1B3c1ccc3c(c1O2)-c1ccccc1[C@@]31c2ccccc2-c2cc3c(cc21)N(c1ccccc1-c1ccccc1)c1cc(C)cc2c1B3c1cc(C(C)(C)C)ccc1S2]

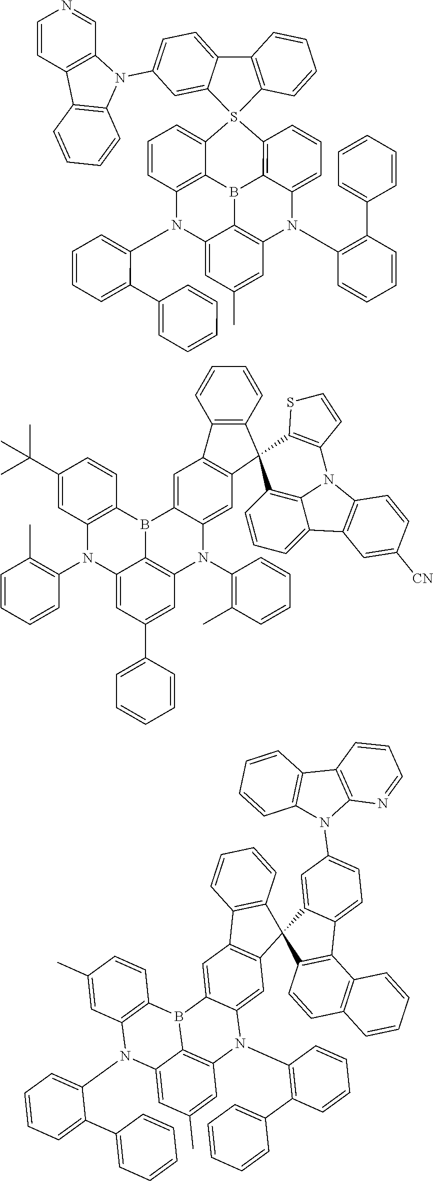

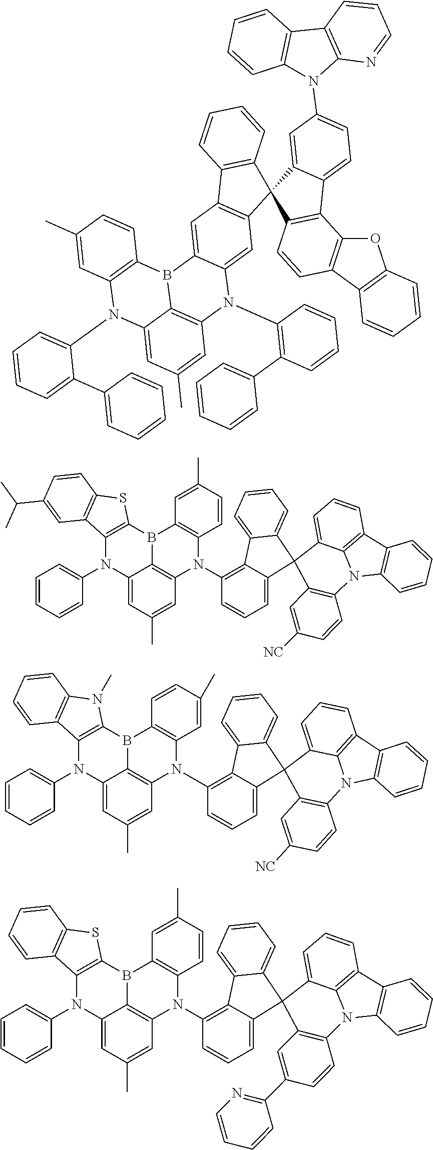 [SMILES: Cc1ccc2c(c1)N(c1ccccc1-c1ccccc1)c1cc(C)cc3c1B2c1cc2c(cc1N3c1ccccc1-c1ccccc1)[C@]1(c3ccccc3-2)c2cc(-n3c4ccccc4c4cccnc43)ccc2-c2c1ccc1c2oc2ccccc21 ; Cc1ccc2c(c1)B1c3sc4ccc(C(C)C)cc4c3N(c3ccccc3)c3cc(C)cc(c31)N2c1cccc2c1-c1ccccc1C21c2cc(C#N)ccc2-n2c3ccccc3c3cccc1c32 ; Cc1ccc2c(c1)N(c1cccc3c1-c1ccccc1C31c3cc(C#N)ccc3-n3c4ccccc4c4cccc1c43)c1cc(C)cc3c1B2c1c(c2ccccc2n1C)N3c1ccccc1 ; Cc1ccc2c(c1)B1c3sc4ccccc4c3N(c3ccccc3)c3cc(C)cc(c31)N2c1cccc2c1-c1ccccc1C21c2cc(-c3ccccn3)ccc2-n2c3ccccc3c3cccc1c32]

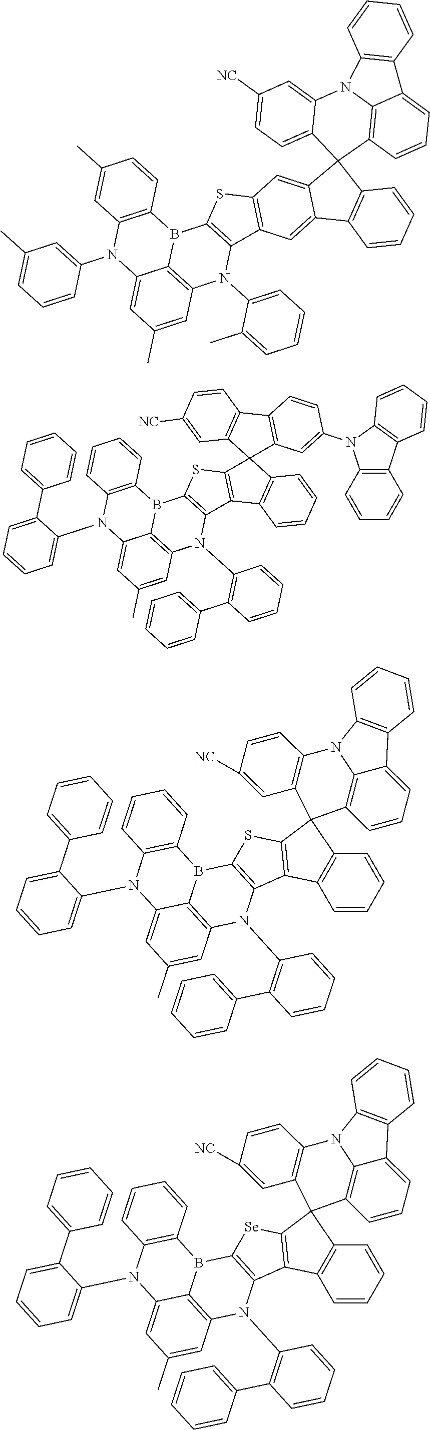 [SMILES: Cc1cccc(N2c3cc(C)ccc3B3c4sc5cc6c(cc5c4N(c4ccccc4C)c4cc(C)cc2c43)-c2ccccc2C62c3ccc(C#N)cc3-n3c4ccccc4c4cccc2c43)c1 ; Cc1cc2c3c(c1)N(c1ccccc1-c1ccccc1)c1c(sc4c1-c1ccccc1C41c4cc(C#N)ccc4-c4ccc(-n5c6ccccc6c6ccccc65)cc41)B3c1ccccc1N2c1ccccc1-c1ccccc1 ; Cc1cc2c3c(c1)N(c1ccccc1-c1ccccc1)c1c(sc4c1-c1ccccc1C41c4cc(C#N)ccc4-n4c5ccccc5c5cccc1c54)B3c1ccccc1N2c1ccccc1-c1ccccc1 ; Cc1cc2c3c(c1)N(c1ccccc1-c1ccccc1)c1c([se]c4c1-c1ccccc1C41c4cc(C#N)ccc4-n4c5ccccc5c5cccc1c54)B3c1ccccc1N2c1ccccc1-c1ccccc1]

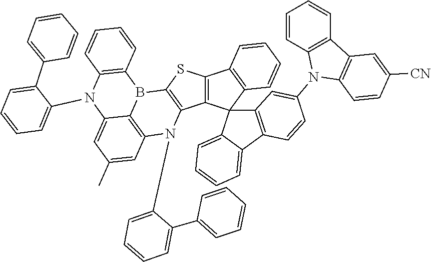 [SMILES: Cc1cc2c3c(c1)N(c1ccccc1-c1ccccc1)c1c(sc4c1C1(c5ccccc5-c5ccc(-n6c7ccccc7c7cc(C#N)ccc76)cc51)c1ccccc1-4)B3c1ccccc1N2c1ccccc1-c1ccccc1]

The charge stabilizing moiety of the multifunctional emitting compound can stabilize the emitting moiety at a short distance when the emitting moiety exists in an ionic state in which charges are trapped, or in an excited state, without significantly affecting the unique light emission properties of the emitting moiety. In addition, the charge stabilizing moiety protects a certain region of the emitting moiety while maintaining a spatial position and angle that do not cause chemical interaction with the emitting moiety, thereby significantly reducing the probability of chemical interactions and Coulomb interactions with other dopant materials, host materials and excitons.

For the above reasons, the multifunctional emitting compound may increase light emission stability in operating the organic light emitting diode device.

The organic light emitting diode may further include a phosphorescent material in the emission layer to further increase light emitting efficiency of the emission layer.

In one embodiment, the emission layer may further include a phosphorescent material including Pt or Ir.

The compounds represented by the following structural formulae are exemplified as organic metal complexes commonly used as phosphorescent materials. In the formulae below, R may be alkyl having 1 to 20 carbon atoms, aryl having 6 to 30 carbon atoms, and the like.

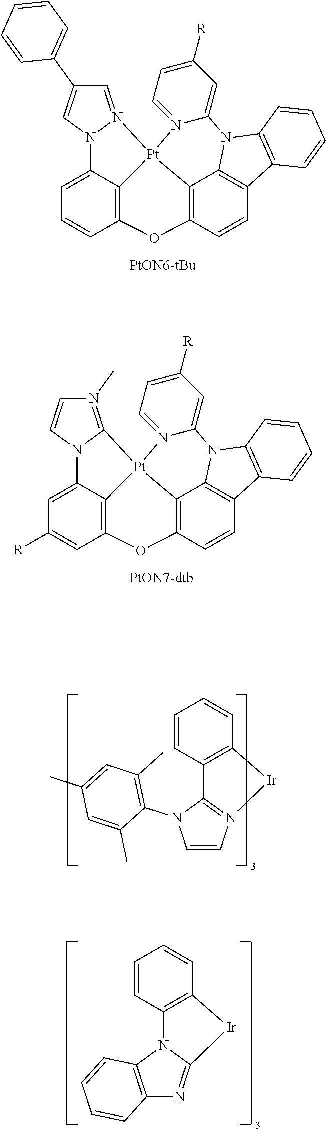

The organic light emitting diode may further include a thermally activated delayed fluorescent material to further increase light emitting efficiency of the emission layer.

In one embodiment, the emission layer may further include a thermally activated delayed fluorescent material having the difference in the energy between a singlet and a triplet of 0.3 eV or more.

The compounds represented by the following structural formulae are shown as examples of commonly used thermally activated delayed fluorescent materials. Ar may be alkyl having 1 to 20 carbon atoms, aryl having 6 to 30 carbon atoms, or etc.

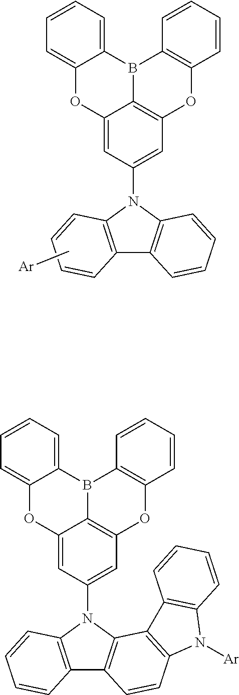

The organic light emitting diode may include, as the organic layer, one selected from the group consisting of a hole injection layer, a hole transport layer, an electron blocking layer, a hole blocking layer, an electron transport layer, an electron injection layer and combinations thereof.

In one embodiment, the organic light emitting diode includes an anode, a hole injection layer (HIL), a hole transport layer (HTL), an emission layer (EML), an electron transport layer (ETL) and a cathode sequentially.

The organic light emitting diode may be a tandem type organic light emitting diode including a plurality of organic light emitting units.

A plurality of the organic light emitting units may be sequentially stacked, and may include a charge generation layer (CGL) between each of the organic light emitting unit. The charge generation layer is positioned between the organic light emitting units, so that charges can be smoothly distributed to the emission layer of each organic light emitting unit.

In the tandem type organic light emitting diode, at least one organic light emitting unit may include an emission layer including the multifunctional emitting compound.

In the tandem type organic light emitting diode, the detailed description of the multifunctional emitting compound is as described above.

Examples and comparative examples of the present disclosure are described below. The following examples are only examples of the present disclosure, but the present disclosure is not limited to the following examples.

### EXAMPLES

In Comparative examples and Examples, Comparative compound 1, Comparative compound 2 and Multifunctional emitting compound 3 as shown below were synthesized.

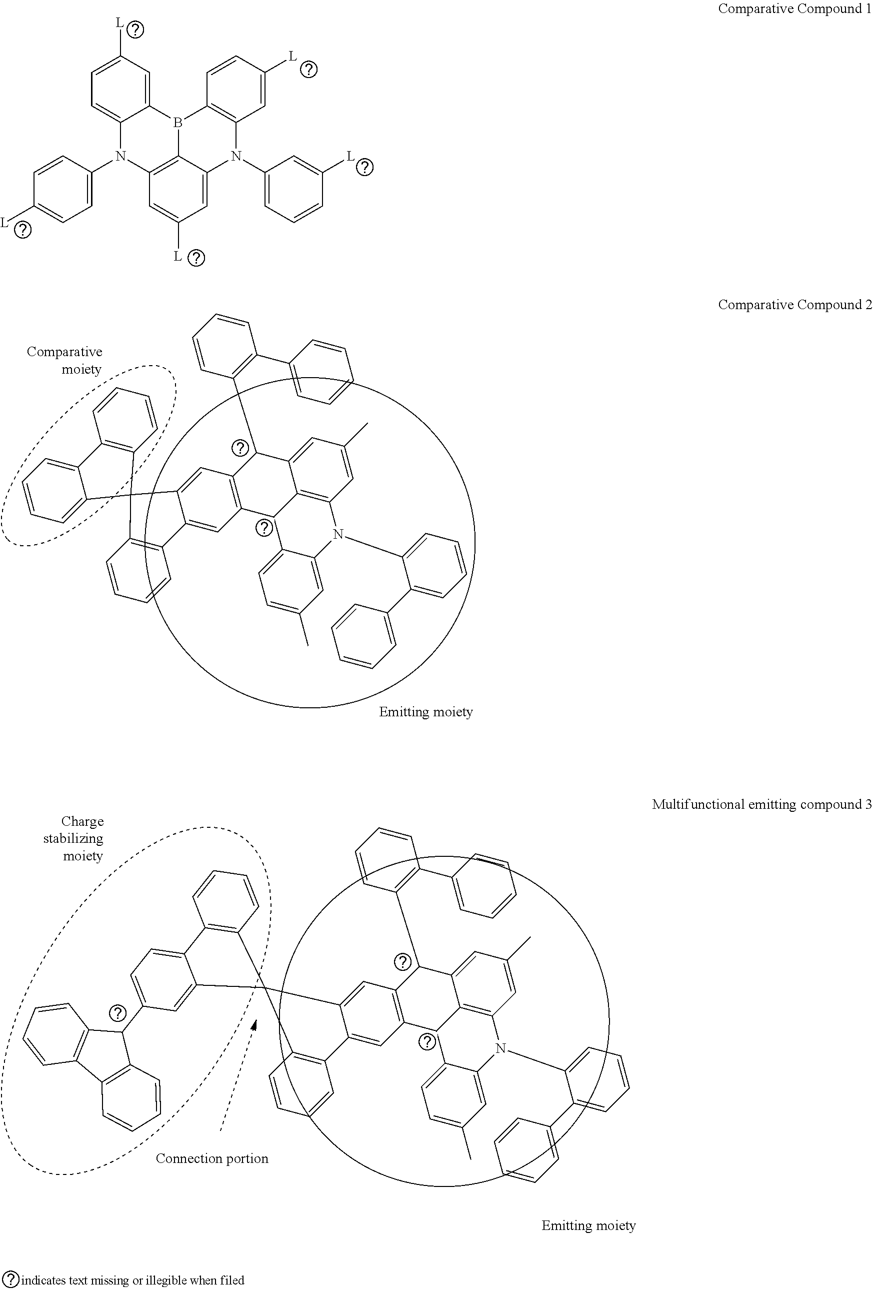

In Comparative compound 1, L₁ is a t-butyl group and L₂ is an adamantyl group.

Multifunctional emitting compound 3, in which the charge stabilizing moiety and the emitting moiety are as indicated, and a connection portion corresponds to the atom X in Formula 1, corresponds to the compound represented by Formula 1. Since Comparative Compound 1 does not correspond to the compound represented by Formula 1, it is not entitled to the multifunctional emitting compound. Since the comparative moiety of Comparative Compound 2 does not include an atom having an unshared electron pair, Comparative Compound 2 is not entitled to the multifunctional emitting compound.

### Synthesis of Comparative Compound 1

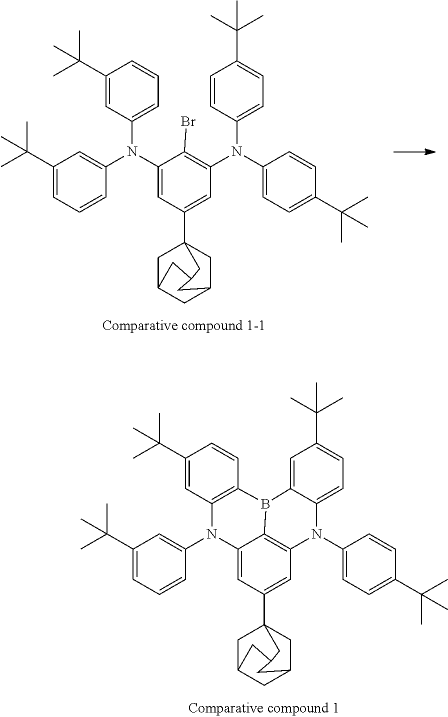

After dissolving 8.48 g (10.0 mmol) of Comparative compound 1-1 in tertiary butylbenzene (32 ml), it was cooled to 0° C. Under a nitrogen atmosphere, 8.0 mL (20.0 mmol) of 2.5M n-butyllithium solution (in hexane) was added and stirred at room temperature for 3 hours.

Then, the reactant was cooled to 0° C. again, and after being added with 1.90 mL (20.0 mmol) of boron tribromide, it was stirred at room temperature for 0.5 hour. The reactants were cooled to 0° C. again, and 3.51 mL (20.0 mmol) of N,N-diisopropylethylamine was added thereto, followed by stirring at 60-70° C. for 2 hours.

The reaction solution was cooled to room temperature, and the organic layer was extracted with ethyl acetate. After drying the solvent of the extracted organic layer with MgSO₄, it was filtered. After concentrating the filtrate under reduced pressure, it was purified using a silica gel column chromatography (DCM/Hexane) method.

Then, recrystallization and purification were performed using a DCM/acetone mixed solvent to obtain 1.05 g of Comparative compound 1 in a yield of 12%.

MS (ACPI) m/z: 779 [M+H]

NMR: δH (500 MHz; CDCl₃; Me₄Si) 8.94 (s, 1H), 8.84 (d, J=10.0, 2.0 Hz, 1H), 7.69 (d, 2H), 7.66-7.56 (m, 2H), 7.51-7.45 (d, 1H), 7.42 (s, 1H), 7.34-7.28 (m, 3H), 7.19 (d, 1H), 7.67 (d, 2H), 6.15 (s, 1H), 6.06 (s, 1H), 1.89 (s, 3H), 1.64 (d, 4H), 1.46 (s, 20H), 1.37 (s, 11H), 1.25 (s, 3H), 1.22 (s, 10H)

### Synthesis of Comparative Compound 2

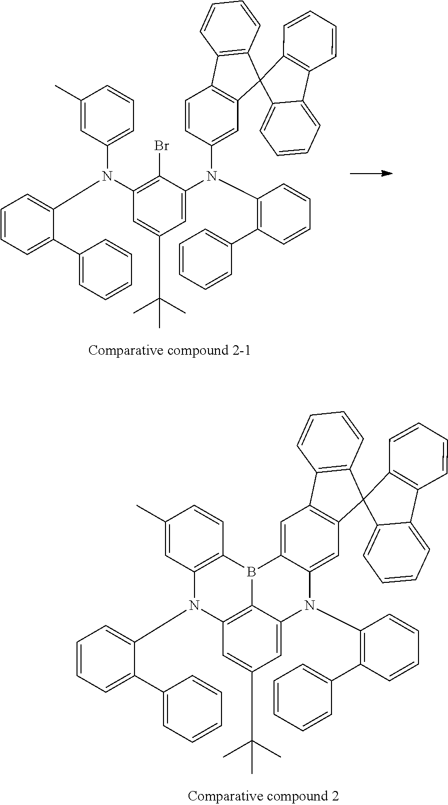 [SMILES: Cc1cccc(N(c2ccccc2-c2ccccc2)c2cc(C(C)(C)C)cc(N(c3ccc4c(c3)C3(c5ccccc5-c5ccccc53)c3ccccc3-4)c3ccccc3-c3ccccc3)c2Br)c1 ; Cc1ccc2c(c1)N(c1ccccc1-c1ccccc1)c1cc(C(C)(C)C)cc3c1B2c1cc2c(cc1N3c1ccccc1-c1ccccc1)C1(c3ccccc3-c3ccccc31)c1ccccc1-2]

After dissolving 9.52 g (10.0 mmol) of Comparative compound 2-1 as a starting material in tertiary butylbenzene (32 ml), it was cooled to 0° C. Under a nitrogen atmosphere, 8.0 mL (20.0 mmol) of 2.5M n-butyllithium solution (in hexane) was added and stirred at room temperature for 3 hours.

Then, the reactant was cooled to 0° C. again, and after being added with 1.90 mL (20.0 mmol) of boron tribromide, it was stirred at room temperature for 0.5 hour. The reactants were cooled to 0° C. again, and 3.51 mL (20.0 mmol) of N,N-diisopropylethylamine was added thereto, followed by stirring at 60-70° C. for 2 hours.

The reaction solution was cooled to room temperature, and the organic layer was extracted with ethyl acetate. After drying the solvent of the extracted organic layer with MgSO₄, it was filtered. After concentrating the filtrate under reduced pressure, it was purified using a silica gel column chromatography (DCM/Hexane) method.

Then, recrystallization and purification were performed using a DCM/acetone mixed solvent to obtain 1.05 g of Comparative compound 2 in a yield of 12%.

MS (ACPI) m/z: 881 [M+H]

NMR: δH (400 MHz; CDCl₃; Me₄Si) 9.13 (1H, s), 8.86-8.83 (1H, m), 7.92-7.90 (1H, m), 7.78 (1H, d, J 8.0), 7.73-7.64 (4H, m), 7.44-7.27 (8H, m), 7.17-6.86 (11H, m), 6.80-6.57 (5H, m), 6.49 (1H, d, J 4.0), 6.37 (1H, d, J 8.0), 6.12 (2H, t), 5.89 (1H, d, J 8.0), 2.36 (3H, s), 0.96 (9H, s)

### Synthesis of Multifunctional Emitting Compound 3 (Also Referred to as Compound 3)

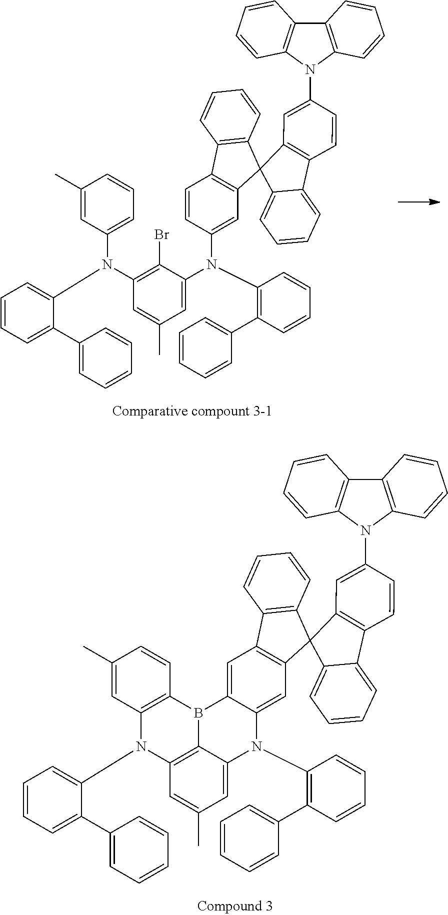 [SMILES: Cc1cccc(N(c2ccccc2-c2ccccc2)c2cc(C)cc(N(c3ccc4c(c3)C3(c5ccccc5-4)c4ccccc4-c4ccc(-n5c6ccccc6c6ccccc65)cc43)c3ccccc3-c3ccccc3)c2Br)c1 ; Cc1ccc2c(c1)N(c1ccccc1-c1ccccc1)c1cc(C)cc3c1B2c1cc2c(cc1N3c1ccccc1-c1ccccc1)C1(c3ccccc3-c3ccc(-n4c5ccccc5c5ccccc54)cc31)c1ccccc1-2]

The same method was performed as in Synthesis of Comparative compound 1, except that Compound 3-1 was used instead of Compound 1-1 in the same molar ratio. Thereafter, 1.0 g of Compound 3 was obtained in a 10% yield.

MS (ACPI) m/z: 1004 [M+H]

NMR: δH (500 MHz; CDCl₃; Me₄Si) 9.19 (1H, d), 8.9 (2H, dd), 7.98-8.43-8.32 (1H, m), 8.25-8.16 (1H, m), 8.11-7.99 (2H, m), 7.93 (1H, dd), 7.70-7.60 (2H, m), 7.54-7.38 (6H, m), 7.37-7.26 (4H, m) 7.25-7.14 (1H, m), 7.13-7.04 (4H, m), 7.04-6.90 (3H, m), 6.89-6.60 (12H, m), 6.58-6.45 (2H, m), 5.93-5.80 (2H, m), 2.24 (3H, dd), 2.03 (3H, d)

For Compound 3, the charge stabilizing moiety had a dipole moment of 1.6 Debye.

### Synthesis of Compound 4

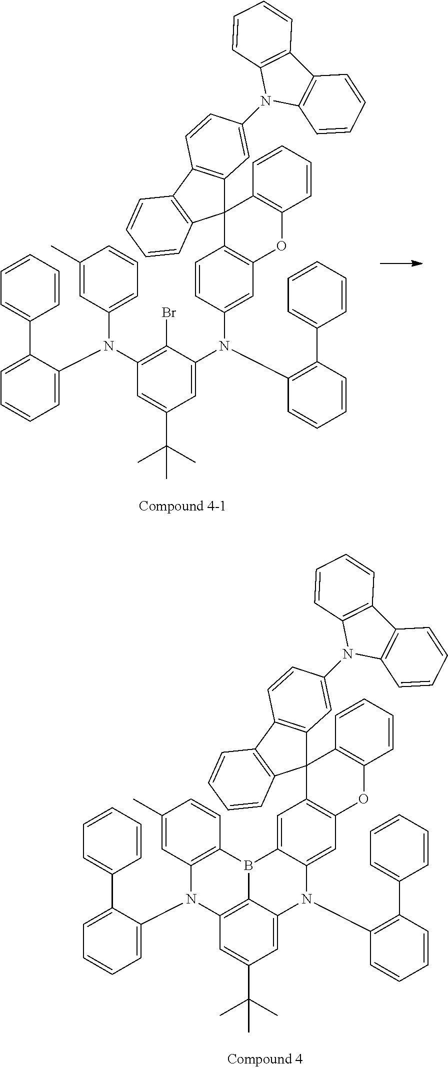 [SMILES: Cc1cccc(N(c2ccccc2-c2ccccc2)c2cc(C(C)(C)C)cc(N(c3ccc4c(c3)Oc3ccccc3C43c4ccccc4-c4ccc(-n5c6ccccc6c6ccccc65)cc43)c3ccccc3-c3ccccc3)c2Br)c1 ; Cc1ccc2c(c1)N(c1ccccc1-c1ccccc1)c1cc(C(C)(C)C)cc3c1B2c1cc2c(cc1N3c1ccccc1-c1ccccc1)Oc1ccccc1C21c2ccccc2-c2ccc(-n3c4ccccc4c4ccccc43)cc21]

The same method was performed as in Synthesis of Comparative compound 1, except that Compound 4-1 was used instead of Compound 1-1 in the same molar ratio. Thereafter, 1.12 g of Compound 4 was obtained in an 11% yield.

MS (ACPI) m/z: 1062 [M+H]

NMR: δH (500 MHz; CDCl₃; Me₄Si) 8.08-7.76 (5H, m), 7.72-7.28 (13H, m), 7.24-6.47 (24H, m), 6.05-5.97 (2H, m), 2.23-2.22 (3H, m), 0.94-0.92 (9H, d)

For Compound 4, the charge stabilizing moiety had a dipole moment of 1.6 Debye.

### Synthesis of Compound 5

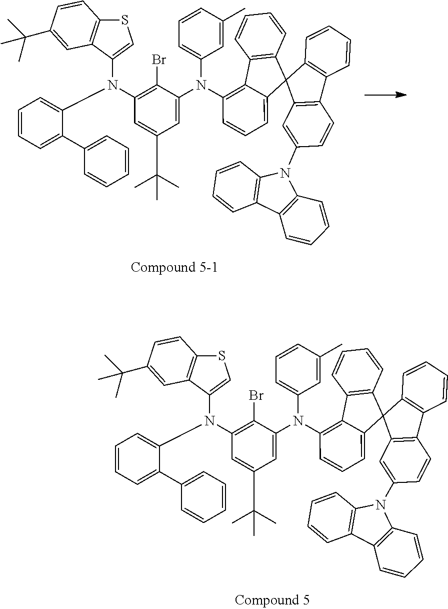 [SMILES: Cc1cccc(N(c2cc(C(C)(C)C)cc(N(c3ccccc3-c3ccccc3)c3csc4ccc(C(C)(C)C)cc34)c2Br)c2cccc3c2-c2ccccc2C32c3ccccc3-c3ccc(-n4c5ccccc5c5ccccc54)cc32)c1 ; Cc1cccc(N(c2cc(C(C)(C)C)cc(N(c3ccccc3-c3ccccc3)c3csc4ccc(C(C)(C)C)cc34)c2Br)c2cccc3c2-c2ccccc2C32c3ccccc3-c3ccc(-n4c5ccccc5c5ccccc54)cc32)c1]

The same method was performed as in Synthesis of Comparative compound 1, except that Compound 5-1 was used instead of Compound 1-1 in the same molar ratio. Thereafter, 1.08 g of Compound 4 was obtained in an 10% yield.

MS (ACPI) m/z: 1082 [M+H]

NMR: δH (500 MHz; CDCl₃; Me₄Si) 8.62-8.58 (2H, s), 8.11-8.07 (3H, m), 7.98-7.88 (2H, m), 7.81-7.56 (4H, m), 7.53-6.68 (25H, m), 6.61-6.09 (3H, m), 1.71-1.69 (3H, d), 1.15-1.13 (9H, d), 1.02-1.00 (9H, d)

For Compound 5, the charge stabilizing moiety had a dipole moment of 1.6 Debye.

### Evaluation Example 1: Device Evaluation

The ITO surface was treated with UV ozone for 3 minutes at atmospheric pressure.

The device was processed in the following order in a 10-7 torr vacuum chamber.

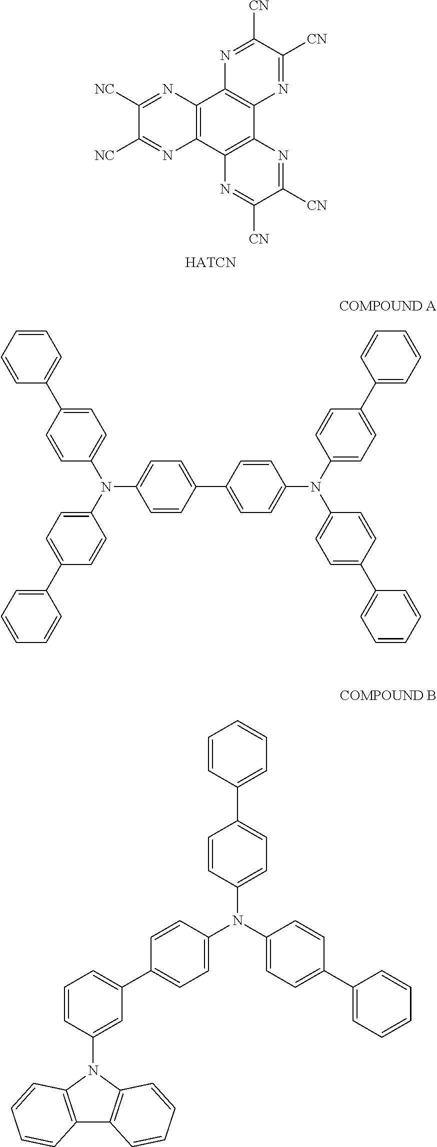 [SMILES: N#Cc1nc2c3nc(C#N)c(C#N)nc3c3nc(C#N)c(C#N)nc3c2nc1C#N ; "HATCN" ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1]

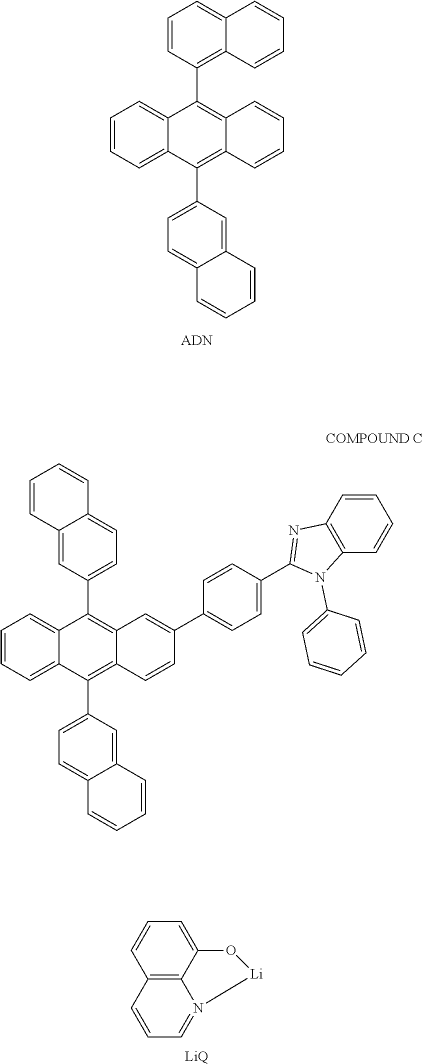

### Comparative Example 1

HATCN as a hole injection material was deposited to a thickness of 50 Å.

Compound A as a hole transport material was deposited to a thickness of 1000 Å.

For an electron blocking layer, Compound B was deposited to a thickness of 50 Å.

For an emission layer, ADN was deposited to a thickness of 250 Å with 2 mol % of Comparative compound 1 doped.

For an electron transport layer, Compound C and LiQ were deposited to a thickness of 300 Å at a mol ratio of 1:1.

For an electron injection layer, LiQ was deposited to a thickness of 10 Å.

For an electrode, Al was deposited to a thickness of 500 Å.

### Comparative Example 2

Organic light emitting diode (OLED) 2 was manufactured in the same manner as in OLED 1 except that the emission layer was doped with 2 mol % of Comparative compound 2 instead of Comparative compound 1.

### Example 1

OLED 3 was manufactured in the same manner as in OLED 1, except that the emission layer was doped with 4 mol % of Compound 3 instead of Comparative compound 1.

### Example 2

OLED 4 was manufactured in the same manner as in OLED 1, except that the emission layer was doped with 4 mol % of Compound 4 instead of Comparative compound 1.

### Example 3

OLED 5 was manufactured in the same manner as in OLED 1, except that the emission layer was doped with 3 mol % of Compound 5 instead of Comparative compound 1.

In each device below, the doping % showing the maximum emitting efficiency and the time (T95) required for the brightness to decrease by 5% when a current of 20 mA/cm² was applied to the device were measured. The results are shown in Table 1 below.

TABLE 1

| | | | Max. | | | |
|---|---|---|---|---|---|---|
| | | | efficiency | | | |
| Device | | | doping | Voltage | EQE | |
| (10 mA/cm²) | | Dopant | (mol %) | (V) | (%) | T95 |
| Comparative | OLED | Comparative | 2 | 3.7 | 6.8 | 120 |
| Example 1 | 1 | compound 1 | | | | |
| Comparative | OLED | Comparative | 2 | 3.8 | 6.9 | 140 |
| Example 2 | 2 | compound 2 | | | | |
| Example 1 | OLED | Compound 3 | 4 | 3.8 | 7.10 | 200 |
| | 3 | | | | | |
| Example 2 | OLED | Compound 4 | 4 | 3.6 | 5.35 | 180 |
| | 4 | | | | | |
| Example 3 | OLED | Compound 5 | 3 | 3.7 | 7.02 | 220 |
| | 5 | | | | | |

As can be seen from Table above, OLEDs using the multifunctional emitting compound show stable lifetime improvement.

While the present disclosure has been described with reference to embodiments as described above, the embodiments set forth herein are not intended to limit the present disclosure, and it is obvious that various modifications can be made by those skilled in the art within the scope of the technical spirit of the present disclosure. In addition, even if not explicitly described about functioning effects according to the configurations of the present disclosure in the foregoing detailed description of embodiments, it is apparent that predictable effects of the corresponding configurations should also be acknowledged.

1. An organic light emitting diode comprising a first electrode, a second electrode and an emission layer interposed between the first electrode and the second electrode,
wherein the emission layer includes a multifunctional emitting compound represented by Formula 1 below,
the multifunctional emitting compound includes an emitting moiety and a charge stabilizing moiety, the emitting moiety and the charge stabilizing moiety are connected through an atom X and the atom X is X indicated in Formula 1 below,
the emitting moiety includes a ring A, a conjugated ring formed with Y¹ to Y⁵ being included, and Q in Formula 1 below,
the charge stabilizing moiety includes a conjugated ring formed with Y⁶ to Y¹⁰ being included, a conjugated ring formed with Y¹¹ to Y¹⁵ being included, and Z in Formula 1 below, the charge stabilizing moiety comprises at least one atom having an unshared pair of electrons: 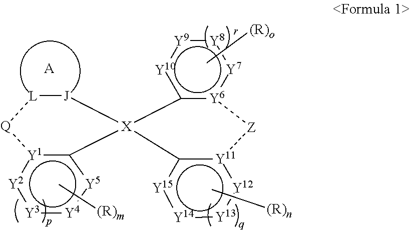
In Formula 1,
a ring A is a fused ring represented by Formula 2, Formula 3 or Formula 4 below,
L represents a linking site in the ring A, wherein L is linked to Q; or Y¹ when Q does not exist;
J represents the other linking site in the ring A, and J is linked to X,
X is C, Si, Ge, Sn or Pb,
Q is absent or represents a single bond, or is an atom selected from the group consisting of group IIIA, group IVA, group VA and group VIA elements,
when Q does not exist, L in the ring A is not linked to Y¹,
when Q is a single bond, a single bond which directly connects L in the ring A and Y¹ is formed so as to form a 5-membered ring including X,
when Q is any of atom selected from the elements defined above, a 6-membered ring including X is formed, and the atom can have a substituent(s) selected from the group consisting of alkyl having 1 to 20 carbon atoms, a first additional substituent-substituted or unsubstituted aryl having 6 to 20 carbon atoms, a first additional substituent-substituted or unsubstituted heteroaryl having 5 to 20 carbon atoms and combinations thereof, in accordance with a stoichiometric ratio, and the first additional substituent can connect to Y² or Y²-linked R to form a fused ring, or connect to the ring A to form a fused ring,
Y¹ to Y¹⁵ are, each independently, boron, carbon, nitrogen, oxygen, sulfur, Se or Te,
Z is absent, or is a single bond, oxygen, sulfur, Se, C—(Ar¹)₂, POAr¹ or N—Ar¹, where Ar¹ is alkyl having 1 to 20 carbon atoms, a second additional substituent-substituted or unsubstituted aryl having 6 to 20 carbon atoms or a second additional substituent-substituted or unsubstituted heteroaryl having 5 to 20 carbon atoms, and Ar′ can connect to any of Y⁷, Y¹², Y⁷-linked R or Y¹²-linked R to form a fused ring,
when Z is absent, Y⁶ and Y¹¹ are not connected,
when Z is a single bond, Y⁶ and Y¹¹ are connected by a single bond,
m, n and o are, each independently, an integer from 0 to 5,
R is, each independently, hydrogen, deuterium, alkyl having 1 to 20 carbon atoms, a second additional substituent-substituted or unsubstituted aryl having 6 to 20 carbon atoms, a second additional substituent-substituted or unsubstituted heteroaryl having 5 to 20 carbon atoms, alkylamine having 1 to 20 carbon atoms, a second additional substituent-substituted or unsubstituted arylamine having 6 to 30 carbon atoms, a second additional substituent-substituted or unsubstituted alkylarylamine having 7 to 30 carbon atoms, halogen, CN, a second additional substituent-substituted or unsubstituted alkoxy having 1 to 20 carbon atoms, aryloxy having 6 to 30 carbon atoms, alkylsilyl having 3 to 20 carbon atoms, a second additional substituent-substituted or unsubstituted arylsilyl having 6 to 30 carbon atoms, a second additional substituent-substituted or unsubstituted alkylarylsilyl having 7 to 30 carbon atoms, alkylthiol having 3 to 20 carbon atoms, a second additional substituent-substituted or unsubstituted arylthiol having 6 to 30 carbon atoms, or a second additional substituent-substituted or unsubstituted arylphosphine oxide having 6 to 30 carbon atoms, and when m, n or o is 2 or more, at least two R present can be connected to each other to form a ring,
p, q and r, each independently, represent 0 or 1; when p, q or r is 0, it means that a 5-membered ring is formed; and when p, q or r is 1, it means that a 6-membered ring is formed; 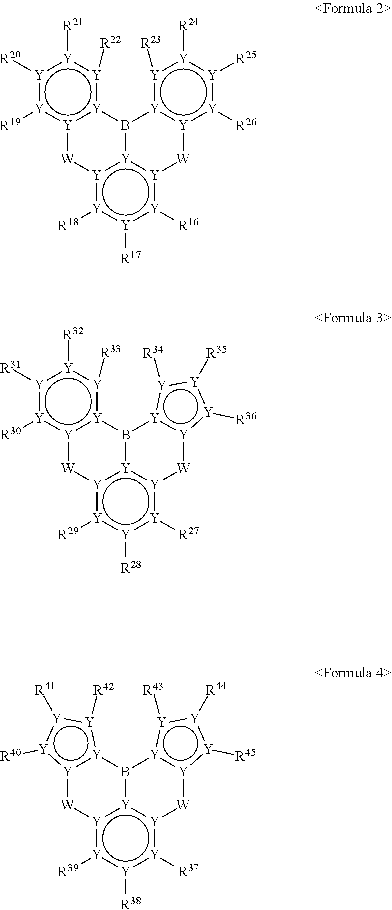
In Formula 2, Formula 3, and Formula 4,
Y is, each independently, carbon, nitrogen, oxygen, sulfur, Se or Te, provided that Y at a position corresponding to J in Formula 1 is carbon,
W is, each independently, oxygen, sulfur, Se, POAr², or N—Ar², and Ar² is alkyl having 1 to 20 carbon atoms, a second additional substituent-substituted or unsubstituted aryl having 6 to 20 carbon atoms, or, a second additional substituent-substituted or unsubstituted heteroaryl having 5 to 20 carbon atoms,
R¹⁶ to R⁴⁵, each independently, represent a bond with X such that the Y connected thereto corresponds to J in Formula 1; or, a bond with Q such that the Y connected thereto corresponds to L in Formula 1; or, is hydrogen, deuterium, alkyl having 1 to 20 carbon atoms, a second additional substituent-substituted or unsubstituted aryl of 6 to 20 carbon atoms, a second additional substituent-substituted or unsubstituted heteroaryl having 5 to 20 carbon atoms, alkylamine having 1 to 20 carbon atoms, a second additional substituent-substituted or unsubstituted arylamine having 6 to 30 carbon atoms, a second additional substituent-substituted or unsubstituted alkylarylamine having 7 to 30 carbon atoms, halogen, CN, alkoxy having 1 to 20 carbon atoms, a second additional substituent-substituted or unsubstituted aryloxy having 6 to 30 carbon atoms, alkylsilyl having 3 to 20 carbon atoms, a second additional substituent-substituted or unsubstituted arylsilyl having 6 to 30 carbon atoms, a second additional substituent-substituted or unsubstituted alkylarylsilyl having 7 to 30 carbon atoms, alkylthiol having 3 to 20 carbon atoms, arylthiol having 6 to 30 carbon atoms, or, arylphosphine oxide having 6 to 30 carbon atoms, and at least two of R¹⁶ to R⁴⁵ can be connected to each other to form a ring,
the first additional substituent is selected from the group consisting of deuterium, alkyl having 1 to 20 carbon atoms, halogen, cyano, aryl having 6 to 30 carbon atoms, alkylsilyl having 1 to 20 carbon atoms, arylsilyl having 6 to 20 carbon atoms, alkylamine having 1 to 20 carbon atoms, arylamine having 6 to 20 carbon atoms, heteroaryl having 5 to 30 carbon atoms, alkoxy having 1 to 20 carbon atoms, aryloxy having 6 to 30 carbon atoms, alkylthiol having 3 to 20 carbon atoms, arylthiol having 6 to 30 carbon atoms, arylphosphine oxides having 6 to 30 carbon atoms and combinations thereof, and
the second additional substituent is deuterium, alkyl having 1 to 20 carbon atoms, alkoxy having 1 to 20 carbon atoms, halogen, cyano group, carboxyl, carbonyl, amine, alkylamine having 1 to 20 carbon atoms, nitro, alkylsilyl having 1 to 20 carbon atoms, alkoxysilyl having 1 to 20 carbon atoms, arylsilyl having 6 to 30 carbon atoms, aryl having 6 to 30 carbon atoms, arylamine having 6 to 30 carbon atoms, heteroaryl having 5 to 30 carbon atoms, aryl phosphine oxide having 6 to 30 carbon atoms, arylphosphinyl having 6 to 30 carbon atoms, alkylphosphine oxide having 6 to 30 carbon atoms, alkylsulfonyl having 6 to 30 carbon atoms and combinations thereof,
provided that (i) the Y connected to one of R¹⁶ to R⁴⁵ corresponds to J in Formula 1, and another Y adjacent to the Y corresponding to J corresponds to L in Formula 1; or,
(ii) one of W is N—Ar², where Ar² is alkyl having 1 to 20 carbon atoms, a second additional substituent-substituted or unsubstituted aryl having 6 to 20 carbon atoms, or, a second additional substituent-substituted or unsubstituted heteroaryl having 5 to 20 carbon atoms, and one of ring members of aryl or heteroaryl of Ar² is carbon and corresponds to J in Formula 1, and another ring member adjacent thereto corresponds to L in Formula 1.

2. The organic light emitting diode according to claim 1, wherein Formula 1 is any one of formulae represented by following B-1 to B-32. 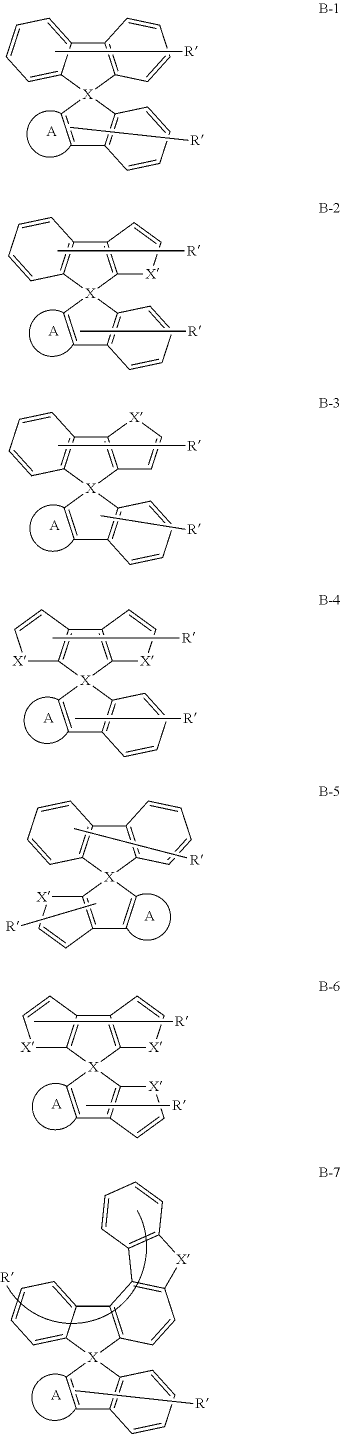 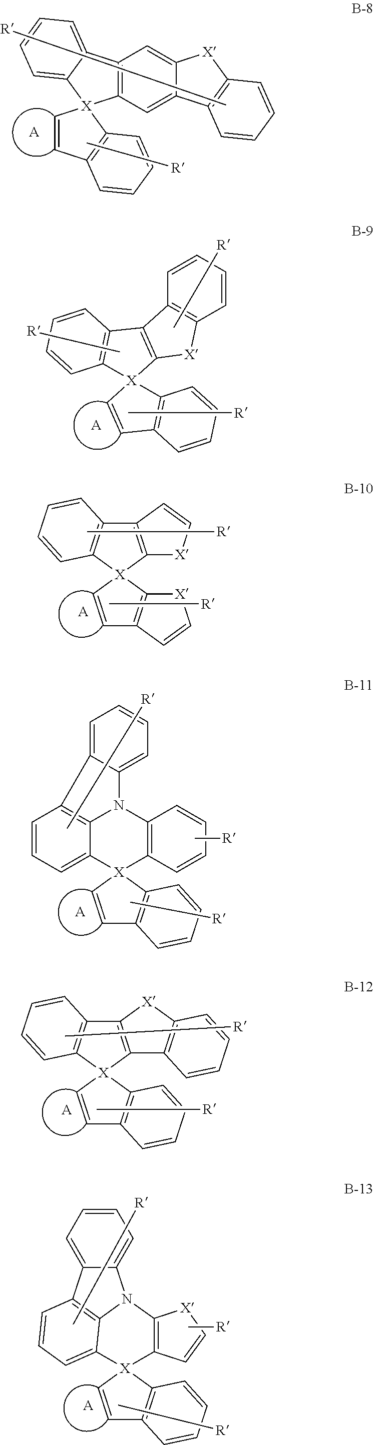 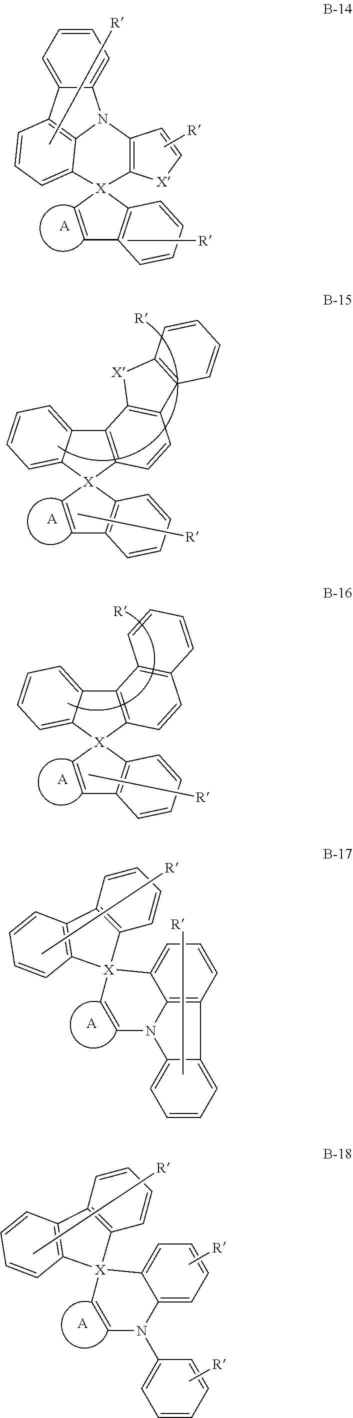 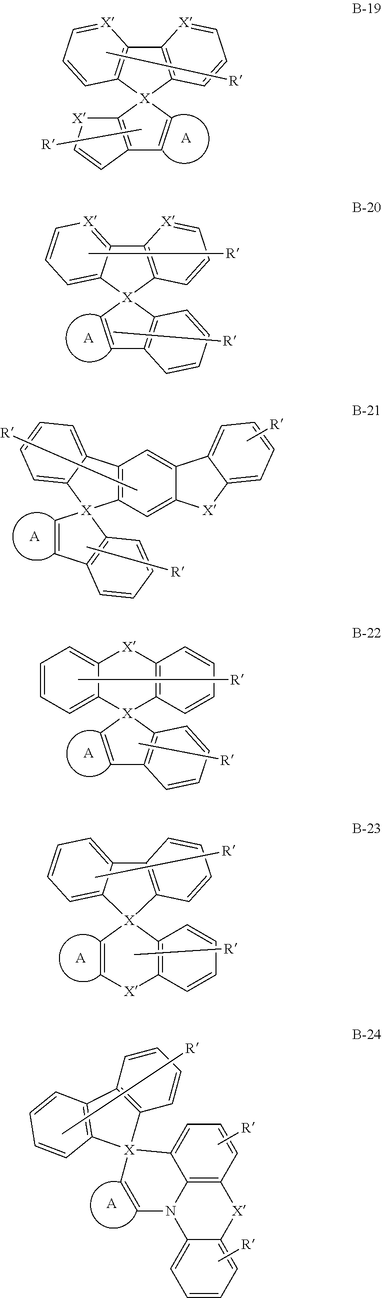 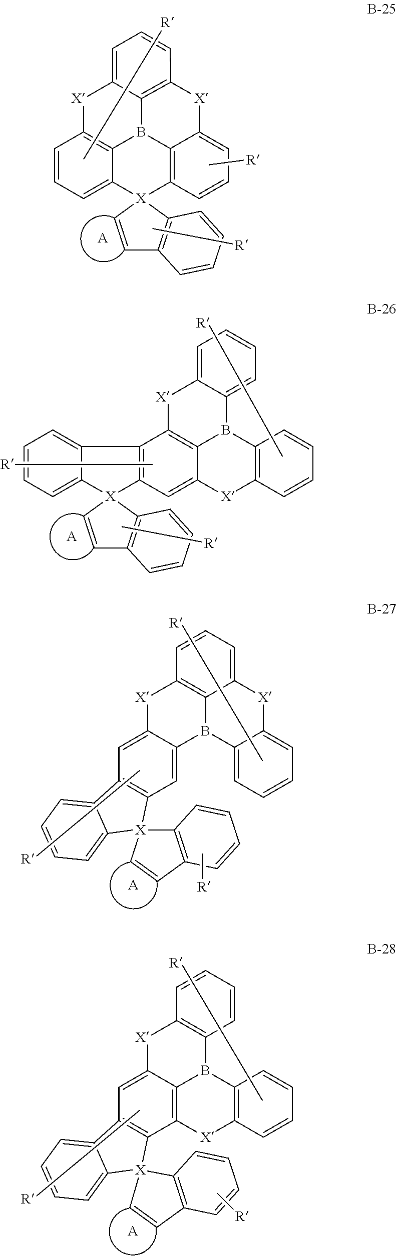 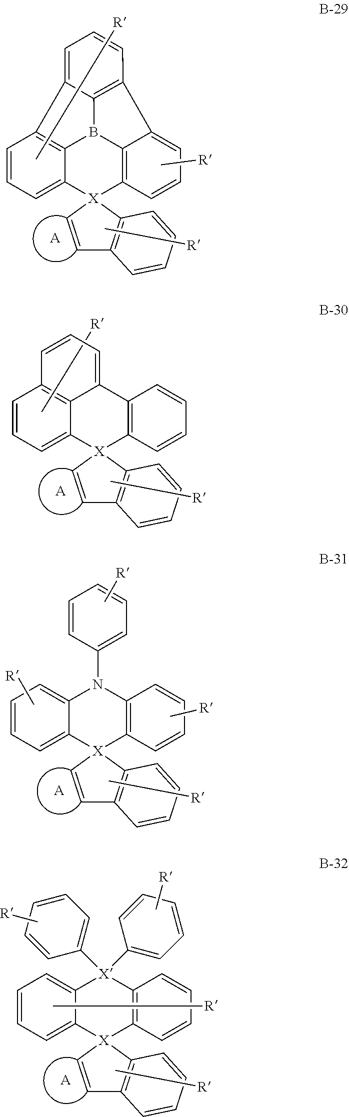
In the above B-1 to B-32,
a ring A is as defined in Formula 1 above,
X is C, Si, Ge, Sn or Pb,
X′ is, each independently, O, S, Se, C, Si, C—(Ar³)₂, Si—(Ar³)₂ or N—Ar³, and Ar³ is alkyl having 1 to 20 carbon atoms, a second additional substituent-substituted or unsubstituted aryl having 6 to 20 carbon atoms, or, a second additional substituent-substituted or unsubstituted heteroaryl having 5 to 20 carbon atoms, and when a plurality of Ar³ exist, a plurality of Ar can be connected to each other to form a ring,
R′ is present in a number according to a stoichiometric ratio, and is, each independently, hydrogen, deuterium, alkyl having 1 to 20 carbon atoms, a second additional substituent-substituted or unsubstituted aryl of 6 to 20 carbon atoms, a second additional substituent-substituted or unsubstituted heteroaryl having 5 to 20 carbon atoms, alkylamine having 1 to 20 carbon atoms, a second additional substituent-substituted or unsubstituted arylamine having 6 to 30 carbon atoms, a second additional substituent-substituted or unsubstituted alkylarylamine having 7 to 30 carbon atoms, halogen, CN, alkoxy having 1 to 20 carbon atoms, a second additional substituent-substituted or unsubstituted aryloxy having 6 to 30 carbon atoms, alkylsilyl having 1 to 20 carbon atoms, a second additional substituent-substituted or unsubstituted arylsilyl having 6 to 30 carbon atoms, a second additional substituent-substituted or unsubstituted alkylarylsilyl having 7 to 30 carbon atoms, alkylthiol having 3 to 20 carbon atoms, arylthiol having 6 to 30 carbon atoms, or arylphosphine oxide having 6 to 30 carbon atoms, and at least two of R′ can be connected to each other to form a ring, and
the second additional substituent is defined the same as the second additional substituent defined in Formula 1 above.

3. The organic light emitting diode according to claim 1, wherein the ring A is represented by any one of following C—1 to C—24. 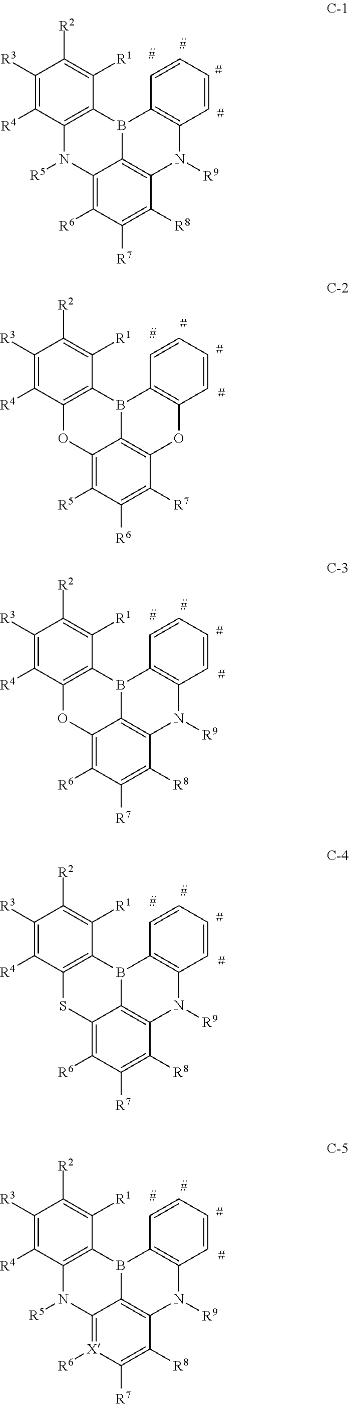 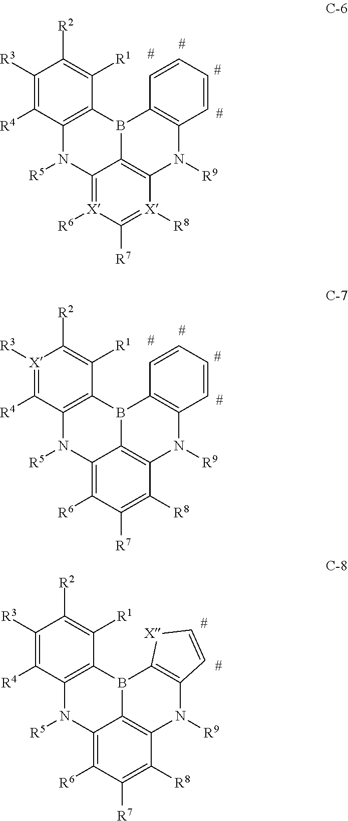 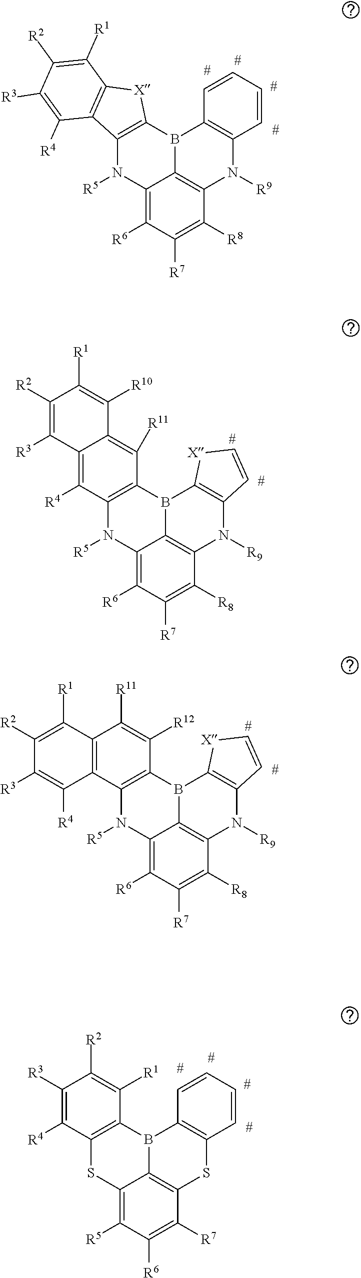 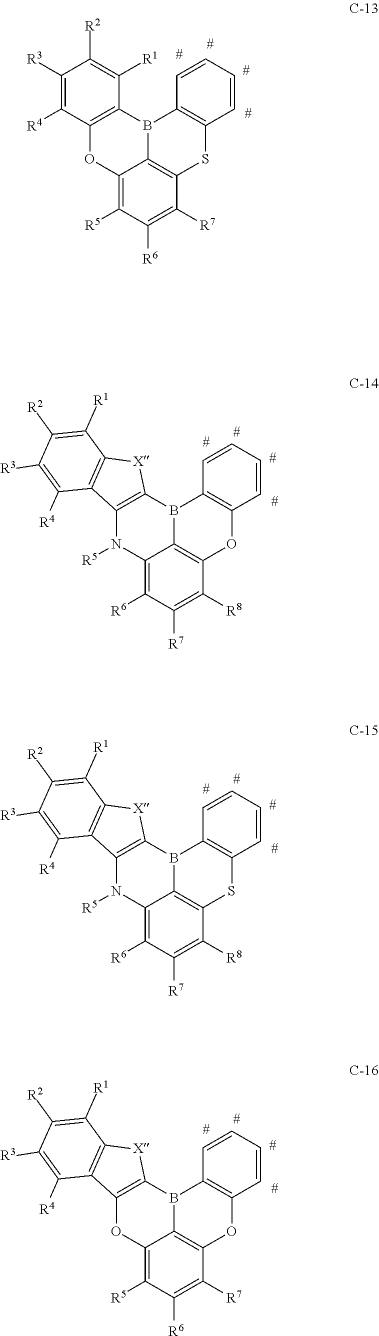 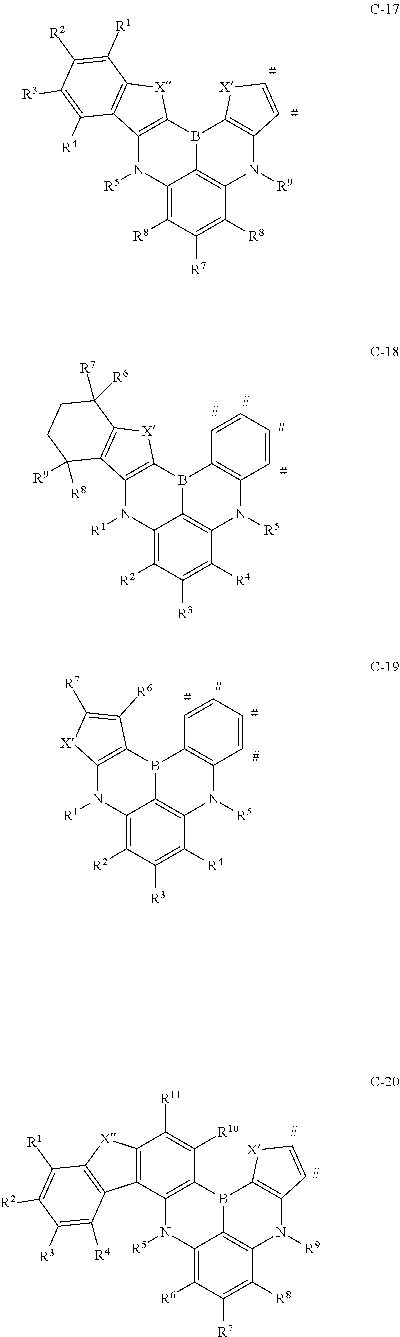 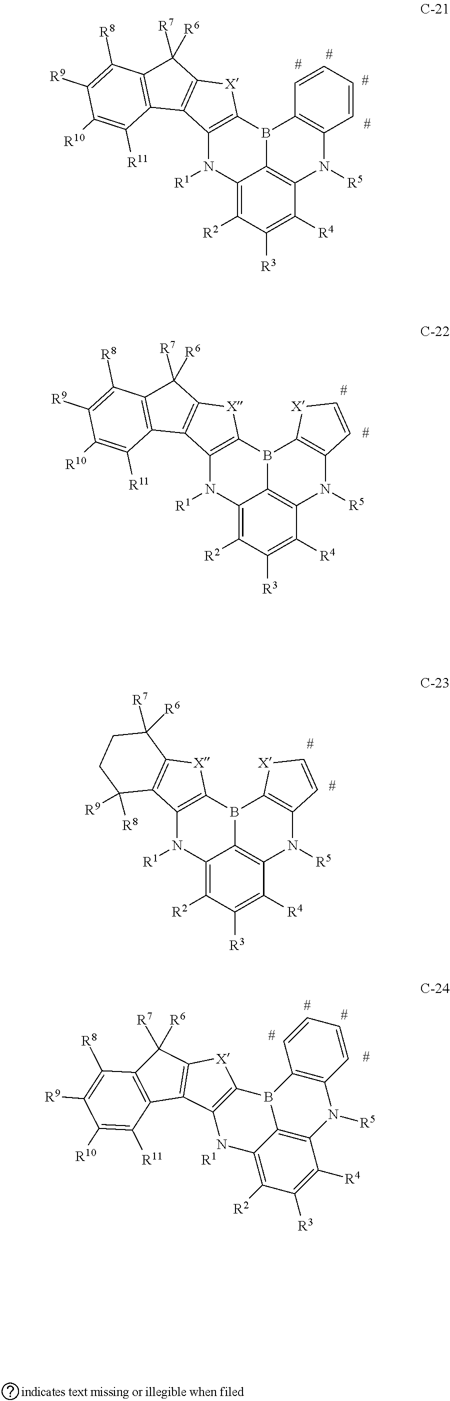
In the above C—1 to C—24,
two adjacent #among #-indicated positions correspond to J or L in the ring A of Formula 1,
R¹ to R¹¹ are, each independently, hydrogen, deuterium, alkyl having 1 to 20 carbon atoms, a second additional substituent-substituted or unsubstituted aryl of 6 to 20 carbon atoms, a second additional substituent-substituted or unsubstituted heteroaryl having 5 to 20 carbon atoms, alkylamine having 1 to 20 carbon atoms, a second additional substituent-substituted or unsubstituted arylamine having 6 to 30 carbon atoms, a second additional substituent-substituted or unsubstituted alkylarylamine having 7 to 30 carbon atoms, halogen, CN, alkoxy having 1 to 20 carbon atoms, a second additional substituent-substituted or unsubstituted aryloxy having 6 to 30 carbon atoms, alkylsilyl having 3 to 20 carbon atoms, a second additional substituent-substituted or unsubstituted arylsilyl having 6 to 30 carbon atoms, a second additional substituent-substituted or unsubstituted alkylarylsilyl having 7 to 30 carbon atoms, alkylthiol having 3 to 20 carbon atoms, arylthiol having 6 to 30 carbon atoms, or, arylphosphine oxide having 6 to 30 carbon atoms, and at least two of R¹ to R¹¹ can be connected to each other to form a ring,
X′ is, each independently, O, S, Se, C, Si, C—(Ar³)₂, Si—(Ar³)₂ or N—Ar³, and Ar³ is alkyl having 1 to 20 carbon atoms, a second additional substituent-substituted or unsubstituted aryl having 6 to 20 carbon atoms, or, a second additional substituent-substituted or unsubstituted heteroaryl having 5 to 20 carbon atoms, and when a plurality of Ar³ exist, a plurality of Ar are connected to each other to form a ring, X″ is, each independently, N, O, S or Se,
the second additional substituent is defined the same as the second additional substituent defined in Formula 1 above.

4. The organic light emitting diode according to any of claims 1-3,
wherein at least one of Y⁶ to Y¹⁵ and Z is an atom having an unshared electron pair included in the wave function of a HOMO or a LUMO of the charge stabilizing moiety; or
at least one of Y⁶ to Y¹⁵ has R represented by Formula 5 or Formula 6 below: 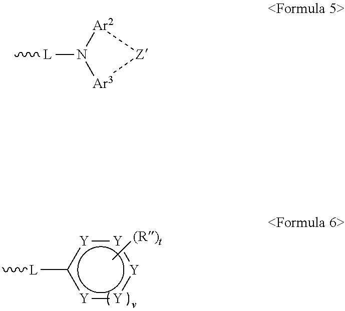
In Formula 5 or Formula 6,
L is a single bond, or a divalent group selected from the group consisting of alkylene having 1 to 20 carbon atoms, alkyl silylene having 1 to 20 carbon atoms, aryl silylene having 1 to 20 carbon atoms, alkylaryl silylene having 1 to 20 carbon atoms, oxygen, sulfur, a divalent group of aryl phosphine having 6 to 20 carbon atoms, a divalent group of aryl phosphine oxide having 6 to 20 carbon atoms, arylene having 6 to 20 carbon atoms, heteroarylene having 5 to 20 carbon atoms and combinations thereof,
Z′ is absent or represents a single bond, or is an atom selected from the group consisting of group IIIA, group IVA, group VA and group VIA elements, and when Z′ is an atom, Z′ can have a substituent(s) selected from hydrogen, alkyl having 1 to 20 carbon atoms, a third additional substituent substituted or unsubstituted aryl having 6 to 20 carbon atoms, a third additional substituent substituted or unsubstituted heteroaryl having 5 to 20 carbon atoms and combinations thereof, in accordance with a stoichiometric ratio,
Ar² and Ar³ are, each independently, alkyl having 1 to 20 carbon atoms, a third additional substituent substituted or unsubstituted aryl having 6 to 20 carbon atoms, or, a third additional substituent substituted or unsubstituted heteroaryl having 5 to 20 carbon atoms,
t is an integer from 0 to 5;
v is 0 or 1
R″ is, each independently, selected from the group consisting of hydrogen, deuterium, alkyl having 1 to 20 carbon atoms, a third additional substituent substituted or unsubstituted aryl having 6 to 20 carbon atoms, a third additional substituent substituted or unsubstituted heteroaryl having 5 to 20 carbon atoms, alkylamine having 1 to 20 carbon atoms, a third additional substituent substituted or unsubstituted arylamine having 6 to 30 carbon atoms, a third additional substituent substituted or unsubstituted alkylarylamines having 7 to 30 carbon atoms, halogen, CN, alkoxy having 1 to 20 carbon atoms, a third additional substituent substituted or unsubstituted aryloxy having 6 to 30 carbon atoms, a third additional substituent substituted or unsubstituted alkylsilyl having 1 to 20 carbon atoms, a third additional substituent substituted or unsubstituted arylsilyl having 6 to 30 carbon atoms, a third additional substituent substituted or unsubstituted alkylarylsilyl having 7 to 30 carbon atoms, alkylthiol having 1 to 20 carbon atoms, arylthiol having 6 to 20 carbon atoms, aryl phosphine having 1 to 20 carbon atoms, aryl phosphine oxide having 1 to 20 carbon atoms and combinations thereof, and at least two R″ can be linked to each other to form a ring,
the third additional substituent is selected from the group consisting of alkyl having 1 to 20 carbon atoms, aryl having 6 to 20 carbon atoms, heteroaryl having 5 to 20 carbon atoms, alkylamine having 2 to 20 carbon atoms, alkylarylamine having 7 to 20 carbon atoms, alkylsilyl having 1 to 20 carbon atoms, arylsilyl having 6 to 20 carbon atoms, alkylarylsilyl having 7 to 20 carbon atoms, alkylarylsilyl having 7 to 30 carbon atoms, alkylthiol having 1 to 20 carbon atoms, arylthiol having 6 to 20 carbon atoms and combinations thereof,
Y is, each independently, nitrogen, oxygen, sulfur or carbon, [symbol]
indicates a connection site,
provided that L or R″ in Formula 6 includes at least one atom having an unshared electron pair included in the HOMO or the LUMO wave function of the charge stabilizing moiety, or at least one of Y is nitrogen, oxygen or sulfur.

5. The organic light emitting diode according to claim 4, wherein the substituent represented by the structure of Formula 5 or Formula 6 is represented by any one of structures of Formulae D-1 to D-38 below: 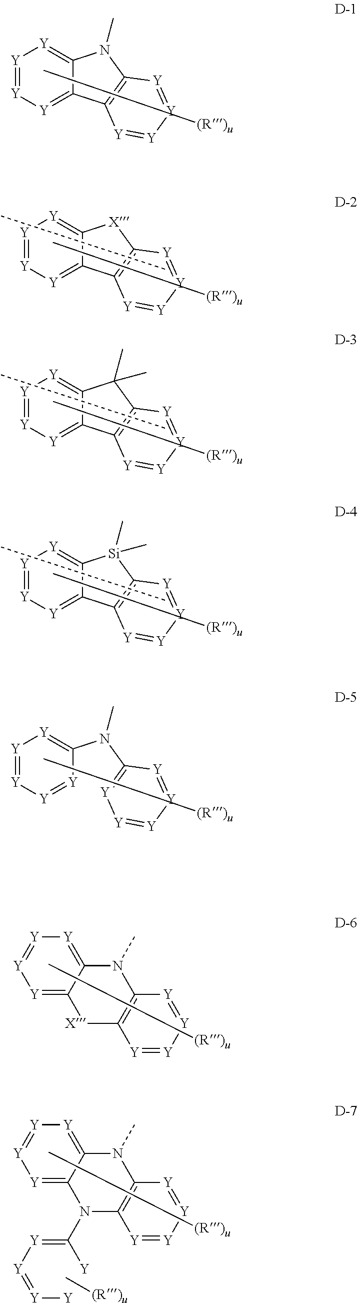 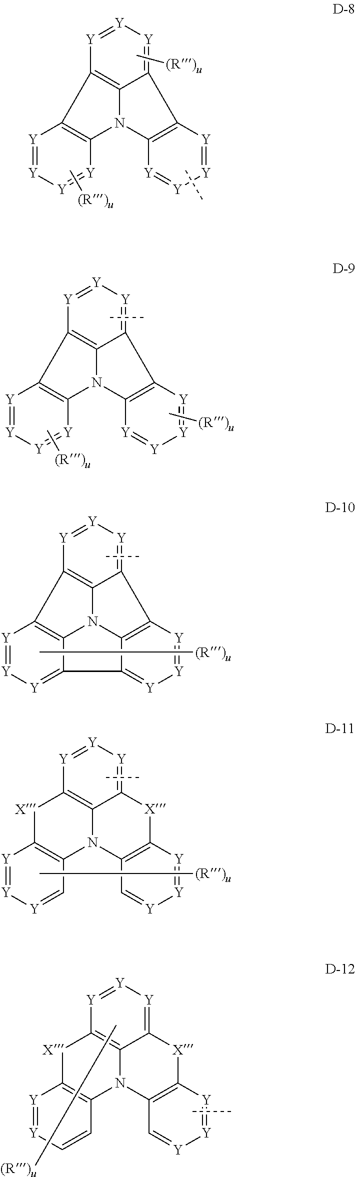 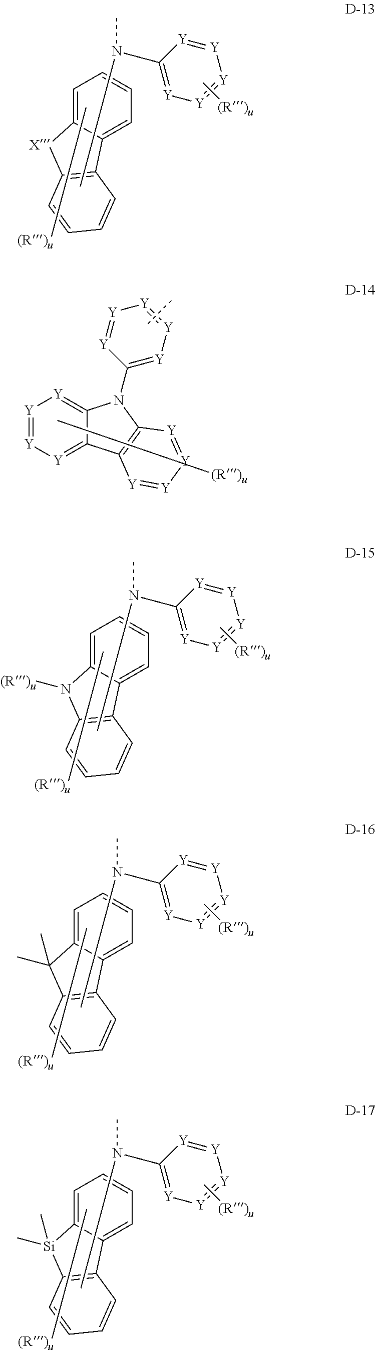 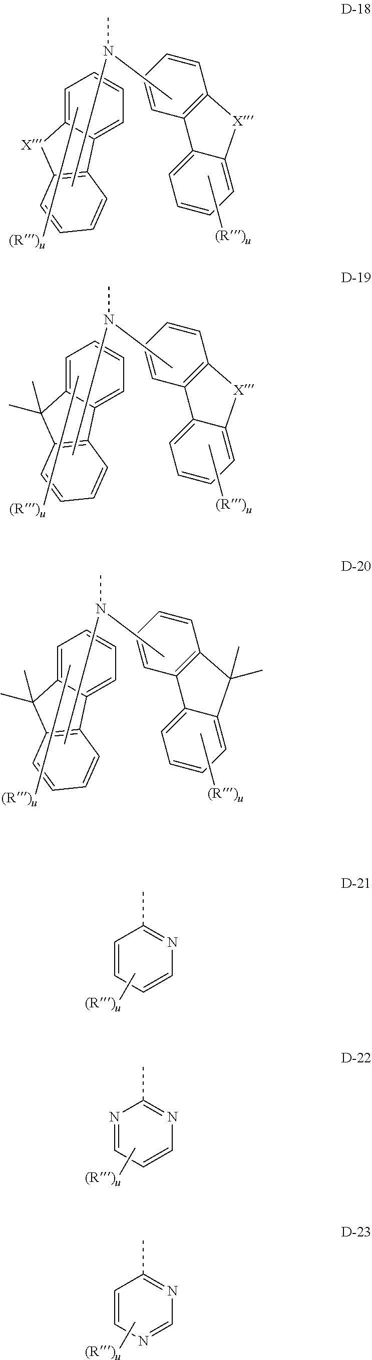 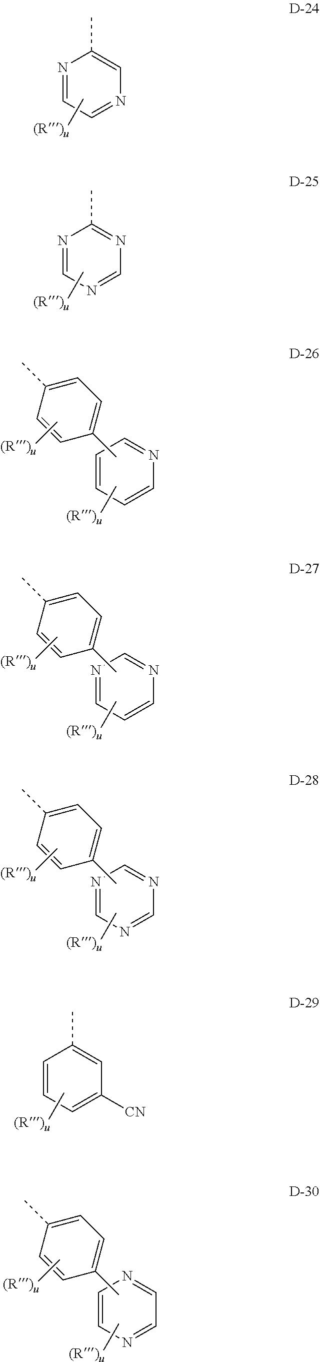 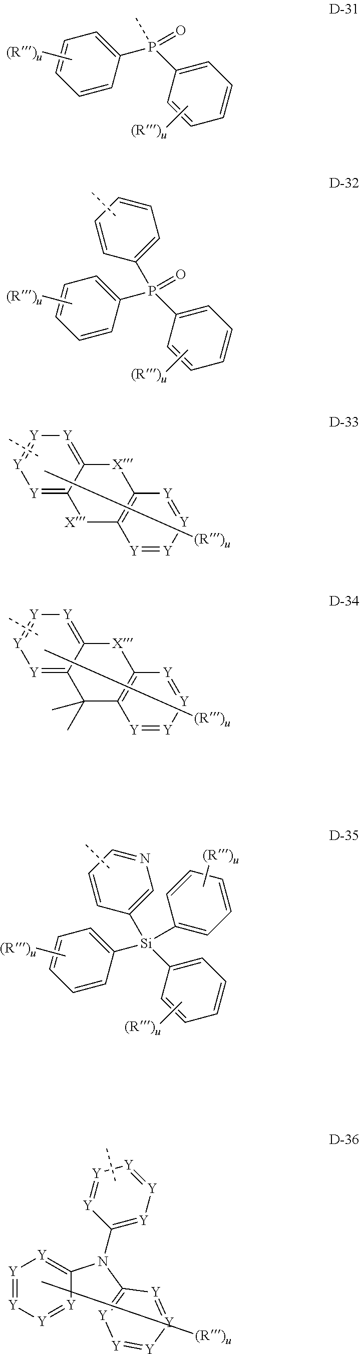 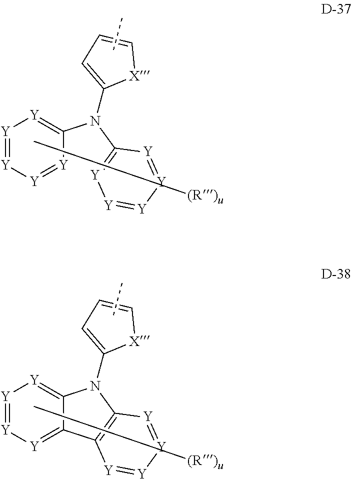
In Formulae D-1 to D-38,
Y is, each independently, carbon or nitrogen,
X′″ is, each independently, oxygen, nitrogen, sulfur or selenium,
R′″ is, each independently, selected from hydrogen, deuterium, alkyl having 1 to 20 carbon atoms, aryl having 6 to 20 carbon atoms, heteroaryl having 5 to 20 carbon atoms, alkylamine having 2 to 20 carbon atoms, halogen, CN group, alkylsilyl having 4 to 20 carbon atoms, arylsilyl of 6 to 20 carbon atoms and combinations thereof,
u is, each independently, an integer from 0 to 20,
a dotted line represents a connection site,
provided that Formulae D-1 to D-38 include at least one atom having an unshared electron pair included in the HOMO or the LUMO wave function of the charge stabilizing moiety.

6. The organic light emitting diode according to claim 1, wherein the compound represented by Formula 1 is any one of following compounds.

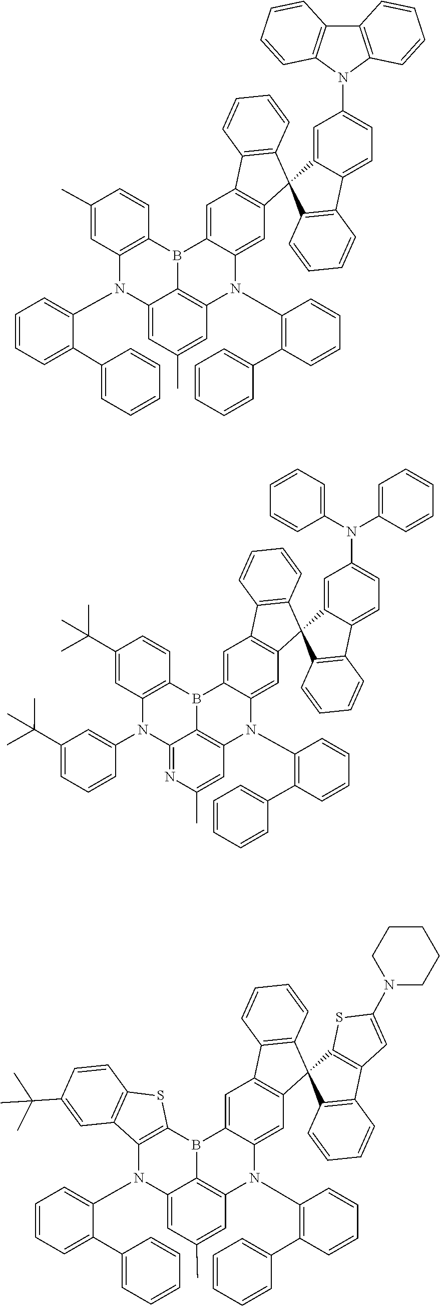 [SMILES: Cc1ccc2c(c1)N(c1ccccc1-c1ccccc1)c1cc(C)cc3c1B2c1cc2c(cc1N3c1ccccc1-c1ccccc1)[C@]1(c3ccccc3-c3ccc(-n4c5ccccc5c5ccccc54)cc31)c1ccccc1-2 ; Cc1cc2c3c(n1)N(c1cccc(C(C)(C)C)c1)c1cc(C(C)(C)C)ccc1B3c1cc3c(cc1N2c1ccccc1-c1ccccc1)[C@]1(c2ccccc2-c2ccc(N(c4ccccc4)c4ccccc4)cc21)c1ccccc1-3 ; Cc1cc2c3c(c1)N(c1ccccc1-c1ccccc1)c1c(sc4ccc(C(C)(C)C)cc14)B3c1cc3c(cc1N2c1ccccc1-c1ccccc1)[C@@]1(c2ccccc2-3)c2ccccc2-c2cc(N3CCCCC3)sc21]

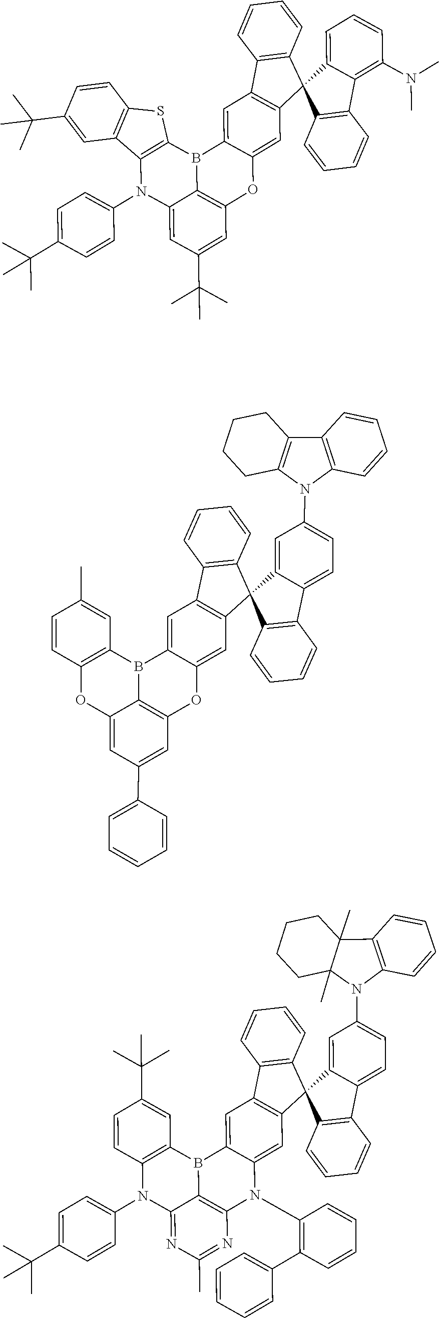

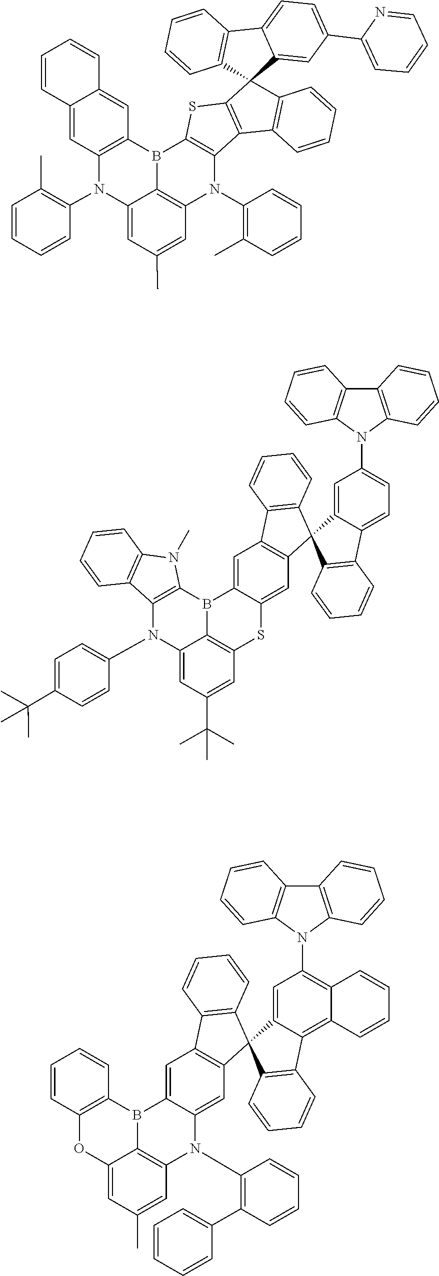 [SMILES: Cc1cc2c3c(c1)N(c1ccccc1C)c1c(sc4c1-c1ccccc1[C@@]41c4ccccc4-c4ccc(-c5ccccn5)cc41)B3c1cc3ccccc3cc1N2c1ccccc1C ; Cn1c2c(c3ccccc31)N(c1ccc(C(C)(C)C)cc1)c1cc(C(C)(C)C)cc3c1B2c1cc2c(cc1S3)[C@]1(c3ccccc3-c3ccc(-n4c5ccccc5c5ccccc54)cc31)c1ccccc1-2 ; Cc1cc2c3c(c1)N(c1ccccc1-c1ccccc1)c1cc4c(cc1B3c1ccccc1O2)-c1ccccc1[C@@]41c2ccccc2-c2c1cc(-n1c3ccccc3c3ccccc31)c1ccccc21]

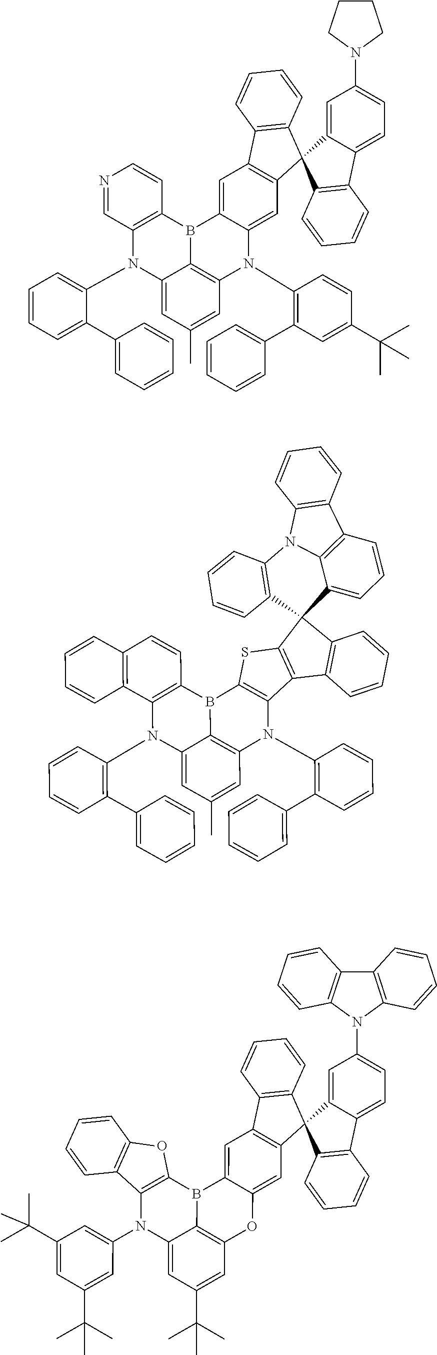

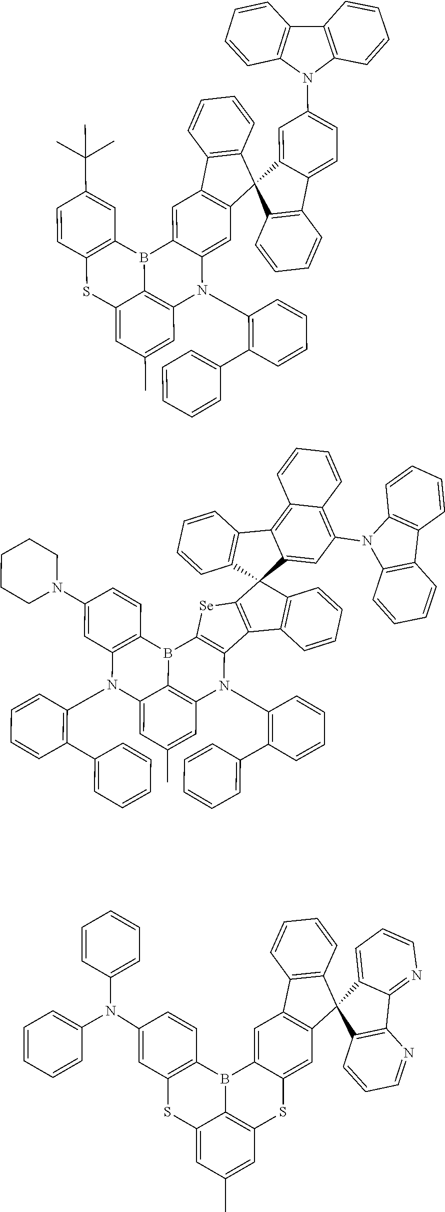

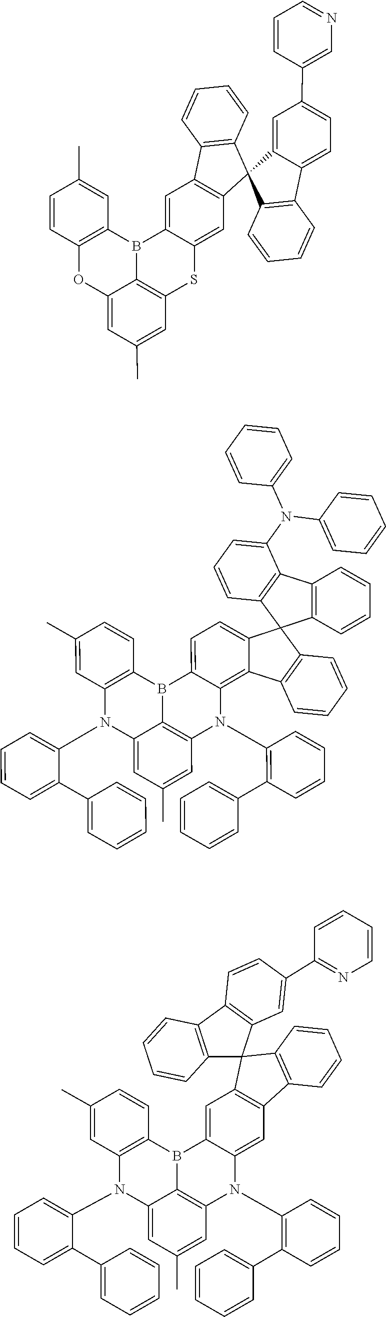 [SMILES: Cc1cc2c3c(c1)Sc1cc4c(cc1B3c1cc(C)ccc1O2)-c1ccccc1[C@@]41c2ccccc2-c2ccc(-c3cccnc3)cc21 ; Cc1ccc2c(c1)N(c1ccccc1-c1ccccc1)c1cc(C)cc3c1B2c1ccc2c(c1N3c1ccccc1-c1ccccc1)-c1ccccc1C21c2ccccc2-c2c(N(c3ccccc3)c3ccccc3)cccc21 ; Cc1ccc2c(c1)N(c1ccccc1-c1ccccc1)c1cc(C)cc3c1B2c1cc2c(cc1N3c1ccccc1-c1ccccc1)-c1ccccc1C21c2ccccc2-c2ccc(-c3ccccn3)cc21]

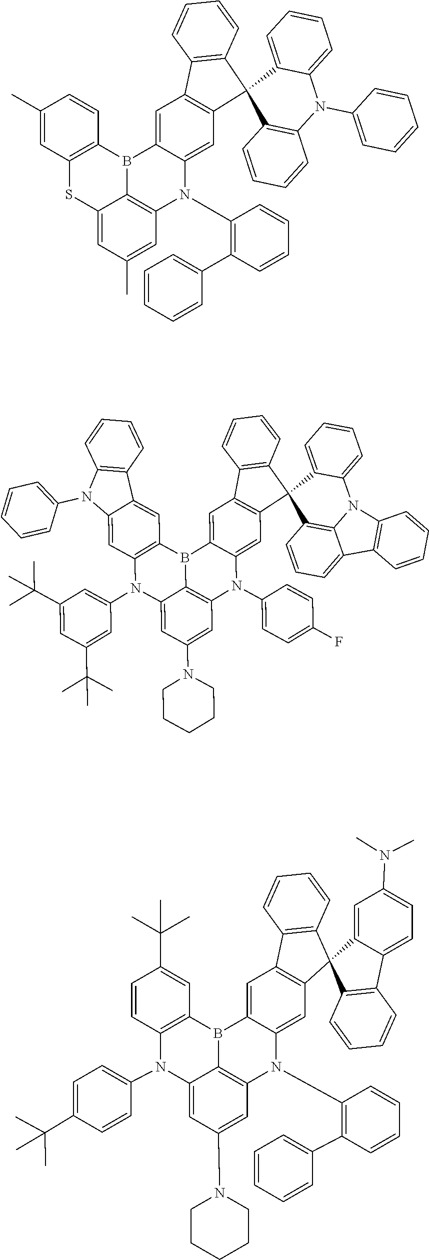

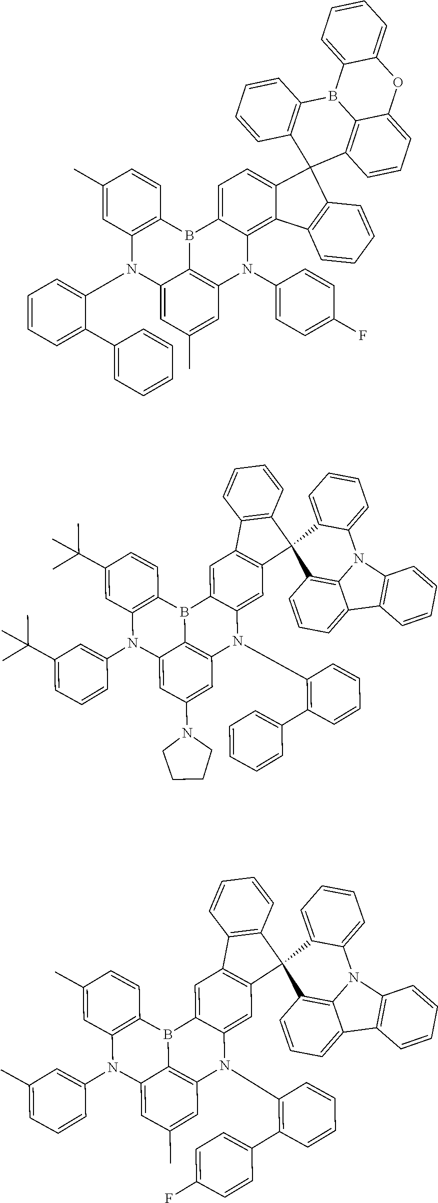 [SMILES: Cc1ccc2c(c1)N(c1ccccc1-c1ccccc1)c1cc(C)cc3c1B2c1ccc2c(c1N3c1ccc(F)cc1)-c1ccccc1C21c2ccccc2B2c3ccccc3Oc3cccc1c32 ; CC(C)(C)c1cccc(N2c3cc(C(C)(C)C)ccc3B3c4cc5c(cc4N(c4ccccc4-c4ccccc4)c4cc(N6CCCC6)cc2c43)[C@]2(c3ccccc3-5)c3ccccc3-n3c4ccccc4c4cccc2c43)c1 ; Cc1cccc(N2c3cc(C)ccc3B3c4cc5c(cc4N(c4ccccc4-c4ccc(F)cc4)c4cc(C)cc2c43)[C@]2(c3ccccc3-5)c3ccccc3-n3c4ccccc4c4cccc2c43)c1]

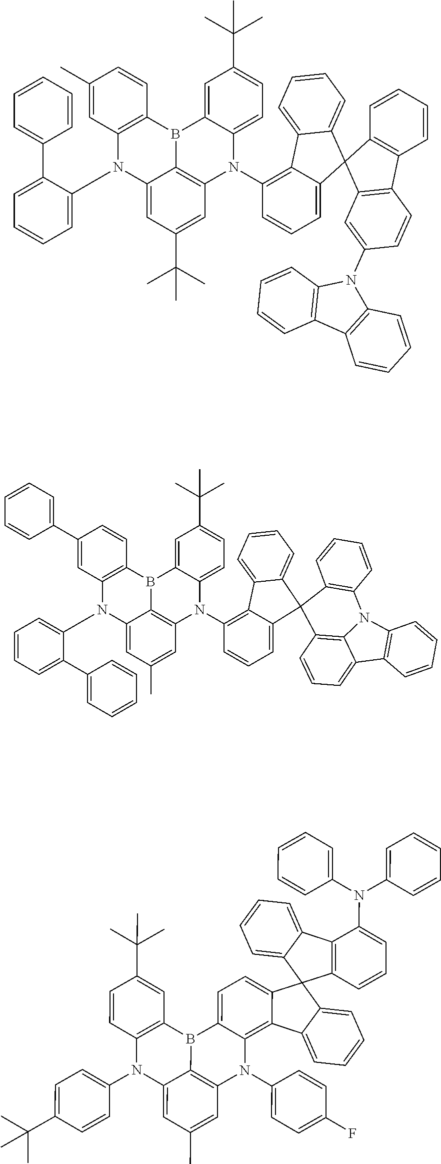 [SMILES: Cc1ccc2c(c1)N(c1ccccc1-c1ccccc1)c1cc(C(C)(C)C)cc3c1B2c1cc(C(C)(C)C)ccc1N3c1cccc2c1-c1ccccc1C21c2ccccc2-c2ccc(-n3c4ccccc4c4ccccc43)cc21 ; Cc1cc2c3c(c1)N(c1cccc4c1-c1ccccc1C41c4ccccc4-n4c5ccccc5c5cccc1c54)c1ccc(C(C)(C)C)cc1B3c1ccc(-c3ccccc3)cc1N2c1ccccc1-c1ccccc1 ; Cc1cc2c3c(c1)N(c1ccc(F)cc1)c1c(ccc4c1-c1ccccc1C41c4ccccc4-c4c(N(c5ccccc5)c5ccccc5)cccc41)B3c1cc(C(C)(C)C)ccc1N2c1ccc(C(C)(C)C)cc1]

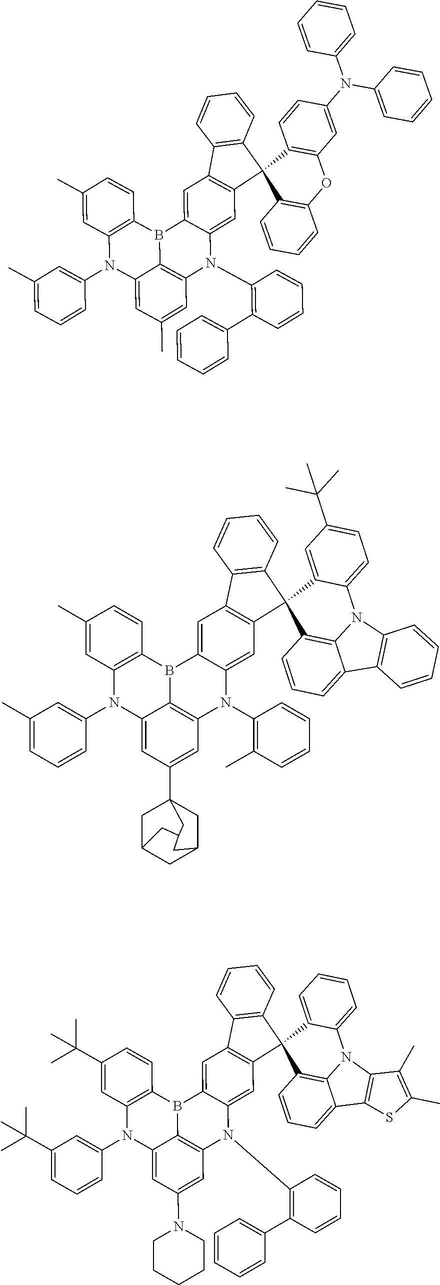 [SMILES: Cc1cccc(N2c3cc(C)ccc3B3c4cc5c(cc4N(c4ccccc4-c4ccccc4)c4cc(C)cc2c43)[C@]2(c3ccccc3Oc3cc(N(c4ccccc4)c4ccccc4)ccc32)c2ccccc2-5)c1 ; Cc1cccc(N2c3cc(C)ccc3B3c4cc5c(cc4N(c4ccccc4C)c4cc(C67CC8CC(CC(C8)C6)C7)cc2c43)[C@]2(c3ccccc3-5)c3cc(C(C)(C)C)ccc3-n3c4ccccc4c4cccc2c43)c1 ; Cc1sc2c3cccc4c3n(c2c1C)-c1ccccc1[C@]41c2ccccc2-c2cc3c(cc21)N(c1ccccc1-c1ccccc1)c1cc(N2CCCCC2)cc2c1B3c1ccc(C(C)(C)C)cc1N2c1cccc(C(C)(C)C)c1]

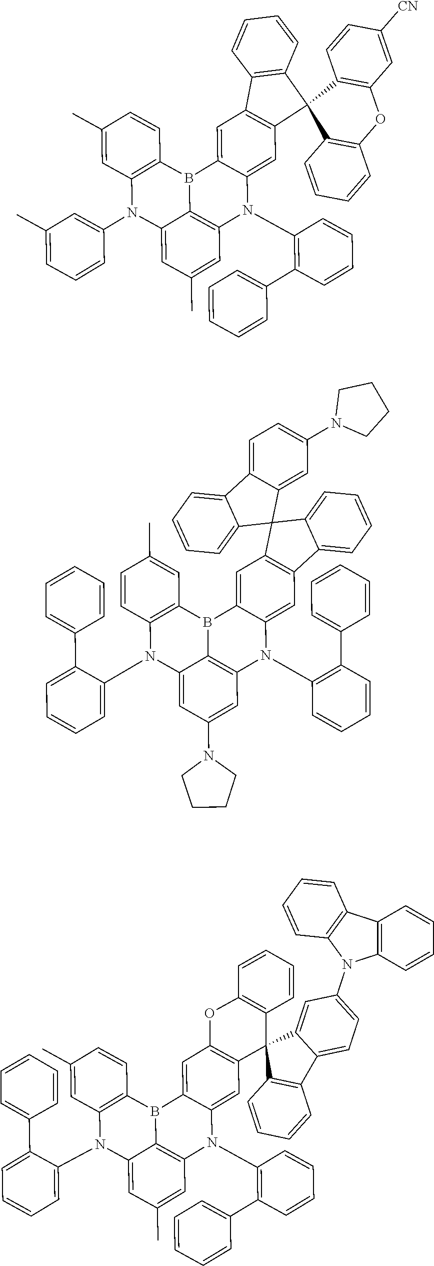 [SMILES: Cc1cccc(N2c3cc(C)ccc3B3c4cc5c(cc4N(c4ccccc4-c4ccccc4)c4cc(C)cc2c43)[C@]2(c3ccccc3Oc3cc(C#N)ccc32)c2ccccc2-5)c1 ; Cc1ccc2c(c1)B1c3cc4c(cc3N(c3ccccc3-c3ccccc3)c3cc(N5CCCC5)cc(c31)N2c1ccccc1-c1ccccc1)-c1ccccc1C41c2ccccc2-c2ccc(N3CCCC3)cc21 ; Cc1ccc2c(c1)N(c1ccccc1-c1ccccc1)c1cc(C)cc3c1B2c1cc2c(cc1N3c1ccccc1-c1ccccc1)[C@@]1(c3ccccc3O2)c2ccccc2-c2ccc(-n3c4ccccc4c4ccccc43)cc21]

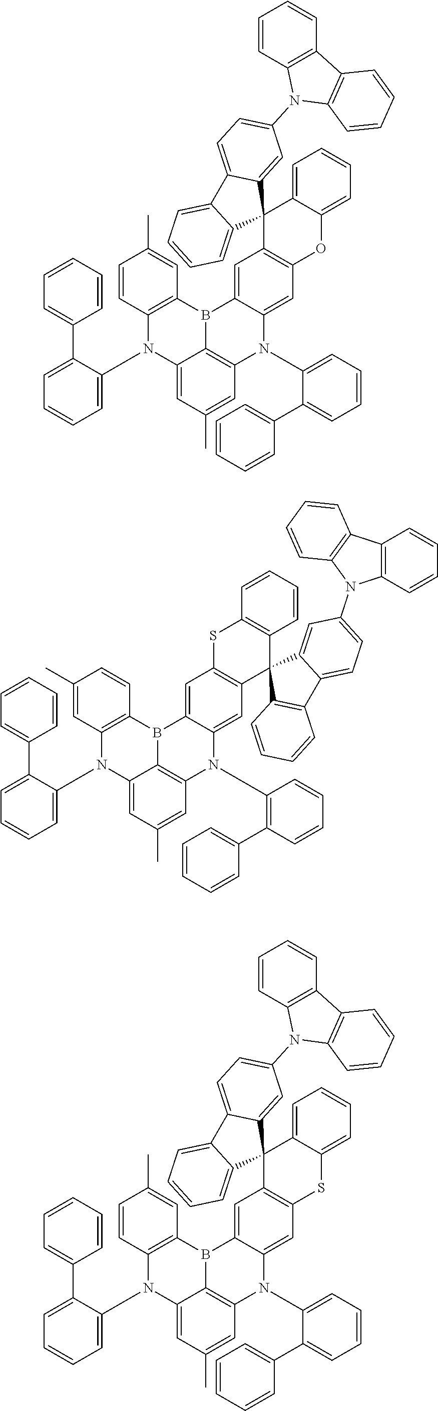 [SMILES: Cc1ccc2c(c1)B1c3cc4c(cc3N(c3ccccc3-c3ccccc3)c3cc(C)cc(c31)N2c1ccccc1-c1ccccc1)Oc1ccccc1[C@@]41c2ccccc2-c2ccc(-n3c4ccccc4c4ccccc43)cc21 ; Cc1ccc2c(c1)N(c1ccccc1-c1ccccc1)c1cc(C)cc3c1B2c1cc2c(cc1N3c1ccccc1-c1ccccc1)[C@@]1(c3ccccc3S2)c2ccccc2-c2ccc(-n3c4ccccc4c4ccccc43)cc21 ; Cc1ccc2c(c1)B1c3cc4c(cc3N(c3ccccc3-c3ccccc3)c3cc(C)cc(c31)N2c1ccccc1-c1ccccc1)Sc1ccccc1[C@@]41c2ccccc2-c2ccc(-n3c4ccccc4c4ccccc43)cc21]

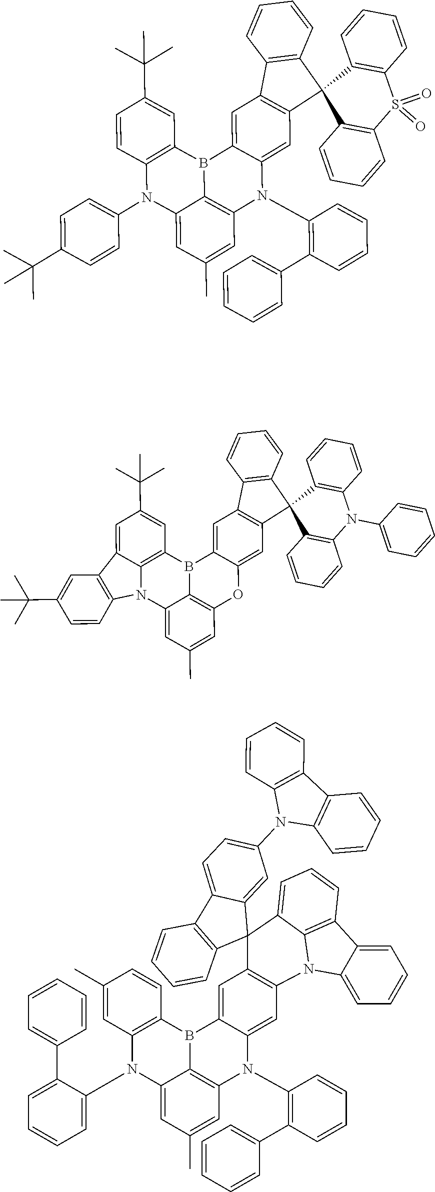

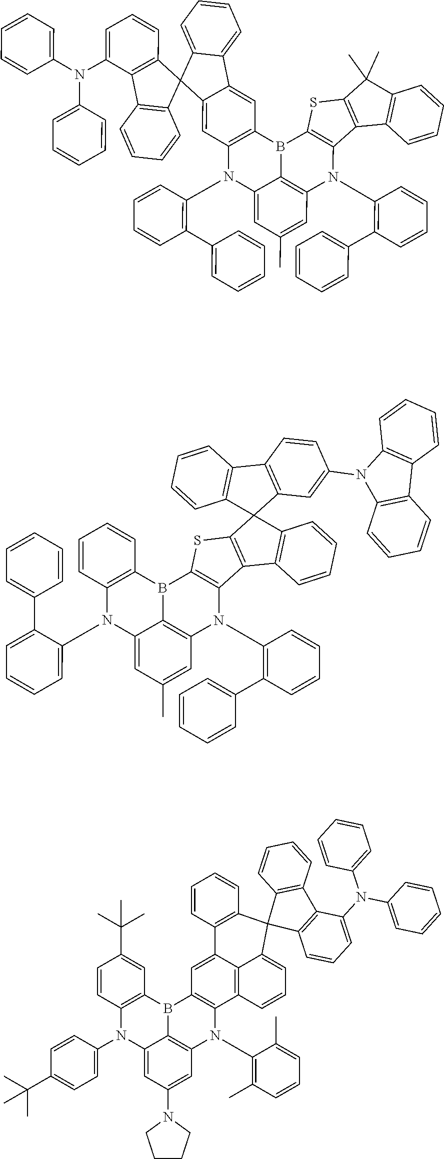 [SMILES: Cc1cc2c3c(c1)N(c1ccccc1-c1ccccc1)c1c(sc4c1-c1ccccc1C4(C)C)B3c1cc3c(cc1N2c1ccccc1-c1ccccc1)C1(c2ccccc2-3)c2ccccc2-c2c(N(c3ccccc3)c3ccccc3)cccc21 ; Cc1cc2c3c(c1)N(c1ccccc1-c1ccccc1)c1c(sc4c1-c1ccccc1C41c4ccccc4-c4ccc(-n5c6ccccc6c6ccccc65)cc41)B3c1ccccc1N2c1ccccc1-c1ccccc1 ; Cc1cccc(C)c1N1c2cc(N3CCCC3)cc3c2B(c2cc(C(C)(C)C)ccc2N3c2ccc(C(C)(C)C)cc2)c2cc3c4c(cccc4c21)C1(c2ccccc2-c2c(N(c4ccccc4)c4ccccc4)cccc21)c1ccccc1-3]

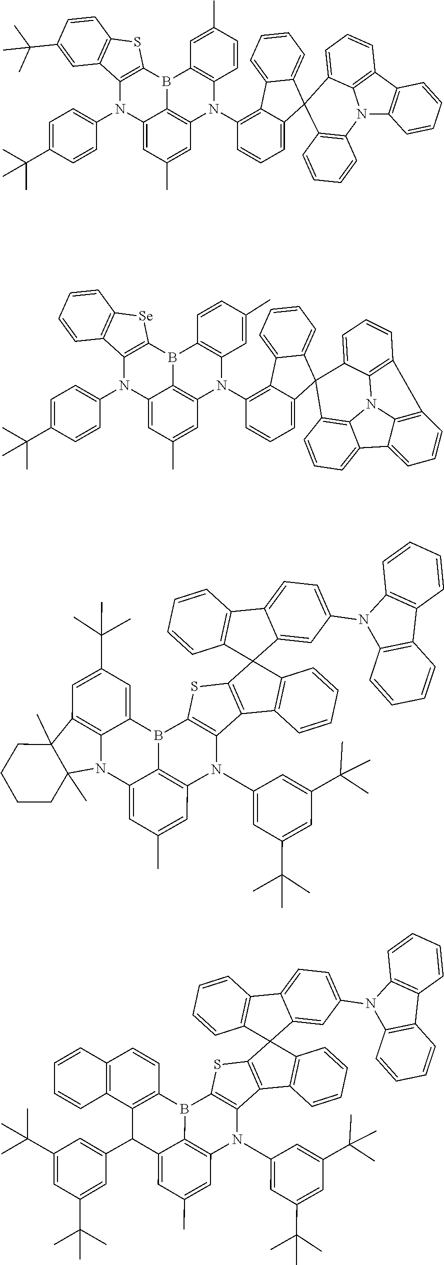

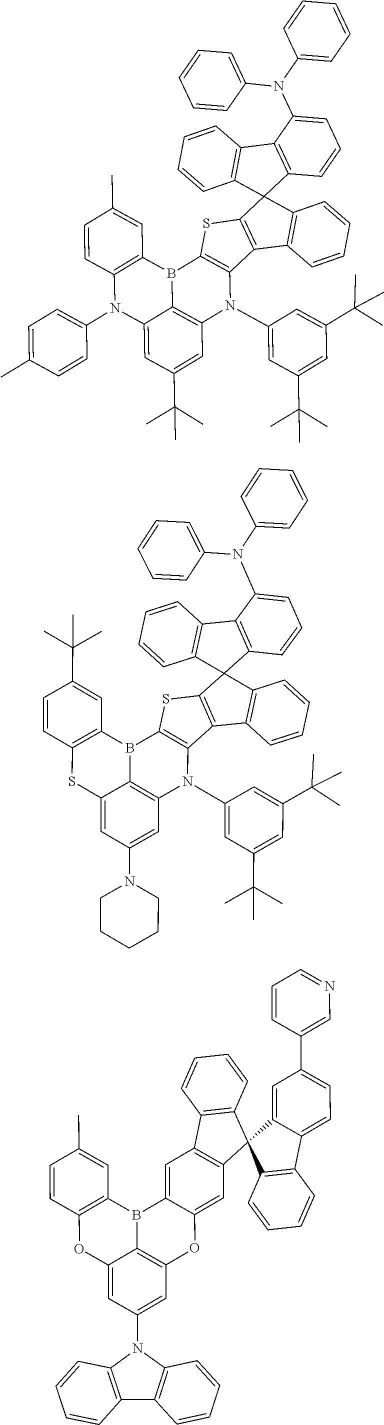

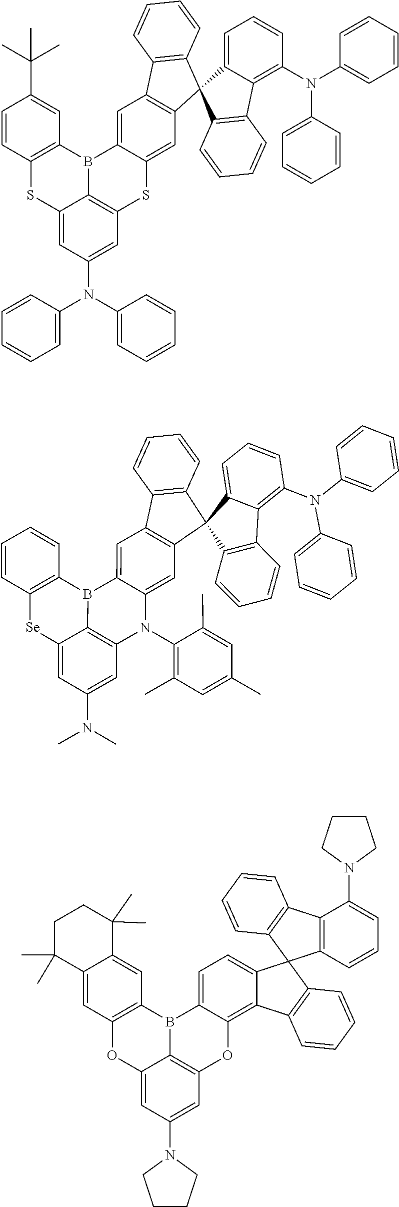 [SMILES: CC(C)(C)c1ccc2c(c1)B1c3cc4c(cc3Sc3cc(N(c5ccccc5)c5ccccc5)cc(c31)S2)[C@@]1(c2ccccc2-4)c2ccccc2-c2c(N(c3ccccc3)c3ccccc3)cccc21 ; Cc1cc(C)c(N2c3cc4c(cc3B3c5ccccc5[Se]c5cc(N(C)C)cc2c53)-c2ccccc2[C@]42c3ccccc3-c3c(N(c4ccccc4)c4ccccc4)cccc32)c(C)c1 ; CC1(C)CCC(C)(C)c2cc3c(cc21)Oc1cc(N2CCCC2)cc2c1B3c1ccc3c(c1O2)-c1ccccc1C31c2ccccc2-c2c(N3CCCC3)cccc21]

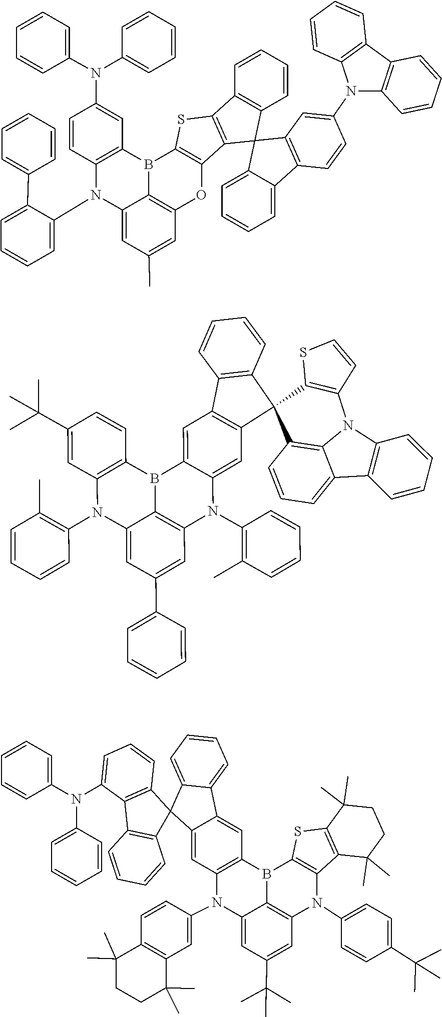 [SMILES: Cc1cc2c3c(c1)N(c1ccccc1-c1ccccc1)c1ccc(N(c4ccccc4)c4ccccc4)cc1B3c1sc3c(c1O2)C1(c2ccccc2-c2ccc(-n4c5ccccc5c5ccccc54)cc21)c1ccccc1-3 ; Cc1ccccc1N1c2cc(C(C)(C)C)ccc2B2c3cc4c(cc3N(c3ccccc3C)c3cc(-c5ccccc5)cc1c32)[C@]1(c2ccccc2-4)c2sccc2-n2c3ccccc3c3cccc1c32 ; CC(C)(C)c1ccc(N2c3cc(C(C)(C)C)cc4c3B(c3cc5c(cc3N4c3ccc4c(c3)C(C)(C)CCC4(C)C)C3(c4ccccc4-5)c4ccccc4-c4c(N(c5ccccc5)c5ccccc5)cccc43)c3sc4c(c32)C(C)(C)CCC4(C)C)cc1]

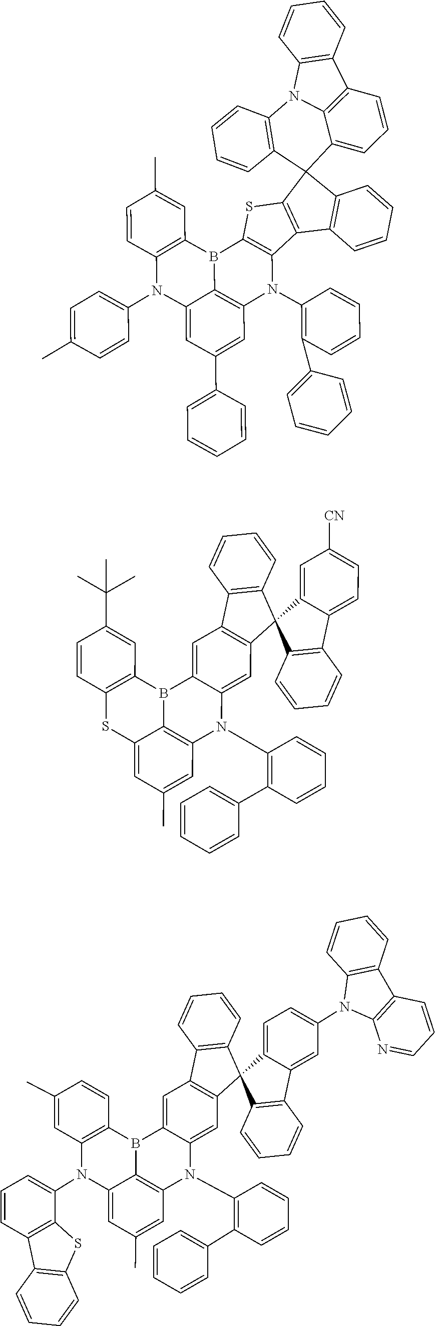 [SMILES: Cc1ccc(N2c3ccc(C)cc3B3c4sc5c(c4N(c4ccccc4-c4ccccc4)c4cc(-c6ccccc6)cc2c43)-c2ccccc2C52c3ccccc3-n3c4ccccc4c4cccc2c43)cc1 ; Cc1cc2c3c(c1)N(c1ccccc1-c1ccccc1)c1cc4c(cc1B3c1cc(C(C)(C)C)ccc1S2)-c1ccccc1[C@@]41c2ccccc2-c2ccc(C#N)cc21 ; Cc1ccc2c(c1)N(c1cccc3c1sc1ccccc13)c1cc(C)cc3c1B2c1cc2c(cc1N3c1ccccc1-c1ccccc1)[C@]1(c3ccccc3-c3cc(-n4c5ccccc5c5cccnc54)ccc31)c1ccccc1-2]

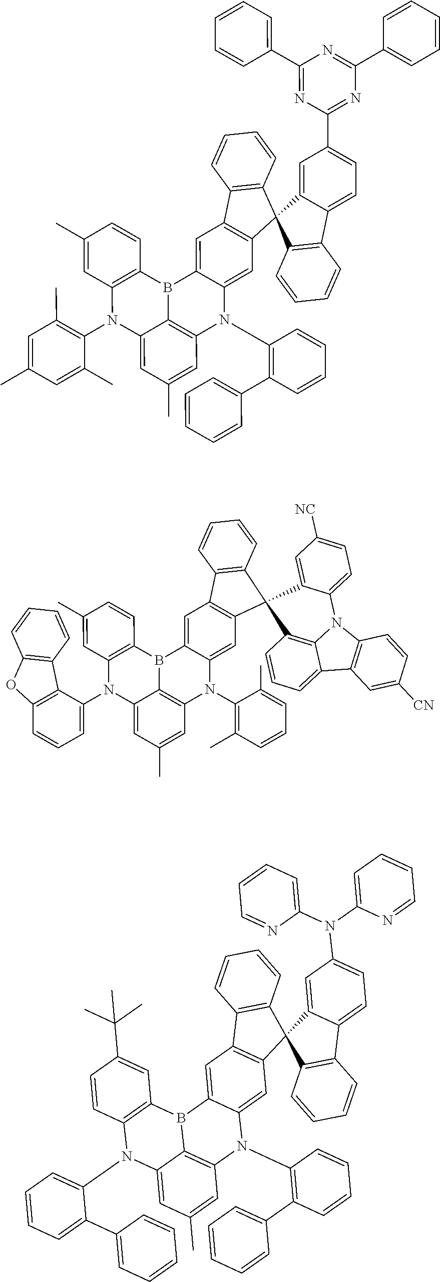 [SMILES: Cc1cc(C)c(N2c3cc(C)ccc3B3c4cc5c(cc4N(c4ccccc4-c4ccccc4)c4cc(C)cc2c43)[C@]2(c3ccccc3-c3ccc(-c4nc(-c6ccccc6)nc(-c6ccccc6)n4)cc32)c2ccccc2-5)c(C)c1 ; Cc1ccc2c(c1)N(c1cccc3oc4ccccc4c13)c1cc(C)cc3c1B2c1cc2c(cc1N3c1c(C)cccc1C)[C@]1(c3ccccc3-2)c2cc(C#N)ccc2-n2c3ccc(C#N)cc3c3cccc1c32 ; Cc1cc2c3c(c1)N(c1ccccc1-c1ccccc1)c1cc4c(cc1B3c1cc(C(C)(C)C)ccc1N2c1ccccc1-c1ccccc1)-c1ccccc1[C@@]41c2ccccc2-c2ccc(N(c3ccccn3)c3ccccn3)cc21]

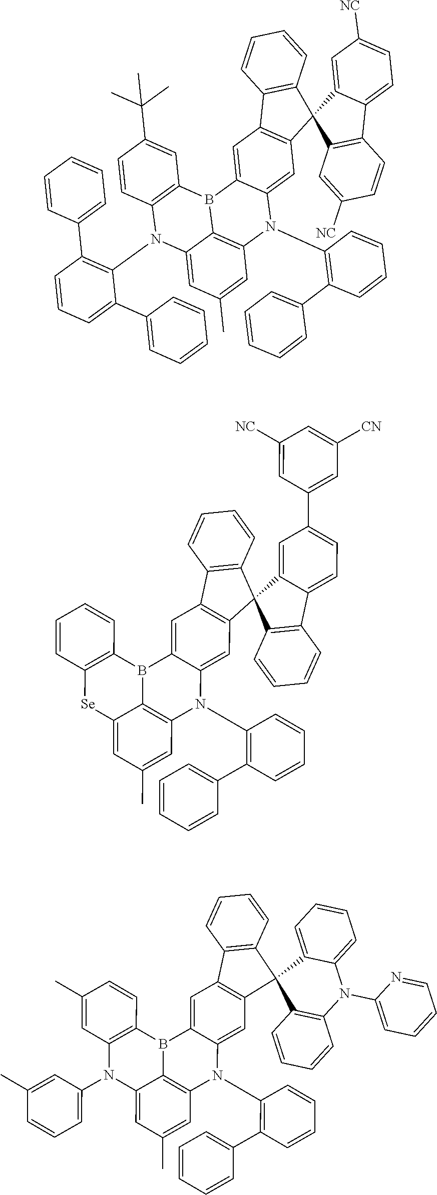

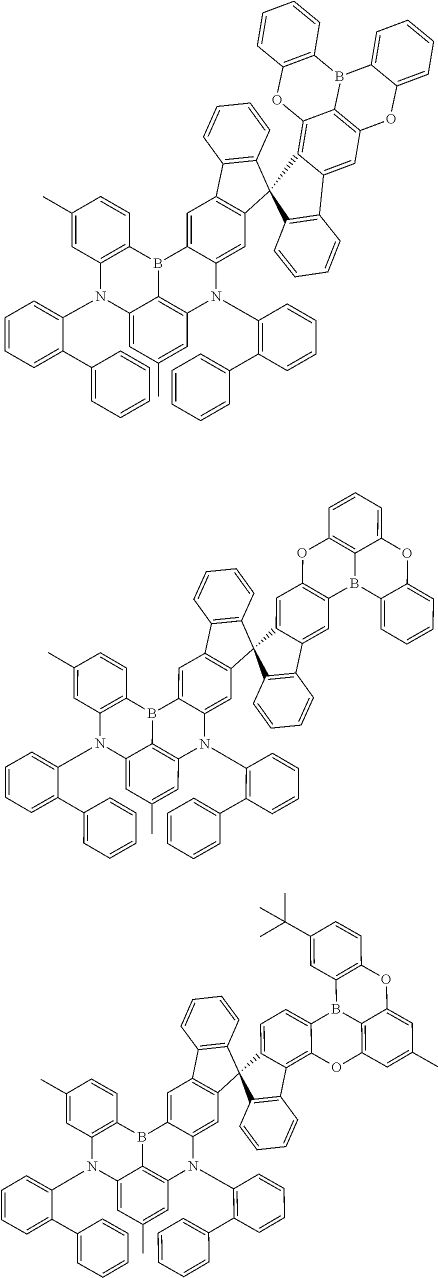 [SMILES: Cc1ccc2c(c1)N(c1ccccc1-c1ccccc1)c1cc(C)cc3c1B2c1cc2c(cc1N3c1ccccc1-c1ccccc1)[C@@]1(c3ccccc3-2)c2ccccc2-c2cc3c4c(c21)Oc1ccccc1B4c1ccccc1O3 ; Cc1ccc2c(c1)N(c1ccccc1-c1ccccc1)c1cc(C)cc3c1B2c1cc2c(cc1N3c1ccccc1-c1ccccc1)[C@]1(c3ccccc3-c3cc4c(cc31)Oc1cccc3c1B4c1ccccc1O3)c1ccccc1-2 ; Cc1cc2c3c(c1)Oc1c(ccc4c1-c1ccccc1[C@@]41c4ccccc4-c4cc5c(cc41)N(c1ccccc1-c1ccccc1)c1cc(C)cc4c1B5c1ccc(C)cc1N4c1ccccc1-c1ccccc1)B3c1cc(C(C)(C)C)ccc1O2]

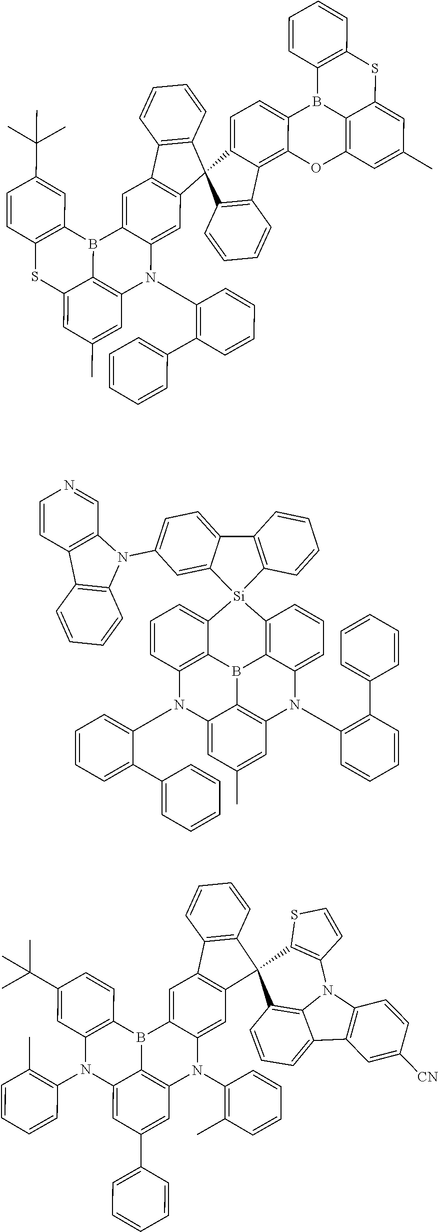 [SMILES: Cc1cc2c3c(c1)Sc1ccccc1B3c1ccc3c(c1O2)-c1ccccc1[C@@]31c2ccccc2-c2cc3c(cc21)N(c1ccccc1-c1ccccc1)c1cc(C)cc2c1B3c1cc(C(C)(C)C)ccc1S2 ; Cc1cc2c3c(c1)N(c1ccccc1-c1ccccc1)c1cccc4c1B3c1c(cccc1[Si]41c3ccccc3-c3ccc(-n4c5ccccc5c5ccncc54)cc31)N2c1ccccc1-c1ccccc1 ; Cc1ccccc1N1c2cc(C(C)(C)C)ccc2B2c3cc4c(cc3N(c3ccccc3C)c3cc(-c5ccccc5)cc1c32)[C@]1(c2ccccc2-4)c2sccc2-n2c3ccc(C#N)cc3c3cccc1c32]

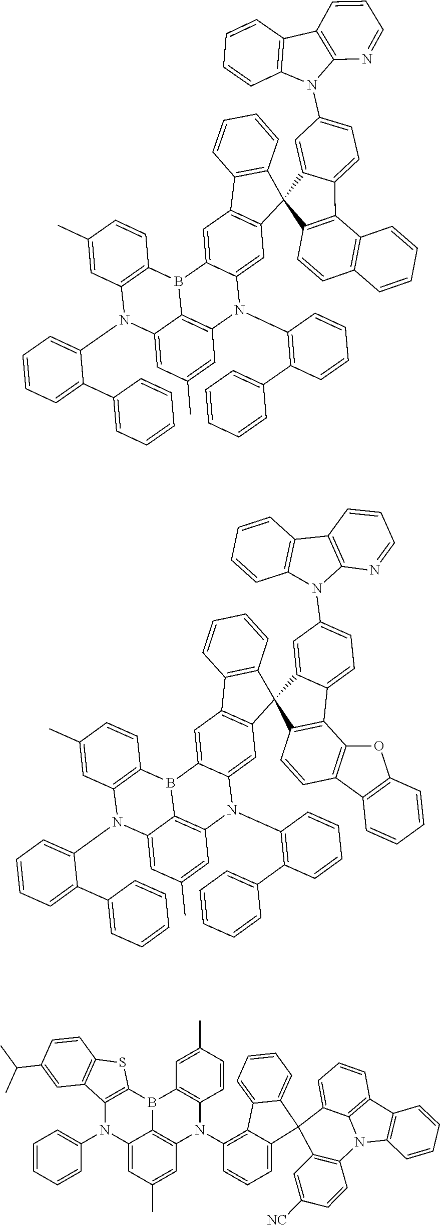 [SMILES: Cc1ccc2c(c1)N(c1ccccc1-c1ccccc1)c1cc(C)cc3c1B2c1cc2c(cc1N3c1ccccc1-c1ccccc1)[C@]1(c3ccccc3-2)c2cc(-n3c4ccccc4c4cccnc43)ccc2-c2c1ccc1ccccc21 ; Cc1ccc2c(c1)N(c1ccccc1-c1ccccc1)c1cc(C)cc3c1B2c1cc2c(cc1N3c1ccccc1-c1ccccc1)[C@]1(c3ccccc3-2)c2cc(-n3c4ccccc4c4cccnc43)ccc2-c2c1ccc1c2oc2ccccc21 ; Cc1ccc2c(c1)B1c3sc4ccc(C(C)C)cc4c3N(c3ccccc3)c3cc(C)cc(c31)N2c1cccc2c1-c1ccccc1C21c2cc(C#N)ccc2-n2c3ccccc3c3cccc1c32]

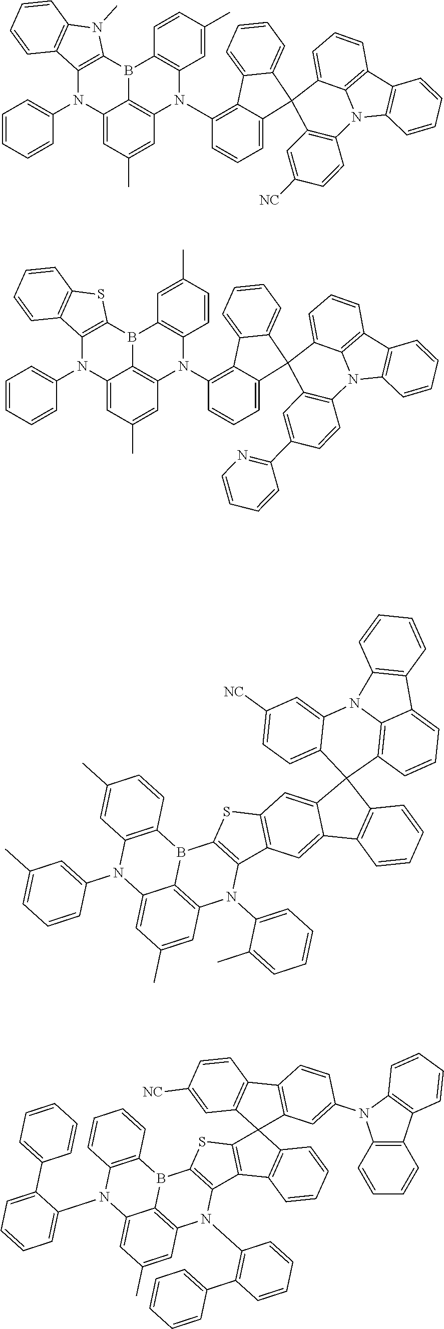 [SMILES: Cc1ccc2c(c1)N(c1cccc3c1-c1ccccc1C31c3cc(C#N)ccc3-n3c4ccccc4c4cccc1c43)c1cc(C)cc3c1B2c1c(c2ccccc2n1C)N3c1ccccc1 ; Cc1ccc2c(c1)B1c3sc4ccccc4c3N(c3ccccc3)c3cc(C)cc(c31)N2c1cccc2c1-c1ccccc1C21c2cc(-c3ccccn3)ccc2-n2c3ccccc3c3cccc1c32 ; Cc1cccc(N2c3cc(C)ccc3B3c4sc5cc6c(cc5c4N(c4ccccc4C)c4cc(C)cc2c43)-c2ccccc2C62c3ccc(C#N)cc3-n3c4ccccc4c4cccc2c43)c1 ; Cc1cc2c3c(c1)N(c1ccccc1-c1ccccc1)c1c(sc4c1-c1ccccc1C41c4cc(C#N)ccc4-c4ccc(-n5c6ccccc6c6ccccc65)cc41)B3c1ccccc1N2c1ccccc1-c1ccccc1]

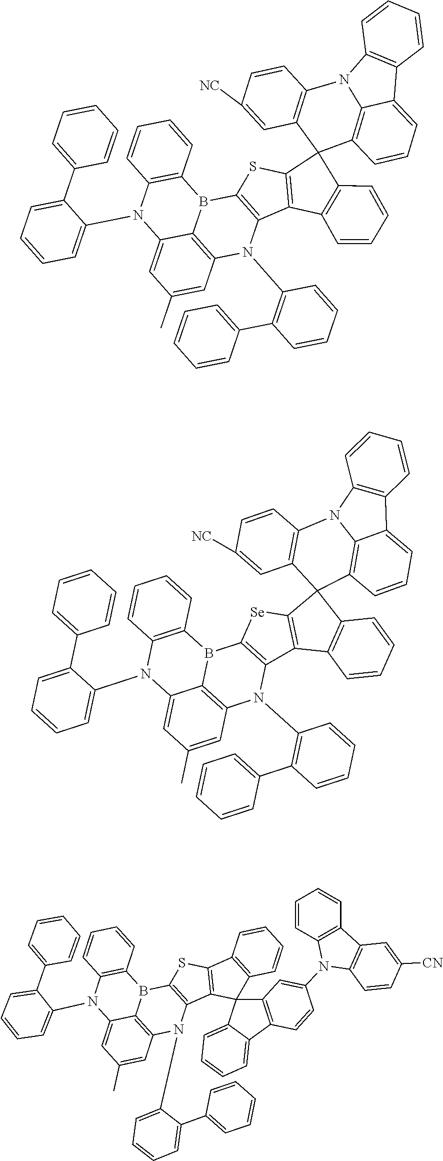 [SMILES: Cc1cc2c3c(c1)N(c1ccccc1-c1ccccc1)c1c(sc4c1-c1ccccc1C41c4cc(C#N)ccc4-n4c5ccccc5c5cccc1c54)B3c1ccccc1N2c1ccccc1-c1ccccc1 ; Cc1cc2c3c(c1)N(c1ccccc1-c1ccccc1)c1c([se]c4c1-c1ccccc1C41c4cc(C#N)ccc4-n4c5ccccc5c5cccc1c54)B3c1ccccc1N2c1ccccc1-c1ccccc1 ; Cc1cc2c3c(c1)N(c1ccccc1-c1ccccc1)c1c(sc4c1C1(c5ccccc5-c5ccc(-n6c7ccccc7c7cc(C#N)ccc76)cc51)c1ccccc1-4)B3c1ccccc1N2c1ccccc1-c1ccccc1]

7. The organic light emitting diode according to claim 1, wherein the emission layer further includes a phosphorescent material containing Ir or Pt.

8. The organic light emitting diode according to claim 1, wherein the emission layer further includes a thermally activated delayed fluorescent material having a singlet and triplet energy difference of 0.3 eV or more.

9. The organic light emitting diode according to claim 1, wherein the organic light emitting diode is a tandem type organic light emitting diode including a plurality of organic light emitting units, and
at least one of the plurality of organic light emitting units includes the emission layer.
